(19) United States
(12) Patent Application Publication
(10) Pub. No.: US 2005/0161749 A1
(43) Pub. Date: Jul. 28, 2005

(54) Apparatus and method for vacuum-based nanomechanical energy force and mass sensors

(75) Inventors: Y. T. L Yang, Sunnyvale, CA (US); Darrell A. Harrington, Pasadena, CA (US); Jean Casey, San Diego, CA (US); Jessica L. Arlett, Altadena, CA (US); H. X. Tang, Pasadena, CA (US); X. M. H. Huang, New York, NY (US); Kamil L. Ekinci, Brookline, MA (US); Michael L. Roukes, Pasadena, CA (US)

Correspondence Address: FOLEY AND LARDNER;SUITE 500, 3000 K STREET NW, WASHINGTON, DC, 20007, US

(73) Assignee: California Institute of Technology

(21) Appl. No.: 10/502,461

(22) PCT Filed: May 7, 2003
(86) PCT No.: PCT/US03/14566

Related U.S. Application Data
(60) Provisional application No. 60/379,536, filed on May 7, 2002.
(60) Provisional application No. 60/379,542, filed on May 7, 2002.
(60) Provisional application No. 60/379,544, filed on May 7, 2002.
(60) Provisional application No. 60/379,535, filed on May 7, 2002.
(60) Provisional application No. 60/379,546, filed on May 7, 2002.
(60) Provisional application No. 60/379,644, filed on May 7, 2002.
(60) Provisional application No. 60/379,713, filed on May 7, 2002.
(60) Provisional application No. 60/379,709, filed on May 7, 2002.
(60) Provisional application No. 60/379,685, filed on May 7, 2002.
(60) Provisional application No. 60/379,550, filed on May 7, 2002.
(60) Provisional application No. 60/379,551, filed on May 7, 2002.
(60) Provisional application No. 60/419,617, filed on Oct. 17, 2002.

(51) Int. Cl. H01L 27/14

(52) U.S. Cl. 257/414

(57) ABSTRACT

A doubly clamped beam has an asymmetric piezoelectric layer within the beam with a gate proximate to the beam within a submicron distance with a gate and beam dipole. A suspended beam is formed using a Cl₂/He plasma etch supplied at a flow rate ratio of 1:9 respectively into a plasma chamber. A parametric amplifier comprises a NEMS signal beam driven at resonance and a pair of pump beams driven at twice resonance to generate a modulated Lorentz force on the pump beams to perturb the spring constant of the signal beam. A bridge circuit provides two out-of-phase components of an excitation signal to a first and second NEMS beam in a first and second arm. A DC current is supplied to an AC driven NEMS device to tune the resonant frequency. An analyzer comprises a plurality of piezoresistive NEMS cantilevers with different resonant frequencies and a plurality of drive/sense elements, or an interacting plurality of beams to form an optical diffraction grating, or a plurality of strain-sensing NEMS cantilevers, each responsive to a different analyte, or a plurality of piezoresistive NEMS cantilevers with different IR absorbers.

### BACKGROUND OF THE INVENTION

1. Field of the Invention

The invention relates to the field of vacuum-based nanomechanical detectors which convert some aspect or attribute of energy, force, and mass into an electrical response.

2. Description of the Prior Art

Thin, suspended two-dimensional electron gas heterostructures have been recently perfected, and have subsequently been employed for nanoscale conducting devices as described in Blick et. al., Phys. Rev. B 62. In Beck et. al., Appl. Phys. Lett. 68, 3763 (1996) and Appl. Phys. Lett. 73, 1149 (1998), a stress sensing field effect transistor was integrated into a cantilever and was used as deflection readout. The FET employed had transconductance of about 1000 μS and a small signal drain-source resistance of about 10 MΩ, and its strain sensitivity was presumed to arise from the piezoelectric effect.

The sensitive detection of motion in resonant mechanical systems invariably relies on at least one of the following: efficient transduction of the motion to an electrical signal, and the use of a low noise electrical readout circuit. In general, for micron-scale structures with extremely high aspect ratios operating in vacuum, transduction is sufficiently responsive to enable the detection of the structure's thermomechanical fluctuations. However, as the device size is reduced to the nanometer-scale, it becomes increasingly difficult to maintain the necessary aspect ratios for the responsive transduction required to attain the fundamental sensitivity limits of thermomechanical fluctuations or quantum zero-point motion.

The detection sensitivity in a nanoelectromechanical device, then, is in general limited by noise at the input of the linear electrical amplifier in the readout circuit, rather than by intrinsic fluctuations. In order to circumvent this limitation, it is necessary to amplify the signal by a nonlinear amplifier prior to its transmission to the linear electrical amplifier. Fortunately, one of the primary attributes of nanoelectromechanical systems (NEMS) is easily accessible nonlinearity.

Mechanical parametric amplification has been demonstrated in a few microfabricated systems in the past decade. In all these systems, amplification of the motion of the resonator was obtained by modulating the spring constant of the resonator at twice its natural frequency. The distinguishing features of these systems are their bandwidth, dynamic range, and the nature of the modulation in spring constant. Rugar and Grutter were the first to demonstrate mechanical parametric amplification in a microfabricated device. In their device, the electrical component of a silicon cantilever's spring constant was modulated by forming a capacitor between the cantilever and a baseplate, and varying the voltage between electrodes on the two surfaces. The bandwidth of their device was ω₀/4Q=5.3 Hz and their detection sensitivity was sufficient to achieve the first demonstration of thermomechanical noise squeezing. Dana et al. observed parametric amplification in a partially metallized gallium arsenide cantilever bent by residual stress due to thermal mismatch between the metal and the gallium arsenide. Modulation of the spring constant was achieved by the superposition of a large pump drive on top of the small mechanical signal to be amplified, in order to access second-order geometric nonlinearity resulting from the curved geometry. The bandwidth in this experiment was again on the order of 6 Hz. Carr et al demonstrated parametric amplification in a surface micromachined torsional resonator operating at 500 kHz, with bandwidth on the order of 1 kHz. In this device, a capacitor was formed between the resonator and the substrate, and the electrical component of the spring constant was again modulated by a pump signal applied across the capacitor. All these experiments showed mechanical gain from up to 20, with threshold pump voltages ranging from 200 mV to a few V.

Balanced Electronic Displacement Detection for VHF NEMS

The recent efforts to scale microelectromechanical systems (MEMS) down to the sub-micron domain have opened up an active research field, drawing interest from both technical and scientific communities. These nanoelectromechanical systems (NEMS) possess fundamental mechanical resonance frequencies reaching into the microwave bands and are suitable for a number of important technological applications such as ultrafast actuators, sensors, and high frequency signal processing components. Experimentally, they are expected to make possible investigations of new phonon mediated mechanical processes and of the quantum behavior of mesoscopic mechanical systems.

Among the most needed elements for developing NEMS based technologies, as well as for accessing the interesting experimental regimes they open up, are sensitive, wide-band, on-chip transduction methods sensitive to sub-nanometer displacements. While displacement detection at the scale of MEMS has been successfully realized using magnetic, electrostatic and piezoresistive transducers through electronic coupling, most of these techniques become insensitive at the sub-micron scales. Moreover, the attractive electronic two-port actuation-detection configuration of most MEMS devices becomes hard to realize at the scale of NEMS, due to the unavoidable stray couplings encountered with the reduced dimensions of NEMS.

An on-chip displacement transduction scheme that scales well into the NEMS domain and offers direct electronic coupling to the NEMS displacement is magnetomotive detection. Magnetomotive reflection measurements on radiofrequency (RF) NEMS have found extensive use and been analyzed in detail. The operational circuit for such a measurement is shown in FIG. 19(a), with the NEMS modeled as a parallel RLC network. When driven by a source at ω, a voltage on R_{L} can be detected as

$${V}_{0} ( ω ) = {V}_{in} ( ω ) \frac{{R}_{e} + {Z}_{m} ( ω )}{{R}_{L} + 2 ( {R}_{e} + {Z}_{m} ( ω ) )} ≅ {V}_{in} ( ω ) \frac{{R}_{e} + {Z}_{m} ( ω )}{{R}_{L} + 2 {R}_{e}} \qquad 4.1$$

Here, Rₑ is the electronic DC coupling resistance to the NEMS device, Zₘ(ω) is the mechanical impedance of the resonator, R_{L} and Rₛ are the source and load impedances, respectively and the simplifying assumption R_{L}=Rₛ=50 Ω has been made. We have made the approximation that Rₑ>>|Zₘ(ω)|, as is the case in most experimental systems. Apparently, the measured EMF due to the NEMS displacement proportional to Zₘ(ω) is embedded in a background voltage proportional to Rₑ. This facilitates the definition of a useful parameter, the detection efficiency at the mechanical resonance frequency as the ratio of the signal voltage, S, to the background, B,

$$\frac{S}{B} = \frac{{R}_{m}}{{R}_{e}} \qquad 4.2$$

The above expressions indicate some limitations of the reflective, one-port magnetomotive displacement detection. First, detection of the EMF becomes extremely challenging in interesting NEMS devices without metallization layers or having high resonance frequencies (small mechanical impedances), i.e. when Rₑ>>Rₘ. Second, the voltage background in the signal prohibits the use of the full dynamic range of the detection electronics. A two-port configuration for displacement actuation and detection might seem to remedy the above problems by improving SIB, but in reality, the stray electronic coupling between the ports typically dominates the measured response.

Ultra High Frequency Silicon Carbide Nanomechanical Resonators

Significant efforts have been made recently in the fabrication and measurement of nanomechanical resonators with fundamental resonance frequencies reaching into the UHF (ultra-high frequency) and microwave bands. Such research and development carry great importance both scientifically and technologically. In terms of fundamental science, such devices offer intriguing potential for testing quantum mechanics by observing mesoscopic mechanical motion, and for ultrasensitive measurement over the standard quantum limit. On the technological side, the nanoelectromechanical systems (NEMS), when used as high resolution sensors and actuators, or as high speed signal processing components, offer great advantage of much greater integratability over what has been implemented in today's industry.

Carr et al at Cornell University have recently reported successful measurement of single suspended wires with fundamental resonant frequencies up to 380 MHz. However, as indicated in their paper, “Wires with lengths below 2 μm could not be easily detected.”, which implies that 380 MHz is nearly the highest fundamental resonance frequency accessible with their technique, without major new developments to be made in the future.

Frequency Tuning of MEMSINEMS Resonators by the Lorentz Force

High performance sensor and transducer applications of MEMS require that the device frequencies be tuned or adjusted after fabrication. Several different methods realizing tuning up to a few times the mechanical resonances have been presented for device frequency tuning in the MEMS literature. These methods can be classified into two categories, those that alter and those that supplement the restoring forces provided by the mechanical springs. The simplest example for the former method comes from thermal cycling of a clamped beam. As the beam contracts or expands depending on the temperature change, the resonance frequency shifts due to the stress induced in the beam. The latter case has been realized by implementing electrostatic actuators in a micromechanical device that provides an electrostatic restoring force in conjunction with the mechanical spring force.

Since higher mechanical resonance frequencies in NEMS devices imply higher spring constants, force tuning by altering the mechanical restoring forces is expected to be a smaller effect in high frequency resonators. In order to assess the tuning prospects of high frequency MEMS (f>1 MHz), we have made some investigations of the dependence of the device frequencies on constant forces and, temperature variations. Our measurements indicate that tuning effects indeed become obscured among other effects such as thermal frequency shifts as the device frequencies go up. Above resonance frequencies of 5 MHz, force tuning was not possible using our current techniques. In lower frequency resonators (1 MHz<f<3.5 MHz), stresses in the structures, induced during micromachining as well as in the electrical contact layers might be governing low force tuning applications. Thermal tuning also depends very strongly on the device frequency, with the largest spring constant devices showing the least tuning.

Ultimate Limits of Displacement Detection with Flexural and Torsional Resonators Using Magnetomotive Transduction

Micromechanical devices have been incorporated into a wide variety of electronic devices operating at frequencies of 1-100 kHz. Consequently, there exists a host of well-established motion detection techniques suitable for this frequency range. Since nanomechanical devices operating above 100 MHz are expected to play an important role in RF signal processing, it is necessary to thoroughly characterize these techniques in this frequency range. The utility of a particular detection technique relies on three components: (1) the efficient transduction of the motion to a measurable signal, (2) the efficient coupling of that signal to the measurement apparatus, and (3) the availability of a low noise detector. What is needed is some way to quantify the performance of the magnetomotive detection technique in the context of micromechanical resonators.

NEMS Array Scalar Analyzers/Correlators

The concept behind a mechanical array spectrum analyzer is many decades old. In one well known embodiment the analyzer functions through resonant reeds (cantilevers) that are vibrationally or electrostatically driven by an applied time-varying waveform. If the signal contains spectral weight within the band over which a given element can resonantly respond, motion of that specific element results and the amplitude of motion is proportional to the spectral weight in that band. A common application for these devices was as a tachometer, e.g. for rotary machinery, in which case an AC voltage derived from a shaft encoder is used to drive the reed array electrostatically.

Miniature suspended devices can form the basis for extremely sensitive bolometric detectors due to their miniscule heat capacities, very small thermal conductances, and the extremely fast thermal response times that result from these twin attributes. The prior art has used these attributes to demonstrate a microscale MEMS array IR imager. There the elements were read out mechanically; upon absorption of IR radiation, an overlayer provided differential thermal expansion compared to the underlying cantilever devices. The strain induced bending was then detected by a separate optical displacement readout scheme. Other work in this area has been based on thermoelectric voltages induced between different materials patterned atop suspended microscale devices. In this case, although the readout is electrical, the enhanced functionality is still derived from the small (micro scale) nature of the isolated sensing elements.

What is needed is a reinvigoration of such analyzers through access to mechanical response from UHF to microwave frequencies using NEMS technologies, to give the prospect of ultralow operating power levels and the monolithic, ultracompact form.

### BRIEF SUMMARY OF THE INVENTION

Nanoelectromechanical systems, or NEMS, are mechanical devices scaled to submicron dimensions. In this size regime, it is possible to attain extremely high fundamental frequencies while simultaneously preserving very high mechanical responsivity (small force constants) and reasonable quality factors (Q) for the resonant mechanical response. This powerful combination of attributes translates directly into optimal characteristics for mechanical sensing, e.g.
a) high energy, force, and mass sensitivity
b) operability at ultralow power
c) the ability to induce usable nonlinearity with quite modest control forces.

NEMS thus engender electromechanical device applications requiring fast response times; operating frequencies comparable to most of today's purely electronic devices are attainable.

Multiterminal electromechanical devices are possible, i.e. devices that incorporate two-, three-, four-ports. In these, separate electromechanical transducers can provide both input stimuli, i.e. signal forces, and readout of the mechanical response, i.e. output displacement. Hereafter these are termed actuators and (displacement) transducers, respectively. Through additional control transducers, electrical signals—either quasi-static or time-varying—can be applied and converted into quasi-static or time-varying forces that excite or perturb the properties of the mechanical element in a controlled and useful manner. Utilizing different physical processes of electromechanical transduction and actuation allow highly independent interaction between these ports, in effect enabling “orthogonality” between the input, output and possibly multiple control ports. In other words, each port can strongly interact with the mechanical element, while maintaining relatively weak direct couplings to each other. For time-varying stimuli when frequency conversion is the goal, this orthogonality can be provided by a tuned or narrowband transducer response to (frequency-) select input and output signals from control signals, e.g. pump signals.

Transduction Between Signal Domain and Displacement

An output signal in displacement domain can be a static shift, resonant response, modulation of steady-state induced vibration amplitude, modulation of the harmonic content of steady-state induced vibration, or modification of noise spectrum, etc. The following table represents the range of models for transduction:

| | Sensing Modality (relevant |
|---|---|
| Input Signal Domain | responsivity) |
| Energy | energy loss (damping, Q factor) |
| Thermal parameters | increase in thermomechanical noise |
| Force | static displacement (compliance) and/or |
| | resonant displacement (dynamical |
| | compliance) |
| Mass changes | frequency shift (mass responsivity) |

Elements of Nanomechanical Sensors

Compliant Elements

The compliant elements are the mechanical structures scaling down to submicron size which move or are displaced. Due to their extremely small size, they act as efficient probe to the microscopic world. These structures are usually made of semiconductor materials. For example, in this invention, we have used GaAs, Si, SiC, and GaAs/AlGaAs heterostructures. Sometimes, pure metal or metal alloy can be used. The selection of materials depends largely on their electrical, chemical and mechanical properties. Sensor geometry is an important factor in the designing. Finite element simulation is useful in the estimate of the resonant frequency, spring constant, force/mass sensitivity.

Transducers

The structure which produces a piezoelectric, piezoresistive, magnetomagnetic or other transformation from the input signal domain to the sensing modality comprises the transducer. Typically, this is a compositional structural layer or a current path and source for generating a Lorentz-force-derived emf.

Actuators

The structure which produces the mechanical movement of the NEMS device is the actuator, which may be an external current and magnetic field combination for the driving Lorentz force in a magnetomotive transducer, a current generating a dipole field on an adjacent electrode, or even stochastic thermal fluctuations of an ambient fluid.

Nanomechanical Sensor Systems

Sensor systems comprise simple one element systems, or more complex compound-element designs to achieve specific functionality. The sensed electrical signal generated in or the changed electrical parameter of the transducer may be sensed in a bridge, one port, two port or other multiple port combination.

“NEMS” in this specification is used to mean devices with at least one dimension which is equal to or smaller than one micron. It does not exclude the possibility that the “NEMS” device may have one or more other dimensions larger than one micron. Furthermore, as can be understood there is often no sharp line of distinction between the characterization of a device at or below one micron in size and one which is above one micron. The more meaningful significance to the term, “NEMS” that the device in question shares some characteristic with similar devices scaled to submicron sizes or which is unique to submicron devices or operation.

The invention is directed to an apparatus and method which produces a high resolution displacement readout that is based upon our ability to achieve very high mobility suspended quantum wires. Two-terminal sensor impedances as low as 5 kΩ. Molecular beam eptiaxial (MBE) grown materials are directly patterned and in-plane gates (IPG) are used to excite the vibration. No metallization is needed. Hence high Q values can be obtained.

The mechanical parametric amplifier described is a practical solution to the problem of detection sensitivity, as it utilizes the geometric nonlinearity inherent in NEMS.

The invention is more specifically defined as a monolithically fabricated apparatus comprising a doubly clamped, suspended beam with a submicron width having an asymmetrically positioned, mechanical-to-electrical transducing layer fabricated within or on the beam. At least one side drive gate is provided proximate to the beam within a submicron distance.

The asymmetrically positioned, mechanical-to-electrical transducing layer comprises an asymmetrically positioned piezoelectric layer within the beam. The beam is fabricated from a 2 DEG heterostructure.

In one embodiment the beam is provided with electrical contacts and forms a two-terminal circuit with an output terminal, and further comprises an inductor in parallel circuit with the beam and a blocking capacitor coupled to the output terminal of the beam. A low noise cryogenic amplifier is coupled to the blocking capacitor.

The gate is provided with a gate dipole charge separation and the beam is provided with a beam dipole charge separation, so that the beam and gate interacting through the dipole-to-dipole interaction. The side gate includes a 2 DEG layer.

In the illustrated embodiment the beam and side gate comprise a chip and further comprise a substrate on which the chip is disposed, the substrate having an electrode formed thereon, where the gate being provided with a gate dipole charge separation between the electrode of the substrate and the gate. The beam is provided with a beam dipole charge separation, the beam and gate interacting through the dipole-to-dipole interaction.

In one embodiment the beam and gate are fabricated from an asymmetric heterostructure stack comprising a 2 DEG GaAs piezoelectric layer, two sandwiching AlGaAs spacer layers on each side of the GaAs layer, a first and second AlGaAs:Si donor layer above and below the AlGaAs spacer layers respectively, two GaAs cap layers above and below the AlGaAs:Si donor layers respectively. Each of the layers below the 2 DEG GaAs piezoelectric layer is thicker than the corresponding layer above the 2 DEG GaAs piezoelectric layer. An AlₓGa₁₋ₓAs sacrificial layer is disposed under the stack and a substrate disposed under the AlₓGa₁₋ₓAs sacrificial layer, where 0<x<1.

The apparatus may further comprise two gates, each disposed within a submicron distance of the beam and each provided with a gate dipole charge separation.

The apparatus further comprises a source of sensing current supplied to the beam and an amplifier in circuit with the beam to generate an output signal. In the illustrated embodiment the amplifier is cryogenic.

The source of sensing current supplies a DC and AC sensing current to the beam.

In one embodiment transducing layer of the beam is piezoelectric which is used to induce oscillation of the beam, and is also piezoresistive which is used to sense oscillation of the beam.

The invention is still further defined as an improvement in a method of forming a suspended NEMS beam including a two-dimensional-electron-gas layer comprising the steps of providing a heterostructure stack including a 2 DEG layer disposed on a sacrificial layer; selectively disposing a mask on the stack to define a pattern for the NEMS beam; dry etching away exposed portions stack the using a Cl₂/He plasma etch to define the NEMS beam without substantially altering the electrical characteristics of the 2 DEG layer; and etching the sacrificial layer away to release the NEMS beam.

The step of dry etching away exposed portions stack the using a Cl₂/He plasma etch comprises supplying Cl₂ and He gas at a flow rate ratio of 1:9 respectively into an ECR plasma chamber.

The step of supplying Cl₂ and He gas into the ECR plasma chamber further comprises maintaining the stack at or less than 150V self-bias with 20 W constant RF power and ionizing the Cl₂ and He gas with approximately 300 W microwave power or more.

The invention is also a NEMS parametric amplifier comprising: a suspended oscillating submicron signal beam defined in a plane and having a flexural spring constant for in-plane motion and being driven at ω at or near the frequency of mechanical resonance of the signal beam; a pair of pump beams coupled to the signal beam and being driven at or near 2ω; a source of magnetic field applying a field with at least a component perpendicular to the signal beam and pair of pump beams; and a source of alternating current coupled in circuit with the pump beams to apply a current through the pump beams in the presence of the magnetic field to generate a modulated Lorentz force on the pump beams to apply in turn a force oscillating of compression and tension to the signal beam to perturb the flexural spring constant for in-plane motion of the signal beam. An amplifier may be coupled to the beam.

The pump beams and signal beam collectively form an H-shaped structure in the plane, the signal beam forming the middle portion of the H-shaped structure. The pump beams are tuned to resonate at 2ω.

The invention is also a method of operating the NEMS parametric amplifier described above.

The invention is also a submicron cantilever characterized by a submicron displacement comprising a NEMS cantilever having a restriction portion; a piezoresistive strain transducer epilayer coupled to the cantilever; where G is the gauge factor of the apparatus given by

$$G = \frac{3 {βπ}_{L} K ( 2 I - {I}_{1} )}{2 {bt}^{2}} {R}_{T}$$

where the parameter π_{L} is the piezoresistive coefficient of the piezoresistive transducer material, the factor β accounts for the decrease in G due to the finite thickness of the conducting layer, K is the spring constant of the cantilever, l the overlength of the cantilever, l₁ the length of the restriction portion, b the thickness of the restriction portion, t the thickness of the thickness of the restriction portion, and R_{T} is two-terminal resistance of the transducer.

Near resonance, the force spectral density of thermomechanical fluctuations is given by
S_{F}^{γ}=4k_{B}Tγ=4Kk_{B}T/(2πQf₀)
where k_{B} is the Boltzman constant, T is the temperature, γ is the damping coefficient, f₀ is the resonance frequency and Q=mf₀/γ is the quality factor, m is the mass of the cantilever.

Near resonance, the voltage spectral density for the thermomechanical fluctuations is given by

$${S}_{V}^{γ} = \frac{{S}_{F}^{γ} {G}^{2} {I}^{2}}{16 {π}^{2} {m}^{2} {f}_{0}^{2} [ 4 {( f - {f}_{0} )}^{2} + {f}_{0}^{2} / Q ]}$$

where f is the frequency of oscillation of the cantilever.

The invention is a method for scaling and determining carrier distribution in NEMS devices having a doped layer with different doping concentration and different thicknesses disposed on an instrinsic layer comprising the steps of: providing the doped layer with a predetermined thickness; providing a doping concentration in the doped layer; adjusting the Fermi level until charge neutrality is obtained by satisfying the condition
∫₀^{l}(ρ(x)/e+N_{A}⁻(x))dx=0
where

$${N}_{A}^{-} ( x ) = \frac{\# dopants}{\frac{1}{2} {ⅇ}^{- β ( {E}_{A} - ( {E}_{F} - {ɛ}_{V} ) )}}$$

is the density of ionized acceptor sites, where ρ is volume density of carriers given by Fermi statistics, ρ(x)=e(p(x)−n(x)) and positive and negative carrier densities are
p(x)=1.04×10²⁵e^{-β(E}^{_{F}}^{-E}^{_{V}}⁾/m³
n(x)=2.8×10²⁵e^{-β(E}^{_{C}}^{-E}^{_{F}}⁾/m³
where β is 1/kT, E_{F} is the Fermi energy, E_{V} is the energy of the valence band energy, and E_{C} is the energy of conduction band; determining the bending of the valence band according to the equation

$$\frac{{ⅆ}^{2} {E}_{v}}{ⅆ {z}^{2}} = \frac{e ρ ( x )}{ɛ}$$
where E_{V} is the energy of the valence band, ∈ is the dielectric constant, e is the charge of the electron, subject to the boundary condition:

$${\frac{{ⅆ}^{2} {E}_{v}}{ⅆ {z}^{2}} \vert}_{z = 0} = \frac{e σ}{ɛ}$$
where σ is the empirical surface carrier density; and iteratively repeating the foregoing steps of adjusting and determining until convergence is attained for a carrier density, ρ.

The invention is also a bridge circuit comprising: a source of excitation signal; a power splitter coupled to the source to generate two out-of-phase components of the excitation signal; a first actuation port coupled to the power splitter; a second actuation port coupled to the power splitter; a first circuit arm coupled to the first actuation port including a first NEMS resonating beam having an transduced electrical output; a second circuit arm coupled to the second actuation port including a second NEMS resonating beam having an transduced electrical output, the first and second beams being matched to each other; and a detection port coupled to the DC coupling resistance, Rₑ and to the NEMS resonating beam.

The bridge further comprises a variable attenuator and a phase shifter coupled in circuit in opposing ones of the first and second circuit arms. The attenuator balances out impedance mismatch between the first and second circuit arms more precisely than without the inclusion of the attenuator, while the phase shifter compensates for the phase imbalance created by the circuit inclusion of the attenuator.

The NEMS resonating beam includes a surface adapted to adsorb a test material, performance of the NEMS resonating beam being affected by the test material and being measured by the bridge.

The bridge further comprises an amplifier and an output impedance mismatch circuit coupling the detection port to the amplifier. The first and second NEMS resonating beams are magnetomotive NEMS resonating beams and have no metallization.

The invention is still further a method of balancing the output of two NEMS devices in a bridge circuit as described above.

The invention is defined as an apparatus comprising a driving source; a power splitter coupled to the source for generating drive signals of opposing phases; a first magnetomotive NEMS resonating beam coupled to one phase of the drive signal generated by the power splitter; a second magnetomotive NEMS resonating beam coupled to the other opposing phase of the drive signal generated by the power splitter; a terminal electrical coupled to the two magnetomotive NEMS resonating beams; an amplifier coupled to the terminal; and means coupled to the amplifier, the means for measuring the frequency dependence of the forward transmission coefficient S₂₁ of the apparatus.

The first and second magnetomotive NEMS resonating beams are comprised of SiC and which vibrate in an in-plane resonance and in an out-of-plane resonance. An adsorbing surface is disposed on one of the NEMS resonating beams, and adsorption of an adsorbate on the adsorbing surface is measured by the means for measuring.

The invention is a method comprising the steps of providing an excitation driving signal; splitting the excitation driving signal into two out-of-phase components; providing one of the out-of-phase components to a first NEMS resonating beam having a first transduced electrical output; providing the other one of the out-of-phase components to a second NEMS resonating beam having a second transduced electrical output, the first and second beams being matched to each other; vibrating the first and second NEMS resonating beams; summing the first and second transduced electrical outputs together to generated a balanced detected output signal; amplifying the balanced detected output signal in an amplifier; and measuring the frequency dependence of the forward transmission coefficient S₂₁.

The step of vibrating the first and second magnetomotive NEMS resonating beams comprises vibrating the beams at an in-plane resonance and/or at an out-of-plane resonance.

The invention is yet further defined as an improvement in a magnetomagnetically driven submicron NEMS resonating beam comprising a submicron SiC NEMS beam having a surface and an axial length L, width W, Young's modulus E, mass density ρ, and displacement amplitude A; a source of a magnetic field, B; an electrode means disposed on the surface of the beam for conducting current along at least a portion of the axial length of the beam; a source of alternating current coupled to a first end of the electrode means to magnetomotively drive the SiC NEMS beam to a resonant frequency

$${f}_{0} = \sqrt{\frac{E}{ρ}} \frac{W}{{L}^{2}} ;$$

and a detector coupled to a second end of the electrode means to detect a generated Vemf from the SiC NEMS beam of

$${V}_{emf} ∝ B A \sqrt{\frac{E}{ρ}} \frac{W}{L} .$$

The electrode means comprises a single electrode coupled to the source of alternating current for driving the beam in the magnetic field and is coupled to the detector for sensing the EMF generated in the electrode by motion of the beam.

The electrode means comprises a first electrode coupled to the source of alternating current for driving the beam in the magnetic field and a second electrode coupled to the detector for sensing the EMF generated in the electrode by motion of the beam.

The SiC NEMS beam has dimensions and parameters providing a fundamental resonance frequencies in the UHF range and higher and in particular in the microwave L band.

The invention is a method of tuning a submicron NEMS device having an out-of-plane resonance comprising providing a magnetic field in which the NEMS device is positioned; supplying an AC current to the NEMS device to oscillate the NEMS device in the magnetic field at a resonant frequency; supplying a DC current to the NEMS device to tune the out-of-plane resonant frequency of the NEMS device with a constant Lorentz force.

The step of supplying a DC current to the NEMS device comprises supplying a DC current to the metallization.

The NEMS device also has an in-plane resonance and the method further comprises the step of varying the temperature of the NEMS device to tune both the out-of-plane and in-plane resonance of the NEMS device.

The invention is also a tunable submicron NEMS device having an out-of-plane resonance which is tuned by the above method. The NEMS device comprises a semiconductor-metal bilayer formed of a single crystalline highly doped semiconductor and the metallization disposed thereon is a polycrystalline metal to reduce stresses in the semiconductor-metal bilayer.

The invention is characterized as an improvement in a resonating submicron one-port NEMS device comprising a resonating beam having a width w, a thickness t, a length L, a detector load resistance R_{L}, an equivalent mechanical impedance Rₘ, operating a frequency corresponding to the wavelength λ with an electrode on the beam with a conductivity of σ such that the insertion loss ε defined as:

$${ɛ}_{1} = \frac{{α}^{2}}{( 1 + α ) ( 1 + α + \frac{{R}_{m} λσ tw}{L} )} where α = \frac{λσ {R}_{L} tw}{L}$$

is minimized or near unity.

The invention is an improvement in a resonating submicron two-port NEMS device comprising a resonating beam having a width w, a thickness t, a length L, a detector load resistance R_{L}, an equivalent mechanical impedance Rₘ, operating a frequency corresponding to the wavelength λ with an electrode on the beam with a conductivity of σ such that the insertion loss ε defined as:

$${ɛ}_{2} = \frac{1}{2} {{α}^{\frac{1}{2}} ( \frac{1 - α}{1 - .75 α} )}^{\frac{1}{2}} where α = \frac{λσ {R}_{L} tw}{L}$$

is minimized or near unity.

The invention is an improvement in a two-port, straight, doubly clamped NEMS magnetomotive beam coupled to an amplifier with a load resistance R_{L}, the NEMS beam having a length L, a thickness t, a width w, Young's modulus E, mass density ρ, in a magnetic field B, with a conductivity σ of its metallization, a temperature T, a driving signal wavelength of λ, a resonant frequency of f₀, an amplifier spectral power density S^{a}_{V}, chosen so that the spectral displacement sensitivity S^{m}_{X(2)} is equal to or greater than the spectral displacement density corresponding to thermal fluctuations of the NEMS beam, which spectral displacement sensitivity S^{m}_{X(2)} is defined as

$$\sqrt{{S}_{X ( 2 )}^{m}} = \frac{1.68}{{σ}^{\frac{1}{2}} {λ}^{\frac{1}{2}} B} {( \frac{ρ}{E} )}^{\frac{1}{8}} {f}_{0}^{- \frac{3}{4}} {t}^{- \frac{3}{4}} {{w}^{- \frac{1}{2}} [ {k}_{B} T + \frac{{S}_{V}^{a}}{{R}_{L}} ( \frac{1 - 0.75 α}{1 - α} ) ]}^{\frac{1}{2}}$$

where k_{B} is the Boltzman constant and

$$α = 0.99 {R}_{L} {σλ ( \frac{ρ}{E} )}^{\frac{1}{4}} {f}_{0}^{\frac{1}{2}} {t}^{\frac{1}{2}} w .$$

The invention is a method for fabrication of a NEMS beam from a Si membrane comprising the steps of: providing a Si substrate; disposing a SiO₂ layer on the Si substrate; disposing a Si epilayer on the SiO₂ layer; selectively anisotropically etching away a portion of the Si substrate down to the SiO₂ layer used as a stop layer; selectively etching away a portion of the SiO₂ layer to expose a suspended Si epilayer membrane; and forming the NEMS beam in the suspended Si epilayer membrane, whereby capillary distortion is avoided and electron beam resolution is achieved without proximate scattering from a substrate.

The invention is a method for fabrication of a NEMS beam from a GaAs membrane comprising the steps of providing a GaAs substrate; disposing an AlGaAs layer on the GaAs substrate; disposing a GaAs epilayer on the AlGaAs layer; selectively anisotropically etching away a portion of the GaAs substrate down to the AlGaAs layer used as a stop layer; selectively etching away a portion of the AlGaAs layer to expose a suspended GaAs epilayer membrane; and forming the NEMS beam in the suspended GaAs epilayer membrane.

The step of selectively anisotropically etching away a portion of the GaAs substrate down to the AlGaAs layer used as a stop layer comprises etching with a NH₄OH or citric acid solution. The step of etching with a NH₄OH solution comprises etching with a solution comprised of NH₄OH and H₂O₂ in the volume ratio of approximately 1:30, freshly mixed prior to etching.

The step of etching with a citric acid solution comprises etching with a room temperature bath comprised of citric acid monohydrate mixed and completely dissolved in a 1:1 mixture with deionized water by weight, then mixing this 1:1 mixture in a 3:1 volume ratio with H₂O₂ to provide the bath.

The invention is a NEMS array analyzer comprising two opposing parallel substrates; a plurality of piezoresistive NEMS cantilevers extending from one of the substrates, each of the NEMS cantilevers having a different resonant frequency so that the corresponding plurality of resonant frequencies covers a selected spectral range; and a plurality of drive/sense elements extending from the other one of the substrates, each of the drive/sense elements primarily coupled with one of the plurality of piezoresistive NEMS cantilevers.

The invention is a NEMS array analyzer comprising a frame; a plurality of NEMS structures forming an interacting array to form an optical diffraction grating; means for driving the plurality of NEMS structures in response to an input signal; and light source for illuminating the plurality of NEMS structures; and detector means for detecting diffracted light from the plurality of NEMS structures acting collectively as a time-varying diffraction grating.

The invention is a NEMS electronic chemical sensing array comprising a plurality of strain-sensing NEMS cantilevers, each having an overlayer disposed thereon which is responsive to a corresponding analyte, the response of the overlayer imposing a strain on the corresponding cantilever; and means for detecting the strain of each of the plurality of strain-sensing NEMS cantilevers. The response of the overlay comprises expansive or contractile volume changes of the overlay causing a strain to be imposed on the corresponding cantilever to cause it to bend, and where the means for detecting comprises an optical detector array for determining the amount of bending of each cantilever. The response of the overlay comprises a mass loading resulting in a change in total inertial mass of each corresponding cantilever and where the means for detecting comprises means for detecting changes in resonant frequency shifts for each cantilever.

The invention is a NEMS infrared sensing array comprising: two opposing parallel substrates; a plurality of identically sized piezoresistive NEMS cantilevers extending from one of the substrates, each of the cantilevers being provided with a corresponding IR absorber responsive to a different IR frequency and inducing a corresponding differential thermal expansion of each cantilever depending on the amount of IR absorbed by each IR absorber; and a plurality of drive/sense elements extending from the other one of the substrates, each of the drive/sense elements primarily coupled with one of the plurality of piezoresistive NEMS cantilevers.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIG. 1a is a graph of the energy band level in a heterostructure as shown in FIG. 1b at different points in the thickness, t.

FIG. 1b is a side cross-sectional diagram illustrating the stack in which the NEMS device of the invention is built.

FIG. 2 is a cross-sectional schematic of the dipolar actuation mechanism of the invention, showing dipole formation on the beam between p₁ of the beam and dp₂ and on the driving gate.

FIG. 3(a) scanning electron microscope image of a doubly clamped beam used in the invention. The in-plane gates are formed by the 2DEG.

FIG. 3b is a schematic of the measurement setup.

FIG. 3c is a simplified side cross-sectional view of an ECR chamber used in the plasma etching step of the invention.

FIG. 3d(i)-(v) is a series of perspective views illustrating the steps of fabricating the 2DEG used in the heterostructure of FIG. 1b.

FIG. 4a is a graph of the voltage drop across the beam verses frequency as it is driven to its lowest mechanical resonance with increasing drive amplitudes. The DC bias current is fixed at 5 μA. In the inset the peak value of amplitude response is shown as a function of driving amplitude in the linear regime.

FIG. 4b is a graph the magnitude response curve verses frequency at various DC bias currents. In the inset the signal amplitude at resonance with a sensing current increase form −26 μA to 26 μA.

FIG. 5 is a graph of the magnitude response curve verses frequency at various temperatures.

FIG. 6 is a microphotograph of the mechanical preamplifier fabricated by surface nanomachining of a 200 nm thick layer of silicon carbide on silicon. The metallic electrodes are patterned from a 50 nm thick layer of Au.

FIG. 7 is a diagram which illustrates the operational principals for the all-mechanical parametric amplifier. The signal electrode is used for excitation and detection of the signal beam, while the pump electrode modulates its flexural spring constant.

FIG. 8 is a circuit schematic of the circuit employed for gain measurements for the parametric amplifier in the illustrated embodiment.

FIG. 9 is a graph of the frequency shift Δf/f as a function of transverse DC force applied to the pump beams. The force is effectively a compressive (positive) or tensile (negative) force on the signal beam. The linear component of frequency shift results from this force, while the quadratic component results from ohmic heating due to current in the pump beams.

FIG. 10 is a diagram of a finite element simulation of the parametric amplifier under a static load of 1 nN applied to the pump beams arising from the compressive or tensile force on the signal beam described in FIG. 9. The compression of the signal beam is 0.235 times what would be expected if the pump beams were not present and the load were applied directly to the ends of the signal beam.

FIG. 11 is a graph showing the dependence of the gain on the phase difference between signal and pump excitation. Depending on the phase, the signal is either amplified or de-amplified. As expected, the magnitude of both amplification and de-amplification increases for stronger magnetic fields.

FIG. 12 is a graph of the response of the signal beam to excitation at frequencies off-resonance, with the pump beams driven at twice the resonance frequency. The plot shows the strength of the sideband at ω. The device bandwidth is reduced dramatically for pump excitations near threshold.

FIG. 13 is a graph of the amplification of thermomechanical noise. At the pump voltage of 8.2 mV, the φ=0 gain is 39, and the quality factor of the resonance is increased from 10600 to 180000.

FIG. 14 are phasor plots of the output noise for the parametric mechanical amplifier. The top left plot shows the lock-in amplifier measurement of the signal beam with no excitation, and no pump. This displays the phase-independent input noise of the amplifier. The top right plot shows the measurement of the signal beam with no excitation and 5 mV pump voltage. The fluctuations are still dominated by the electrical amplifier. The bottom left plot shows the measurement of the signal beam with no excitation and pump voltage of 8.1 mV. Thermomechanical fluctuations are amplified beyond the amplifier input noise in one quadrature. In the other quadrature, the effect of the pump is not seen.

FIG. 15 is a graph which provides a comparison of gain with the noise level in each quadrature, normalized to the values with pump off. The effect of the pump is to increase the signal-to-noise ratio, especially with respect to the φ=π/2 quadrature.

FIG. 16 is a graph which shows the dependence of the gain on the voltage applied to the pump. At low pump amplitudes, the gain is independent of the excitation of the signal beam. At high pump voltages, the gain begins to saturate when the rms amplitude of motion reaches 360 pm.

FIG. 17 is a graph of the carrier distribution for a sample of 130 nm thickness in which the dopant layer is 30 nm thick and the dopant concentration is 4×10²⁵ m⁻³.

FIG. 18 is a graph of the carrier distribution for a sample of 30 nm thickness in which the dopant layer is 7 nm thick and the dopant concentration is 4×10²⁵ m⁻³.

FIGS. 19a, 19, 19c and 19d are directed to magnetomotive reflection and bridge measurements. FIG. 19a is a schematic diagram illustrating the magnetomotive reflection and FIG. 19b is a schematic diagram illustrating bridge measurements. FIG. 19c is a scanning electron microscope (SEM) micrograph of a representative bridge device of FIG. 19b. FIG. 19d is a schematic illustration of the reflection and bridge arrangements, showing perspective views of the single and balanced beam configurations respectively.

FIG. 20a is the graph of a doubly-clamped, B-doped Si beam resonating at 25.598 MHz with a Q about 3×10⁴ measured in reflection in the upper curves and in bridge configurations for magnetic field strengths of B=0, 2, 4, 6 T in the lower curves. FIG. 20b is a graph of the amplitude of the broadband transfer functions for both reflection and bridge configurations.

FIG. 21 is a graph of the amplitude of transmission coefficient (S₂₁) measured from SiC beams in the bridge configuration for different magnetic field strengths of B=2, 4, 6, 8 T.

FIGS. 22a-22d are SEM micrographs of one embodiment of the device. FIG. 22a is a top plan view. FIG. 22b is a plan side view. FIG. 22c is an enlarged top plan view of one of the beams. FIG. 22d is an enlarged side plan view of one of the beams showing clear suspension of the mechanical structure.

FIG. 23 is a schematic drawing of measurement setup.

FIG. 24 is a three-dimensional graph of the frequency dependence of the forward transmission coefficient S₂₁ of the network under study. The insert shows the projection of the complex function onto the S₂₁ plane.

FIG. 25 is a graph of the signal amplitude referred back to the input of the pre-amplifier. This is obtained by taking modulus after subtracting the background function from the raw data, see text for the procedure of subtraction.

FIG. 26 is a SEM photograph showing a top plan view of the device used to illustrate high frequency tuning.

FIG. 27 is a graph of measured resonances vs. aspect ratios of Si and GaAs beams.

FIG. 28 is a graph of the out of plane frequency shift of a GaAs Beam with applied Lorentz force.

FIG. 29 is a graph of the frequency shift as in FIG. 28 plotted as a function of applied force.

FIG. 30 is a graph of the Lorentz Force tuning for the in plane direction.

FIG. 31 is a graph of the frequency shifts in FIG. 29 plotted as a function of the tuning force.

FIG. 32 is a graph of the temperature shifts of the two modes of a beam.

FIG. 33 is a graph of the temperature dependence of the resonance frequencies of three Si beams.

FIG. 34 is a graph of the temperature dependence of the resonance frequencies of four GaAs beams.

FIG. 35 is a graph of the corrected data for FIG. 29.

FIG. 36 is a schematic of an equivalent circuit for a mechanical resonance.

FIG. 37 is a schematic for an one-port drive and detection circuit.

FIG. 38 is a schematic for an equivalent circuit for one-port measurement.

FIG. 39 is a schematic for an equivalent circuit for a two-port detection circuit.

FIG. 40 is a simplified top views of representative designs for flexural (left) and torsional (right) resonators.

FIG. 41 is a graph of the sensitivity of the two-port magnetomotive detection technique as a function of frequency, compared to thermomechanical noise.

FIG. 42 is a graph of the input noise level required of a 50 Ω amplifier for magnetomotive sensitivity limited by thermomechanical noise, as a function dof the conductivity of the electrode.

FIGS. 43a-43d are side cross-sectional views of a method of fabricating Si membranes using bulk micromachining.

FIGS. 44a-44d are side cross-sectional views of a method of fabricating GaAs membranes using bulk micromachining.

FIGS. 45a and 45b are SEM pictures of wells etched in GaAs with NH4OH: FIG. 45a shows a tilted view from backside, cleaved along [011] plane, FIG. 45b shows a face-on view of [011] plane. Note the smooth, well defined sides and bottom.

FIGS. 46a and 46b are SEM pictures of wells etched in GaAs with citric acid: FIG. 46a shows a tilted view from backside, and FIG. 46b shows a plane cleaved along the [011] plane. Note the inhomogeneity of descending walls and the roughness of floor surface. The dashed line represents the [011] cleave plane.

FIG. 47 is a simplified perspective diagram of a NEMS array based power spectrum analyzer. Elements within the array are electrostatically actuated by local stubs protruding along a common transmission line electrode. Each resonant element is separately read out piezoresistively. The element lengths are staggered, as in a vibrating reed tachometer, to provide coverage over a desired spectral range.

FIG. 48 is a diagrammatic depiction of a NEMS array spectrum analyzer based upon the collective modes arising in a coupled array. The signal is applied to the entire array, but readout is optical, and involves simultaneous resolution of the diffracted orders using a photodiode array.

FIG. 48a is an enlarged SEM photo of the array of FIG. 48.

FIG. 49 is a diagrammatic depiction of a NEMS array based electronic nose in which resonant sensors used to monitor mass loading and changes in surface strain induced by chemical or biochemical adsorbates.

FIG. 50 is a diagrammatic depiction of a NEMS array based uncooled IR imager. An array of resonant sensors is used to monitor out-of-plane flexure arising from absorption of IR energy. Local radiation induced heating of the IR absorbers results in differential thermal expansion between the absorbers and the cantilevers. The common electrostatic bias/drive connection provides a local dc electrostatic bias and a common ac drive electrode for swept frequency interrogation of the array.

FIG. 51a is a scanning electron microphotograph of a piezoelectric cantilever. The dimensions of the device are 15 μm in length, 2 μm in width and 130 nm thickness of which the top 30 nm forms the conducting layer (with a boron doping density of 4×10¹⁹/cm³). For this device b=0.5 μm and l₁=4 μm.

FIG. 51b is a graph of cantilever displacement as a function of time, studied using an atomic force microscope tip to move the cantilever a known amount. This yields a direct measurement of G=dR_{T}/dx=3×10⁷ Ω/m.

FIG. 51c is a graph of cantilever resistance as a function of time corresponding to FIG. 51b, studied using an atomic force microscope tip to move the cantilever a known amount. This yields a direct measurement of G=dR_{T}/dx=3×10⁷ Ω/m.

FIG. 52 is a graph of the nanomechanical resonance peak in vacuum. The dependence of the quality factor on pressure is shown in the inset. A bias current of 102 μA was used for these measurements.

FIGS. 53a and 53b is a graph of the 9K measurement of thermomechanical noise.

FIGS. 54a-54c are diagrammatic side cross-sectional views of scaled piezoresistive structures in which the scaling has been augmented with additional semiconductive layers to confine the carriers in a quantum well.

FIG. 55 is a diagrammatic side cross-sectional views of scaled piezoresistive structures in which the scaling has been augmented with a quantum well disposed on an insulator.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

Doubly Clamped Beam

Doubly clamped beams from GaAs/AlGaAs quantum well heterostructure containing a high-mobility two-dimensional electron gas (2DEG) is disclosed which applies an IT-drive to in-plane side gates to excite the beam's mechanical resonance through a dipole-dipole mechanism. Sensitive high frequency displacement transduction is achieved by measuring the A.C. EMF developed across the 2DEG in the presence of a constant D.C. sense current. The high mobility of the incorporated 2DEG provides low-noise, low power, and high gain microelectromechanical displacement sensing, through combined piezoelectric and piezoresistive mechanisms.

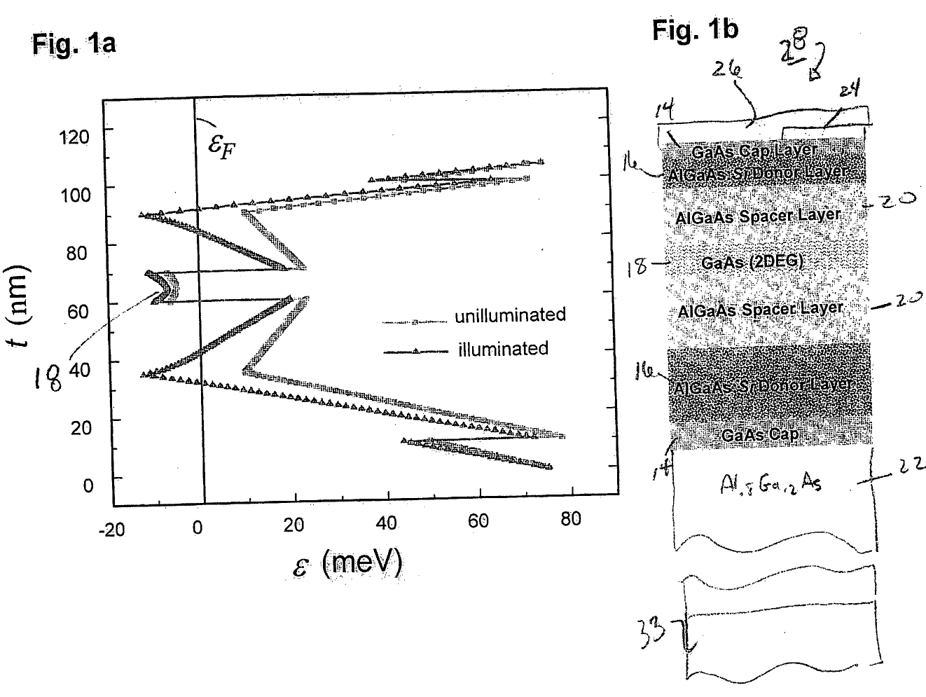

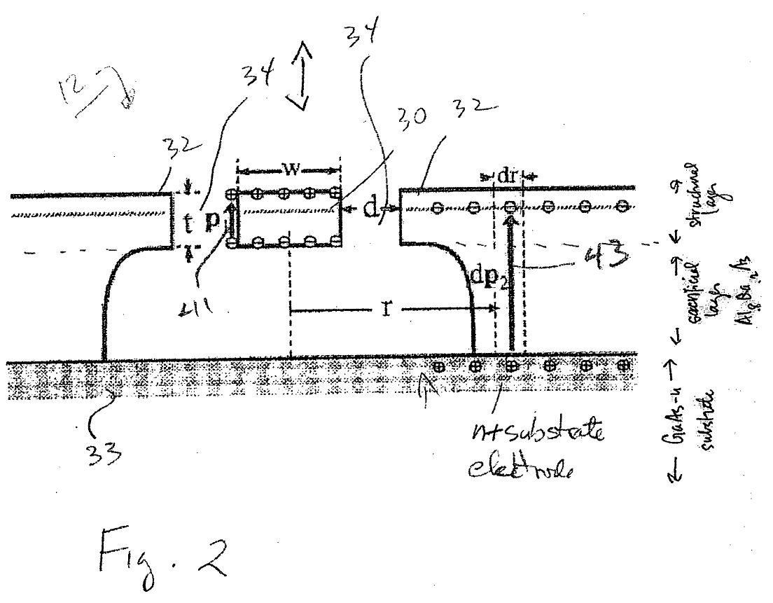

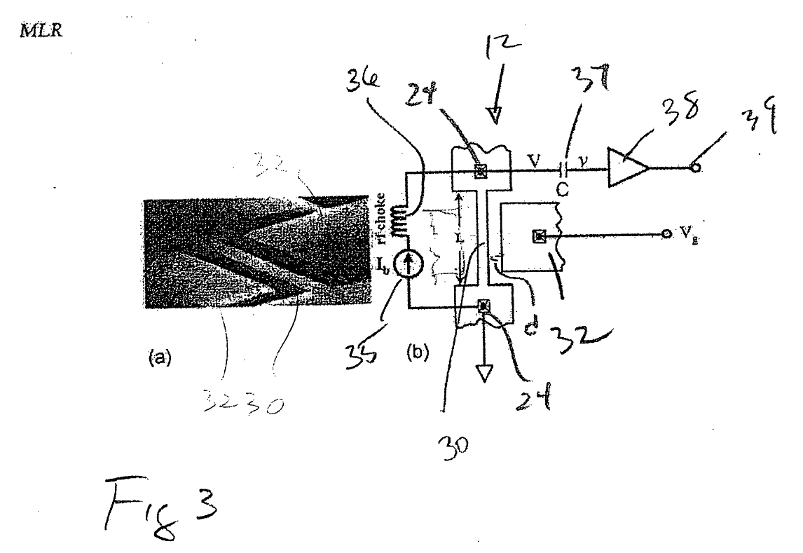

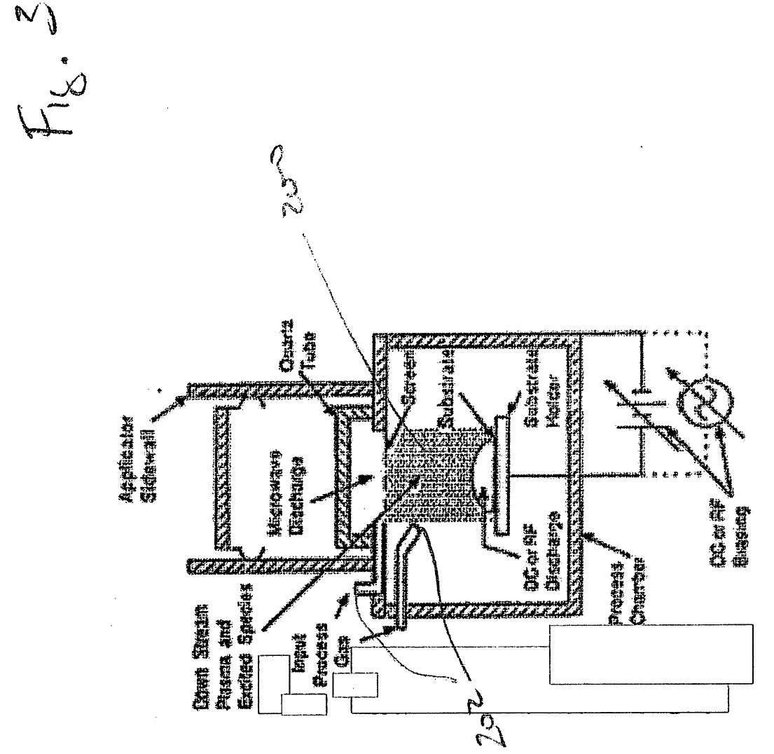

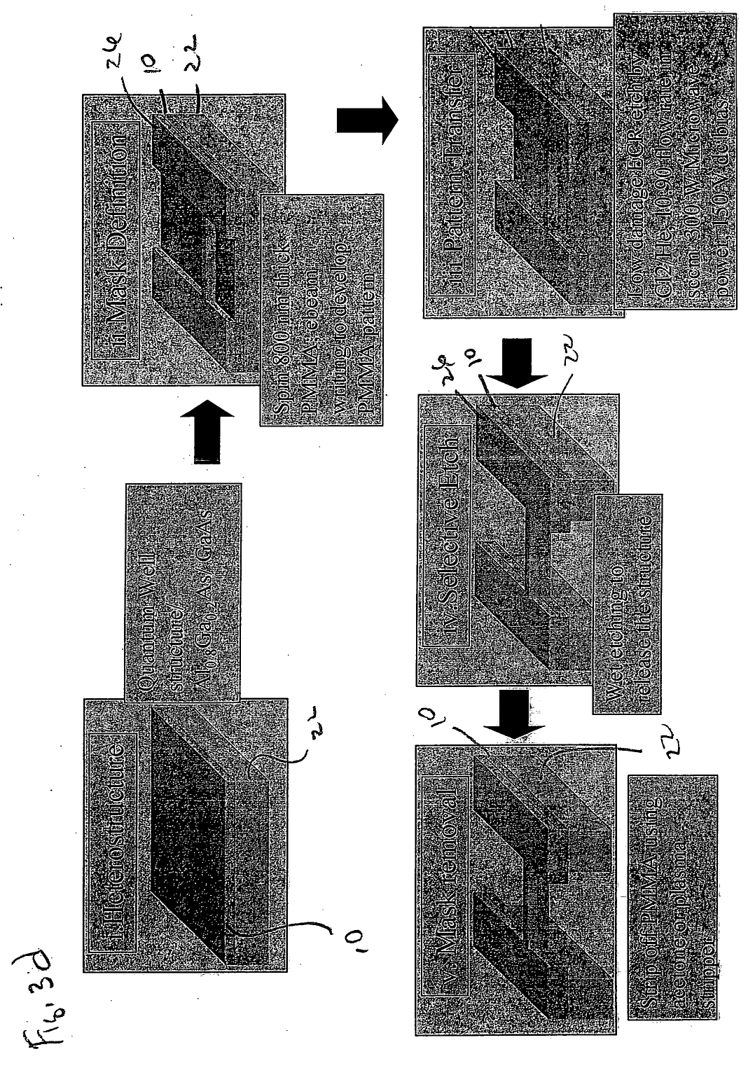

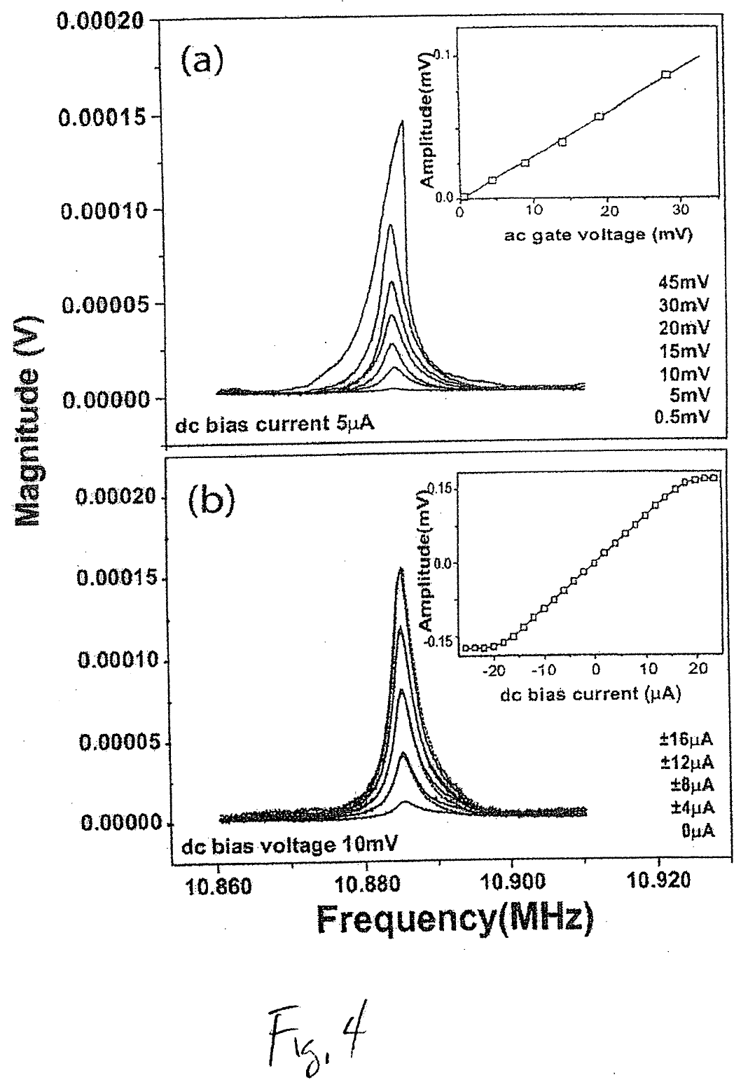

A beam 30 is formed between two gates 32 to collectively comprise a device 12 as shown in FIG. 2 and in the microphotograph of FIG. 3. The starting material was a specially designed, MBE-grown two dimensional electron gas (2DEG) heterostructure. The structural layer stack, generally denoted by reference numeral 10, from which the devices 12 of FIG. 2 are formed, comprises seven individual layers having a total thickness of 115 nm as shown in FIG. 1b. The top and bottom layers 14 are thin GaAs cap layers preventing oxidation of the AlGaAs:Si donor layers 16 in between. The central 10 nm-thick GaAs layer 18 forms a quantum well sustaining a high mobility two dimensional electron gas (2DEG) located 37 nm below the top surface and surrounded by two AlGaAs spacer layers 20. Below the structural layer stack 10 is a 400 nm Al_{0.8}Ga_{0.2}As sacrificial layer 22. Sacrificial layer 22 in turn is disposed on an even thicker n+ substrate which provides a back electrode and mechanical support for chip 28.

FIG. 1a is an energy level diagram for the heterostructure of FIG. 1b. The thickness or position, t, within stack 10 is shown on the vertical scale with the energy level, ε, in MeV on the horizontal scale. The Fermi energy ε_{F}, is taken as the zero energy level. With the exception of a small amount of conduction in some sidebands, most of the electron conduction is confined to the 2DEG layer 18.

Note that the stack structure 10 was intentionally made asymmetric to avoid neutralizing the piezoelectric effect of GaAs layer 18, i.e. layer 18 is not in the center of the stack 10, but is fabricated to lie to one side of stack 10. As a result, layer 18 will be subjected to only tension or only compression along with the stretched or compressed layers on its side of the stack 10 as the stack is strained. The stack 10 and sacrificial layer 22 comprise the chip 28. In fact the fabrication of overlying passivating or other layers on layer 18 gives rise to a built-in strain without the imposition of external forces.

After ohmic contacts 24 are deposited, a thick layer 26 of PMMA is spun on the chip 28, followed by a single electron-beam lithography step to expose trenches 34 in PMMA layer 26 that isolate the beam 30 from its side gates 32 as shown in FIG. 2. PMMA layer 26 is then employed as a direct mask against a low voltage electron cyclotron reactor (ECR) etch performed to further etch the trenches 34 to the sacrificial layer 22. After stripping off the PMMA layer 26, the final structure of FIG. 2 relief is achieved by removing the sacrificial layer 22 beneath the beam 30 with diluted HF.

To minimize the damage to the 2DEG layer 18 from dry etching, significant efforts have been expended to optimize the etching process. After experimenting with numerous plasma mixtures, a Cl₂/He plasma was chosen because of its excellent etching characteristics such as smooth surface morphology and vertical sidewall without attacking the PMMA thus leaving a well defined mask edge. A stable etching speed at 35 Å/s is obtained in an otherwise conventional ECR chamber diagrammatically depicted in cross-sectional view in FIG. 3c. Cl₂ and He gas supplied at volume flow rate (sccm) ratio 1:9 respectively through orifices 202 to a plasma chamber 200 which has been partially evacuated to 3 mTorr and the gases are ionized by 300 W microwave power to etch the trenches 34 in FIG. 2 to define beam 30 while the chip 28 has 20 W of constant RF power at 150 V applied to it.

The process is further illustrated in FIG. 3d. At step i the stack 10 including the quantum well structure comprised of the Al_{0.8}Ga_{0.2}As/GaAs sandwich of FIG. 1b is supplied on sacrificial layer 22. At step ii a 800 nm thick PMMA mask 26 is spun onto the surface of stack 10 and patterned using electron beam lithography to form the outline of what will become the doubly clamped beam 30 and side gates 32 (formation of the gates 32 is omitted from FIG. 3d for the sake of simplicity). At step iii the low damage ECR etch described above is performed to transfer the PMMA pattern into the underlying stack 10. At step iv a selective wet etch is performed to preferentially remove the exposed portions of sacrificial layer 22. At step v PMMA mask 26 will be stripped off using acetone or a plasma etch.

To demonstrate that the etching process does not affect the 2DEG layer 18, we have also fabricated suspended Hall effect bars with the same method and extensively characterized the suspended 2DEG that results. Before processing, the initial mobility and density after illumination are 5.1×10⁵ cm²/Vs, 1.26×10¹² cm⁻² respectively. With our improved low damage etching, the mobility can be maintained at 2.0×10⁵ cm²/Vs, while the electron density is somewhat reduced to 4.5×10¹¹ cm⁻². We observed well-developed quantum Hall plateaus in the etched structure even with channel width as small as 0.35 μm. In longitudinal resistance measurements, we detected a low field maximum, corresponding to maximal boundary scattering when the electron cyclotron motion diameter matches the electrical width of the suspended wire. From the position of this peak, we are able to deduce the depletion to be 0.1 μm on each side of the wire. We also confirmed ballistic behavior of electrons from transport measurement on the Hall cross-junction. Both “last Hall plateau” and “negative bend resistance” are present in all of the devices 12. The transport mean free path was found to be approximately 2 μm.

In nanoelectromechanical (NEMS) system, both the induction and the detection of motion pose material challenges. In devices 12 of FIG. 2, the actuation is relatively easy and very effective. An RF-drive is supplied directly to one or both of the side gates 32, which is a large area of 2DEG connected to the output of a network analyzer (not shown) through an alloyed ohmic contact 24 in FIG. 1. Inducing the out-of-plane vibration of beam 30 through one or more side gates 32 is unique. Since the gate-to-beam separation, d, can be as narrow as 100 nanometers, a small driving amplitude proves sufficient. In the illustrated embodiment, all the trenches 34 have a constant width of 0.5 μm. The devices 12 are first measured at 4.2 K in vacuum. A constant DC sensing current ranging from 0 to 26 μA is supplied to the vibrating beam 30 through a 10 mH RF-choke 36, whose value is chosen big enough to avoid loss of the small signal that is induced. The oscillatory signal is picked up by a low temperature amplifier 38 placed close in proximity to the device 12, whose output is led out of the cryostat in which device 12 is immersed through a coaxial cable 39. Before connecting the signal to the input of network analyzer, a room temperature amplifier (not shown) may be used to improve the signal-to-noise ratio. The combined amplifiers have a voltage gain of about 200 in the frequency range of the illustrated experiments.

A typical completed device 12 is shown in the microphotograph of FIG. 3a and is schematically depicted in FIG. 3b. A constant DC bias current (l_{b}) from current source 35 is sent through a large RF-choke 36 (about 10 mH) before reaching the beam 30. Gate drive voltage applied to gate 32 consists of both DC and RF components: Vg=V_{g}⁽⁰⁾+v_{g}^{iωt}. The induced signal can be expressed as V=V⁽⁰⁾+ve^{i(ωt+φ)}, where the DC voltage potential V⁽⁰⁾=I_{b}R_{dc} is blocked by a capacitor 37, C, and the oscillating component is amplified at both liquid helium and room temperature. The beam 30 is 0.5 μm wide and 6 μm long, having a calculated spring constant of 0.25 N/m. When cooled to liquid helium temperature, their two-terminal resistance is about 100 kΩ. After illumination, this drops to about 5 kΩ. The electrical width of the beam 30 is about 0.3 μm with R=170 Ω.

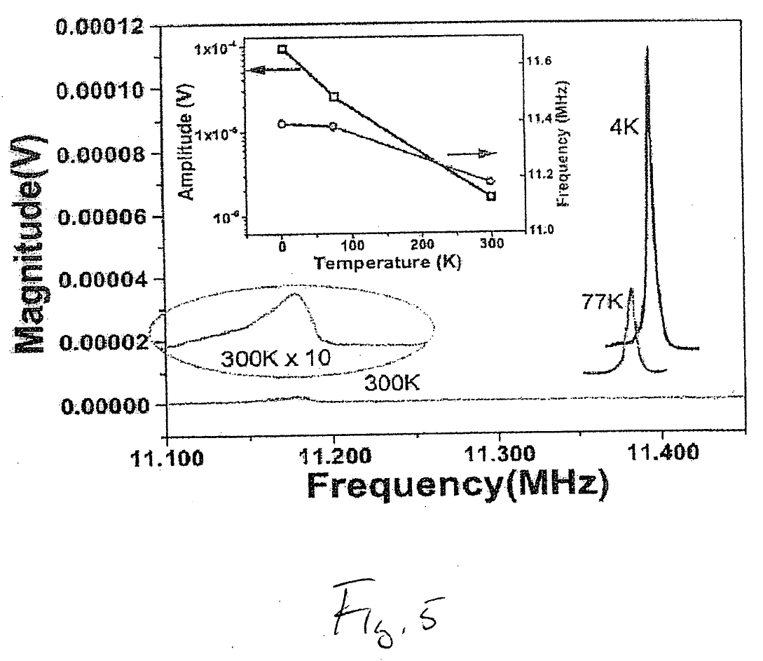

We observed very strong vibration signal around a first mechanical resonance. The magnitude response curves at various driving amplitudes are shown in FIG. 4a, which is a graph of output voltage magnitude verses frequency. Calculations confirm that this resonance corresponds to the first out-of-plane vibrational mode, i.e. out of the plane in which the beam normal lies. When the drive amplitude is increased above 45 mV, the response curve becomes nonlinear and assumes an asymmetric Lorentzian shape. In the linear response region, the amplitude at resonance is proportional to the AC gate voltage amplitude as shown in the inset graph of FIG. 4a.

To clarify the origin of the observed signal, we fixed the gate drive at 10 mV and then varied the DC bias current from −26 μA to 0 then to 26 μA. The response amplitude verses the drive amplitude at resonance is presented in FIG. 4b. Two features are evident from this data. First, at the highest currents close to 20 μA, the signal becomes saturated for two reasons: (a) Joule-heating of the small beam 30, and (b), saturation of the drift velocity at such high applied electrical field (about 15 kV/m). Second, at intermediate current, the signal strength at resonance is proportional to the DC bias current, as indicated in the inset of FIG. 4b. In addition, when we reverse the current direction, we also find that the induced signal changes its sign (180 degree phase change).

Therefore we conclude that the dominant contribution to the observed signal is a change of resistance due to beam vibration. This appears to originate from both the piezoresistive effect of bulk GaAs and transverse piezoelectric charge gating of 2DEG. Note that a small signal is observed even for zero current bias. From the slope of the linear part in the inset of FIG. 4b, a nominal drive of 10 mV induces a resistance change of about 100 in the device 12. The piezoelectric property of the beam 30 is used to induce oscillation of the beam, while its piezoresistive property is used for sensing oscillation.

We now estimate the sensitivity of this technique. By looking at the critical amplitude at the onset of nonlinearity, we can determine the amplitude of vibration of the resonating beam 30. This critical displacement amplitude depends only on the geometry of the beam 30, and is approximately given as

$${x}_{c} ∼ \frac{2 h}{\sqrt{0.5 Q ( 1 - {v}^{2} )}} \qquad ( 1.1 )$$

where h is the thickness of the beam in the vibration direction, and v is the Poisson's ratio for GaAs. Plugging in measured values of Q=2600 and v=0.31, we obtain x_{c}=6 nm, which is attained at a drive level of about 45 mV. The minimum resolvable signal is achieved at 0.1 mV drive and about 5 μA sensing current. Hence, at the highest possible current of 20 μA, we can detect a resonance at x₀/450/4=0.03 Å, or 3×10⁻³ Å/√Hz, which is consistent with our estimate based on Johnson noise from beam resistance at 4.2K. The corresponding force sensitivity is 75 fN/√Hz, which is comparable with previous schemes to detect small NEMS resonators or transducers by optical interferometry and the magnetomotive method. The required force to drive the beam to nonlinearity threshold is 1.5 nN. The displacement resolution can be improved by using 2DEG heterostructures with even higher mobility, or by operating at about 100 mK with a state-of-the-art low temperature preamplifier.

Note that in FIGS. 4a and 4b all the driving force we applied corresponds to an applied AC gate voltage. We did not find any significant change of resonant frequency or magnitude with DC bias on the gate. This is indicative of a coupling mechanism different from electrostatic force between the gates 32 and the beam 30. Electrostatic force is proportional to the product of DC and AC components of gate potential so that the response should directly scale with the DC gate voltage. This assumes a direct Coulomb interaction between coupling plates. In our in-plane-gate configuration, the net charge on the beam is C (V_{g}⁽⁰⁾+v_{g}e^{iωt}) where V_{g}⁽⁰⁾ is the DC signal magnitude, v_{g} is AC signal magnitude and C is the capacitance between coplanar 2DEG areas at the gates 32 which has an estimated value of 18 aF/μm, which is very small compared to parallel plates. With a nominal 1 V DC gate voltage, there are only a few hundred induced electron charges on the beam 30. The upper bound of the electric field applied on the gate is (V_{g}⁽⁰⁾+v_{g}e^{iωt})/d, where d is the beam-to-gate separation distance as shown in FIG. 2. Thus the total electrostatic force applied on the beam 30 with angular frequency ω is f=C V_{g}⁽⁰⁾ v_{g}e^{iωt} y₀/d² where yₒ is a static offset. Only a projection of this force drives the beam along the out-of-plane (z) direction perpendicular to the plane of the drawing of FIG. 3b. A reasonable estimate of the effective z-component of this force is,
f_{y}=CV_{g}⁽⁰⁾v_{g}e^{iωt}y₀/d² (1.2)
where yₒ is a static offset due to, e.g., uncontrolled asymmetry of suspended beam 30. A 10 nm misalignment of the beam 30 with respect to gate 32 should be observable in devices 12 but was not seen. Therefore, we take this number as the upper limit of in the estimation of y₀. At a nominal 1V DC gate voltage, 45 mV AC gate voltage, the force originating from the electrostatic drive mechanism is calculated to be fy=0.2 pN. This is four orders of magnitude smaller than the force required to drive the beam 30 into non-linear response.

For a suspended beam with strictly symmetric structural heterostructure, the static net stress is zero. Therefore in this case, the dipole-dipole actuation is a second order effect. Build-in strain in this heterostructure is induced by an intentionally designed asymmetric quantum well structure layer. Alternatively, by making bimorph structure that contains piezoelectric layer, due to the lattice mismatch of the bilayer structure, a build-in stress can develop on the beam and induce a static dipole in the beam. (p₂ in FIG. 2). The piezoelectric layer could be GaAs or other III-V semiconductors, PZT, ZnO etc. The other component, p₁ in FIG. 2, forms between the 2DEG layer of the side gate and a conducting substrate or the chip carrier. Given the absence of electrostatic A.C. forces, we propose that a new driving mechanism, a short-range dipole-dipole interaction, is dominant in our nanoelectromechanical system. This dipole-dipole interaction potential can be expressed as,

$$U = \int \frac{1}{4 {πɛ}_{0}} \frac{{p}_{2} d {p}_{1}}{{r}^{3}} \qquad ( 1.3 )$$

which can be understood as RF-coupling between two dipole moments dp₁ and p₂ as diagrammatically depicted in FIG. 2 showing a dipole charge separation 41, p₁, on beam 30 and a differential dipole charge separation 43, dp₂, on gate 32 in a differential slice dr taken perpendicular through the plane of FIG. 3b and FIG. 2. Here dp₁ is the dipole momentum of a slice of the gate, dp₁=εᵣ ε₀ L v_{g} e^{iωt} dr, and p₂ is the fixed dipole moment due to piezoelectric effect of strained GaAs/AlGaAs beam 30. z is the out-of-plane beam displacement, p₂=3E d_{A} wt² z/L, and L, w and t are beam length, width and thickness as shown in FIG. 2. ∈ᵣ is dielectric constant of GaAs. Here E is about 85 Gpa is Young's Modulus and d_{A} at about 3.8 pC/N is the appropriate piezoelectric constant of AlGaAs. The resulting force along z direction is,

$${f}_{z} = \frac{\partial U}{\partial z} = \frac{3 {ɛ}_{r}}{4 π} ( {Ed}_{A} ) ( \frac{{wt}^{2}}{{d}^{2}} ) {v}_{g} {ⅇ}^{ⅈω t}$$

This force is independent of the DC gate voltage, consistent with our observation. At 45 mV AC gate voltage drive, f_{z} is estimated to be 1.2 nN from this mechanism, four orders of magnitude higher than the direct Coulomb interaction. This is consistent with to the force we observe at the onset of non-linearity. Because of its short-range characteristics, this dipole-dipole interaction is unique to NEMS and is insignificant in microelectromechanical systems (MEMS).

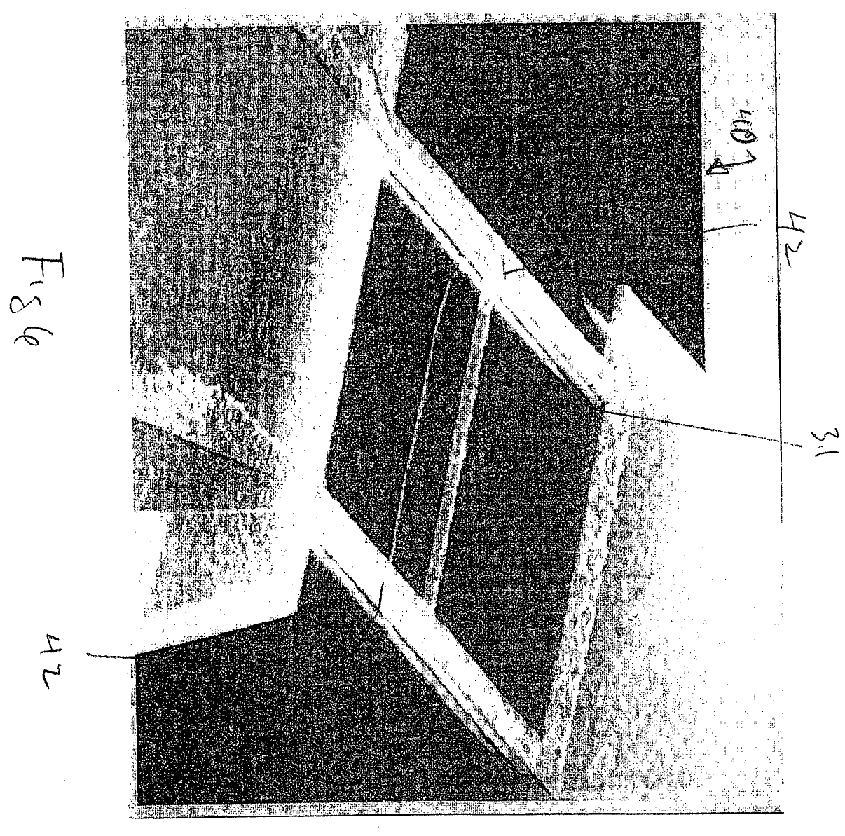

We have also studied the temperature dependence of our strain sensitive devices. Measurements were performed at three different temperatures in vacuum. The results are shown in the graph of FIG. 5. The drive and sensing current are kept at the same level. The devices 12 perform exceptionally well at liquid helium and nitrogen temperatures, but at room temperature, the response is diminished. The decay of signal strength at resonance with respect to temperature can be explained by the significant reduction of 2DEG mobility at higher temperature. At elevated temperature the increased two-terminal beam resistance acts as a large voltage divider, and only a small fraction of induced signal voltage drops across the input of RF-amplifier 38.

Parametric Amplifier

A nanometer-scale mechanical parametric amplifier is provided based purely upon the intrinsic mechanical nonlinearity of a doubly-clamped beam. Operating in degenerate mode, a parametric modulation of the beam's force constant at twice the signal frequency is produced by the application of an alternating longitudinal force to its ends. This provides stable, nearly thousand-fold small-signal mechanical gain at the threshold for parametric oscillation. For large signals, we find the gain saturates below this threshold; in this regime the device performs as a limiting preamplifier. At the highest gains noise-matched performance at the thermodynamic limit is achieved. A simple theoretical model explains the observed phenomena and indicates that this approach offers great promise for achieving output-coupled quantum-limited nanoelectromechanical systems.

The parametric amplifier described in the illustrated embodiment as shown in the microphotograph of FIG. 6 operates on a suspended nanomechanical transducer or beam 30 with a natural frequency at 17 MHz, with a gain-bandwidth product of 2.6 kHz, and requires pump voltages of only a few mV and power on the order of 1 μW to yield small-signal gain approaching 1000. The modulation of the spring constant is purely mechanical, requiring no capacitor plate as in the prior art, and precisely controlled by the fabrication geometry, requiring no prestress as in the prior art. The mechanism employed in the illustrated embodiment permits high gain-dynamic range product, in excess of 65 dB. Phase dependent amplification of thermomechanical fluctuations is observed at 4 K. Due to the stiffness of the device 40, detection sensitivity is limited by noise in the electrical readout amplifier 38, and is insufficient to observe thermomechanical noise. However, the device 40 is operated as a mechanical preamplifier, demonstrating a dramatic improvement in signal-to-noise ratio for small-amplitude harmonic motion.

Device 40 in FIG. 6 was fabricated by electron beam lithography from an epitaxial layer of silicon carbide on a silicon substrate. The device 40 was patterned by a vertical plasma etch of the silicon carbide layer and suspended by an isotropic plasma etch removing the supporting silicon. Device 40 is comprised of a signal beam 31 supported at either end by perpendicular pump beams 42 as shown in the microphotograph of FIG. 6. The lateral extent of the device 40 is 17.5 μm and its thickness is 200 nm. The device 40 is measured in vacuum at 4 K in a magnetic field of B=8 Tesla perpendicular to the chip's surface, so the Lorentz force provides an excitation of the signal beam 31, and the magnetomotive technique is used to detect its motion.

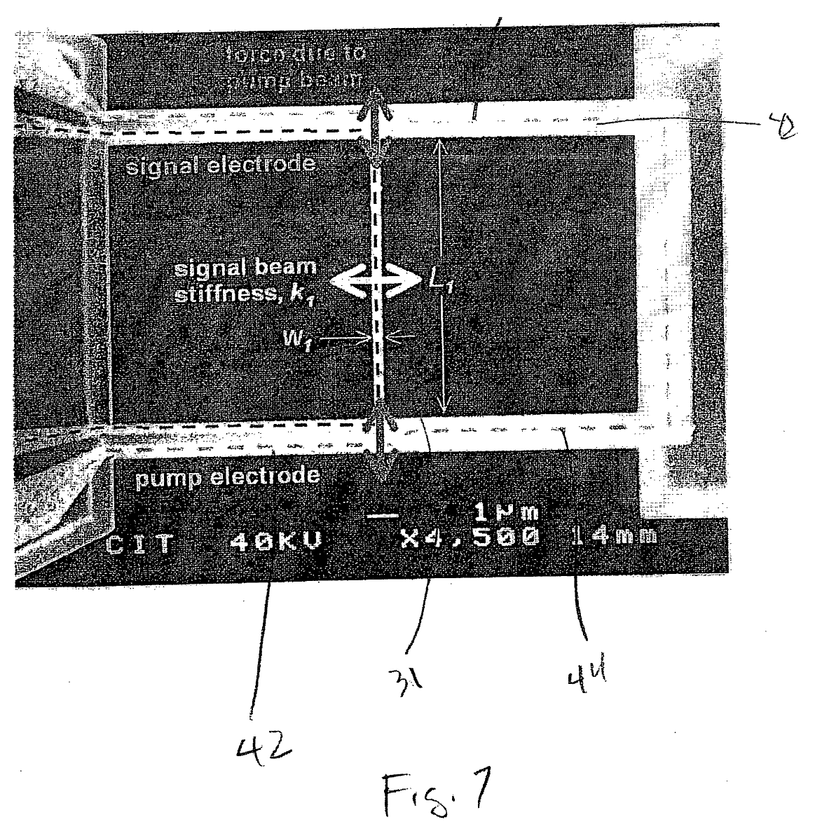

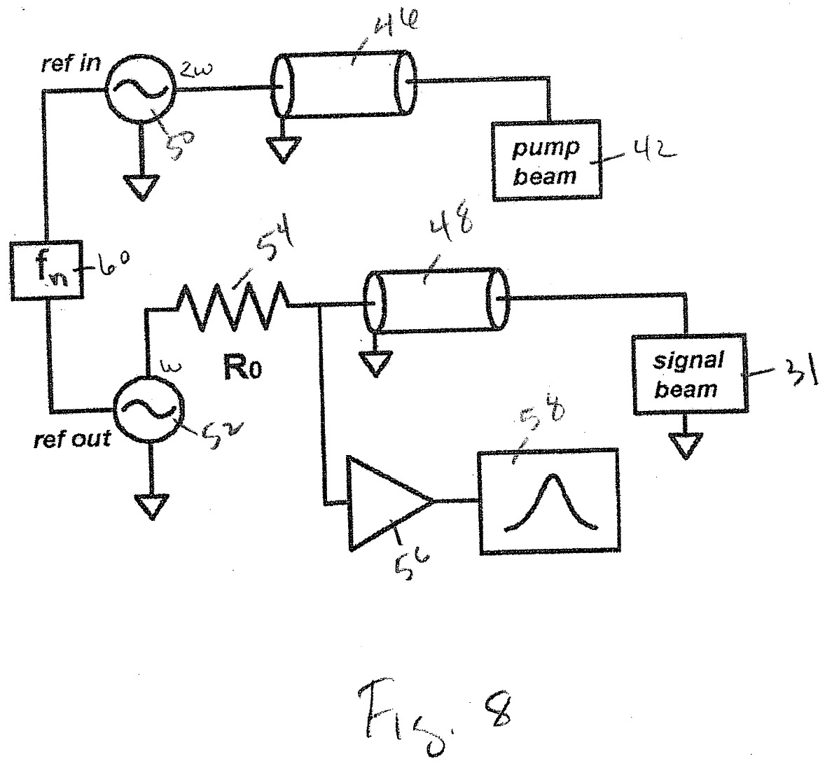

The spring constant of the signal beam 31 is modulated by the application of an alternating current I flowing through path 44 at a frequency 2ω₀ through the pump beams 42 as shown in the diagram of FIG. 7, where ω₀ is the fundamental frequency of beam 31. The Lorentz force, T, generated by this current applies sinusoidal compression and tension to the signal beam 31 is:
T=2BIL₂ζ cos(2ω₀t) (2.1)
where L₂ is the length of the pump beams 42 and ζ is a geometric factor to account for the finite restoring force of the pump beams 42. In principle, ζ can be evaluated from a finite element simulation. The longitudinal force perturbs the flexural spring constant for in-plane motion of the signal beam 31 with an amplitude of:

$$\frac{{k}_{p}}{{k}_{1}} = \frac{12}{{π}^{2} E {t}_{1} {w}_{1}} {( \frac{{L}_{1}}{{w}_{1}} )}^{2} T \qquad ( 2.2 )$$

where E is Young's modulus, and w₁,L₁, and t₁ are the width, length and thickness of the signal beam 31.

For small displacements, the equation of motion of the signal beam 31 under the influence of the pump and a harmonic excitation Fa is:

$$m \ddot{x} + \frac{m {ω}_{0}}{Q} \dot{x} + ( {k}_{1} + {k}_{p} cos ( 2 {ω}_{0} t ) ) x = {F}_{0} sin ( {ω}_{0} t + ϕ ) + {f}_{n} \qquad ( 2.3 )$$

where m is the effective mass, Q is the quality factor, and fₙ is a thermomechanical noise. Above a threshold pump amplitude

$${k}_{1} = 2 \frac{{k}_{1}}{Q} \qquad ( 2.4 )$$

the gain of the parametric amplifier diverges. For pump amplitudes below threshold, the mechanical gain depends on the relative phase φ between the excitation and the pump:

$$G ( ϕ ) = {[ \frac{{cos}^{2} ϕ}{{( 1 + \frac{{k}_{p}}{{k}_{t}} )}^{2}} + \frac{{sin}^{2} ϕ}{{( 1 - \frac{{k}_{p}}{{k}_{t}} )}^{2}} ]}^{\frac{1}{2}} \qquad ( 2.5 )$$

Although this expression for gain diverges as kₚ approaches the threshold, in practice nonlinearities in the system cause the gain to saturate. The dominant nonlinearity in our system is the geometric stiffening due to flexure, which results from longitudinal stretching of the signal beam 31 clamped by semi-rigid supports. To develop a model for saturation, we incorporate the cubic stretching term into the equation of motion:

$$m \ddot{x} + \frac{m {ω}_{0}}{Q} \dot{x} + ( {k}_{1} + {k}_{{p}^{0}} cos ( 2 {ω}_{0} t ) ) x + {k}_{3} {x}^{3} = {F}_{0} sin ( {ω}_{0} t + ϕ ) + {f}_{n} \qquad ( 2.6 )$$

where
   k₃=0.36k₁/t² (2.7)

If we consider motion at the fundamental frequency, with phase φ=0 chosen for maximum gain G, then
x=Gx₀ sin(ω₀t) (2.8)
and the cubic term perturbs the spring constant at 2ω₀ to oppose the action of the pump:

$${x}^{3} = \frac{{G}^{2} {x}_{0}^{2}}{2} cos ( 2 {ω}_{0} t ) x + \frac{{G}^{2} {x}_{0}^{2}}{2} x \qquad ( 2.9 )$$

Ignoring the linear term above, we derive an equation for the steady-state amplitude of motion x=Gx₀:

$$\frac{{k}_{3}^{2}}{4} {x}^{5} + {k}_{3} ( {k}_{t} - {k}_{{p}^{0}} ) {x}^{3} + {( {k}_{t} - {k}_{{p}^{0}} )}^{2} x - {k}_{t}^{2} {x}_{0} = 0 \qquad ( 2.10 )$$

The response of the parametric amplifier is measured with the circuit shown in the schematic diagram of FIG. 8. The lengths of the coaxial cables 46 and 48 to the pump beams 42 and signal beam 31 are chosen so that they act as 1-1 impedance transformers at 2ω₀ and ω₀ respectively. Pump beams 42 are coupled through cable 46 to a driving oscillator 50 operating at 2ω and an equivalent thermoelectric noise source 60. A virtual output oscillator 52 operating at ω is coupled through load resistance 54 through cable 48 to signal beam 31 and comprises an output reference signal indicative of the parametric oscillation of signal beam 31. The output from signal beam 31 is coupled through amplifier 56 to a display or measurement device 58. The electrical response is then the superposition of the mechanical motion on the baseline electrical resistance of the signal beam 31. To determine the mechanical gain we compare the electrical response on and off resonance, as measured by a spectrum analyzer:

$$G = \frac{{V}_{on resonance}^{pump on} - {V}_{off resonance}^{pump on}}{{V}_{on resonance}^{pump off} - {V}_{off resonance}^{pump off}} \qquad ( 2.11 )$$

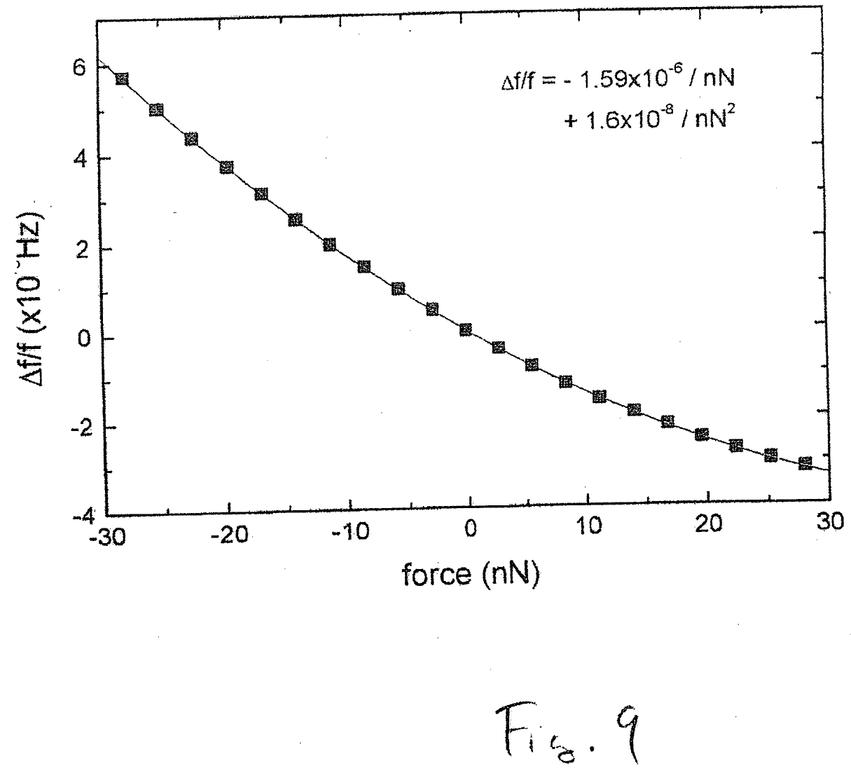

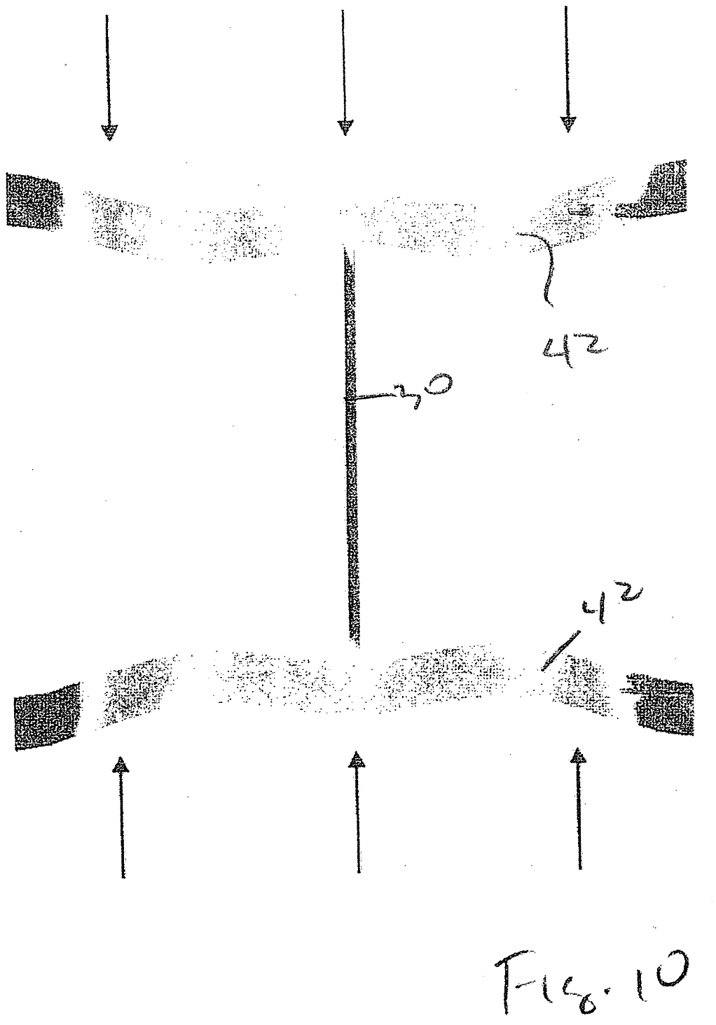

In order to verify the effectiveness of the pump, we substituted a network analyzer for the signal source 50 and spectrum analyzer 58 in the schematic in FIG. 8, and measured the frequency shift of the resonance peak as a function of DC pump force. From the fit in FIG. 9, we find the frequency shift to be Δf/f=1.59/mN, neglecting the finite restoring force of the pump beam 42 (assuming ζ=1 in (1)). From equation (2.2), the expected variation is Δf/f=6.24/mN. The discrepancy between these values suggests that the stiffness of the pump beam 42 does indeed reduce the effective pump force applied to the signal beam 31. To evaluate ζ, we conducted a finite element mechanical simulation of the structure in which static forces totaling 1 nN were applied transverse to the pump beams 42 as shown in the diagram of FIG. 10. From the calculated compression, 87 pm, of the signal beam 31 in the model, the effective compressive force applied to the signal beam 31 can be found:
T=EtwΔx/x (2.12)

Thus, we find T=0.235 nN and ζ=0.235, so our measured frequency shift is actually 6.77/mN. The agreement with the expected value indicates that our model accounts for the effectiveness of the pump.

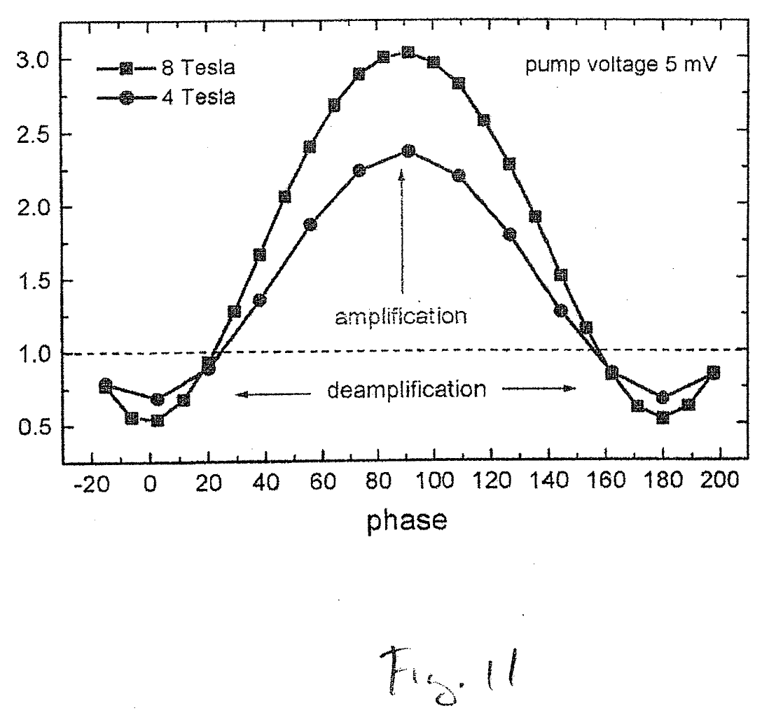

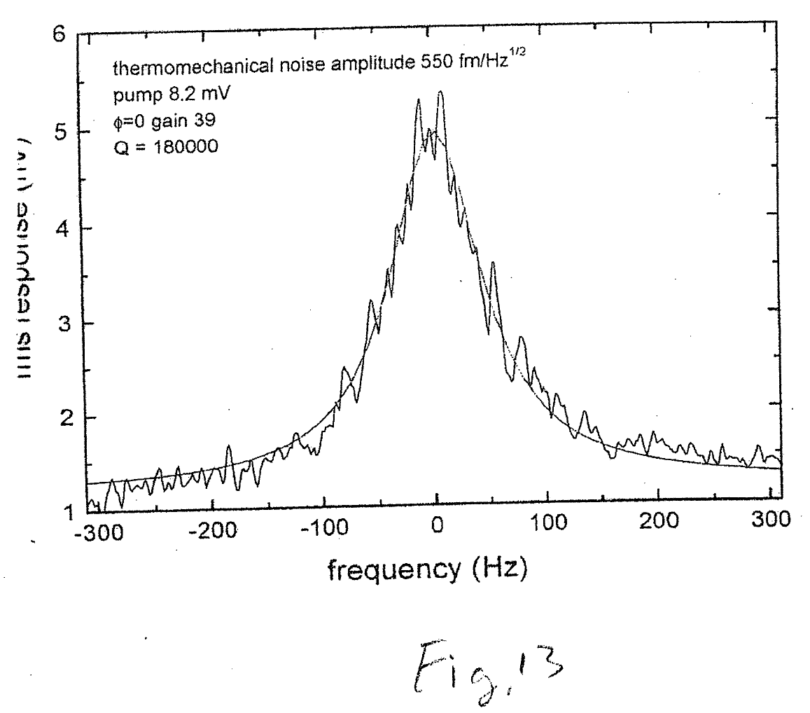

To further demonstrate that the observed parametric effect is due to the Lorentz force on the pump beam 42, FIG. 11 is a graph which shows a measurement of the phase-dependent gain of the amplifier of FIG. 8 at two different magnetic fields. The signal beam 31 is driven at its fundamental frequency ω₀ and the pump beams 42 are driven at 2ω₀, referenced to the signal beam 31 through a variable phase shifter (not shown). The motion of the signal beam 31 is either amplified or deamplified, depending on the phase difference between the motion of the signal beam 31 and the excitation of the pump beams 42. As equation (2.5) predicts, the maximum gain occurs at φ=π/2 and the minimum gain occurs at φ=0. As equations (2.1) and (2.2) predict, for stronger magnetic field, the pump-induced frequency shift is greater, so the maximum gain is greater and the minimum gain is smaller. Although amplification and deamplification are greatest when the pump is at exactly 2ω₀, substantial variation in gain is possible off-resonance. For excitation at ω slightly off-resonance, two sidebands are created, one at ω and one at 2ω₀−ω. FIG. 12 shows the dominant sideband ω of the signal beam's response to a fixed excitation with the phase shift set for maximum gain. At high gain, the action of the pump substantially reduces the bandwidth of the resonance. For a pump voltage of 8.2 mV, the bandwidth is reduced from 1760 Hz to 35 Hz.

As the pump amplitude approaches the threshold value, the gain of the parametric amplifier on resonance is expected to increase dramatically. When our device is operated just below threshold, at 8.2 mV, the gain of 39 at φ=0 is sufficient to observe amplified thermomechanical fluctuations, as shown in the graph of FIG. 13. The response of the signal beam 31 to thermomechanical fluctuations has a Lorentzian line shape which is narrowed by the parametric amplifier. Since the fluctuating force is not coherent with the pump, the gain for this peak should be averaged over phase. Assuming an average gain of 39, the amplitude of the peak corresponds to an rms amplitude of motion of 550 fm/Hz^{1/2}, or 14 fm/Hz^{1/2}. The amplitude of thermomechanical fluctuations for a simple harmonic oscillator on resonance is given by

$$\sqrt{{S}_{x}^{t}} = \sqrt{\frac{4 {k}_{B} TQ}{{ω}_{0} k}} \qquad ( 2.13 )$$

where the spring constant k=mw₀²; is 32 N/m, which yields a value of 26 fm/Hz^{1/2} for the signal beam 31. The discrepancy between the values can be attributed to an error due to the average gain approximation and in the calculation of spring constant.

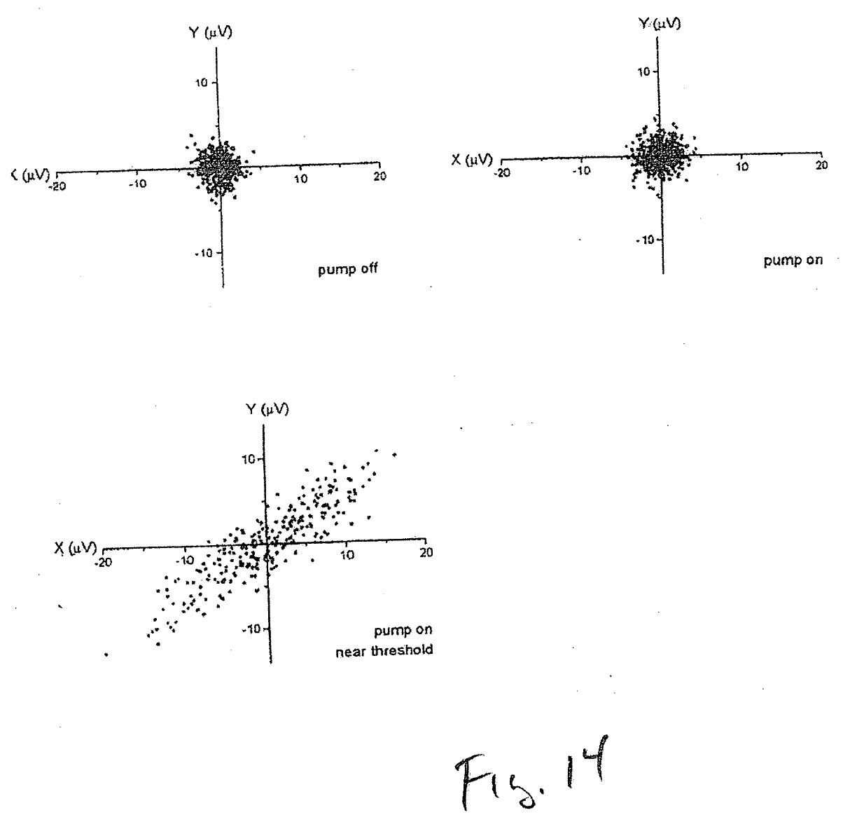

We observed the phase dependence of the amplified thermomechanical fluctuations by replacing the spectrum analyzer with a radiofrequency lock-in amplifier (not shown) referenced to the pump beams 42. As FIG. 14 demonstrates, for pump voltage close to threshold, the fluctuations are clearly amplified, but in one quadrature only (i.e. the phase relationship between ω and 2ω). No effect is observed in the other quadrature, because the total noise in that quadrature is dominated by the phase-independent noise at the input of the linear electrical amplifier 56.

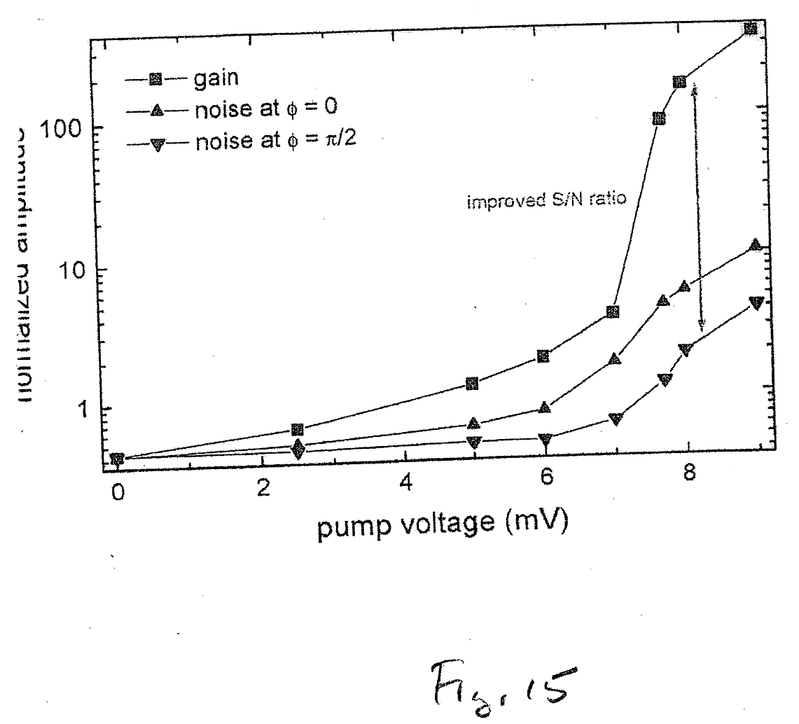

Just as the Brownian motion of the signal beam 31 is amplified without the addition of mechanical noise, so too is harmonic motion. Since in our system, the electrical amplifier dominates the noise level, the signal-to-noise ratio for measurement of harmonic motion of the signal beam 31 can be improved dramatically by parametric amplification. The graph of FIG. 15 compares the gain for a harmonic excitation which would yield an rms amplitude of motion of 1.2 pm with the overall noise level in each quadrature. Near the threshold pump amplitude, the signal-to-noise ratio improves by a factor of nearly 100 with respect to the φ=π/2 quadrature. As a consequence of the dominance of the electrical amplifier's 56 input noise over thermomechanical noise, the signal-to-noise ratio is also improved in the φ=0 quadrature, although to a lesser extent. This result describes the most fundamental application of a parametric amplifier, namely as a mechanical preamplifier.

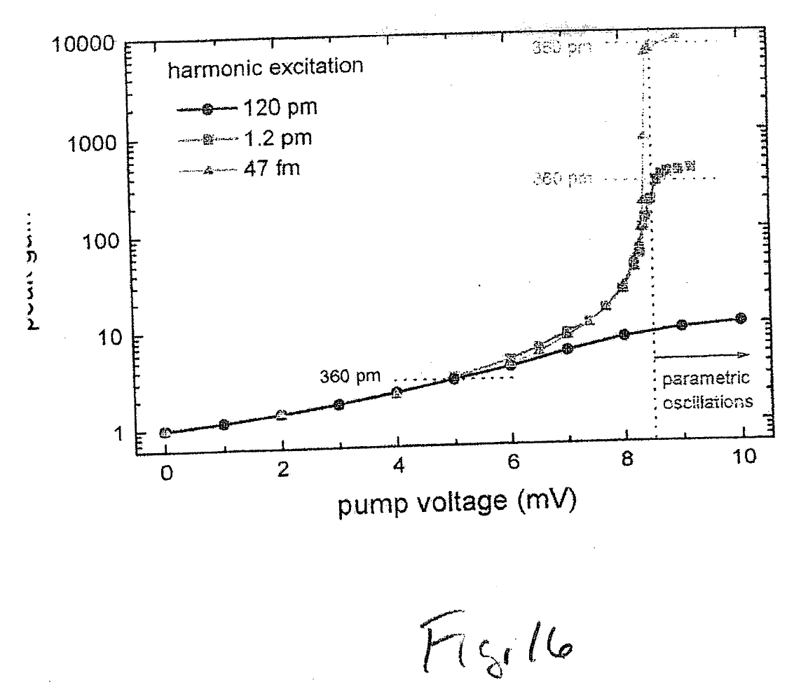

The dynamic range of the amplifier is critically important to this application. For a harmonic excitation of 47 fm in the absence of a pump, our device exhibits gain as high as 800, as shown in the graph of FIG. 16. However, for larger excitations, the gain saturates at much lower values. FIG. 16 clearly demonstrates that the point at which the gain begins to saturate depends solely on the amplitude of motion, not the excitation. The saturation begins at an rms amplitude of −360 pm, and gives a good approximation to the upper bound for the dynamic range of the amplifier. Ultimately, the upper limit of dynamic range is a direct consequence of nonlinearities in the system. In our system, the dominant nonlinearity is expected to be the cubic term in the expansion of the flexural spring constant.

Sensitivity of Piezoresistive NEMS Displacement Transducers in Vacuum

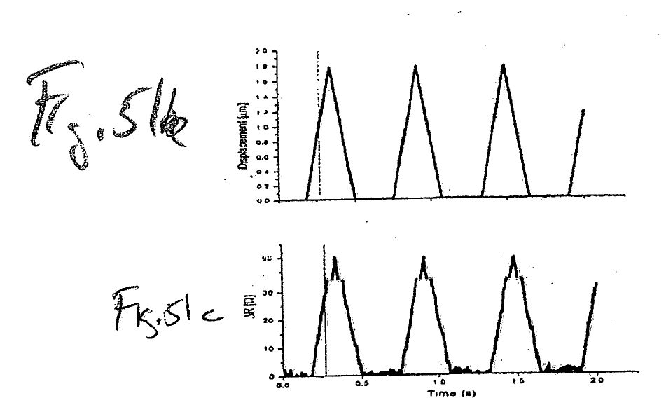

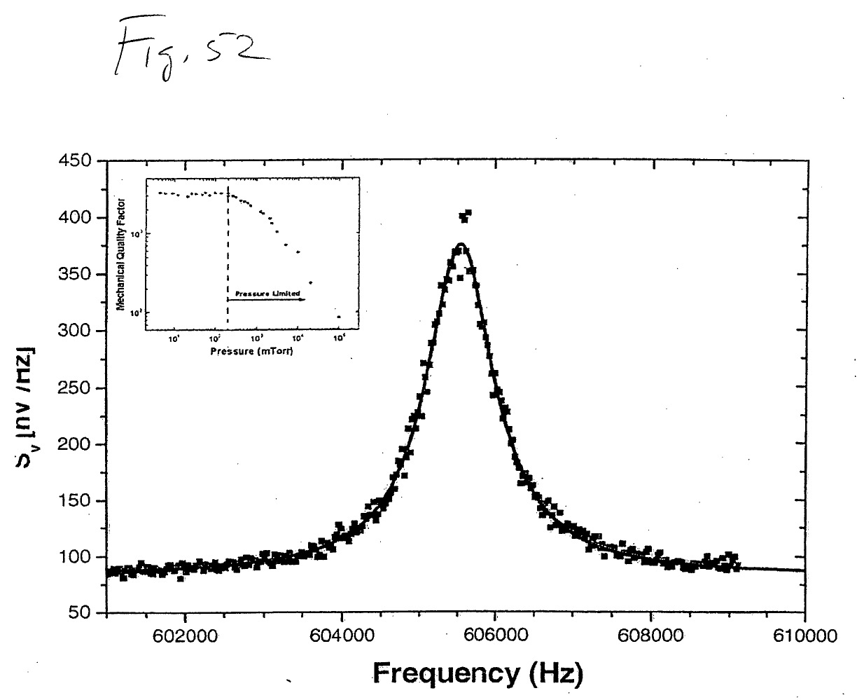

One of the most important engineering challenges to be faced is optimization of the readout system that measures a NEMs cantilever displacement. Shown in the SEM photograph of FIG. 51 is an example of a practical device, a cantilever 190, which incorporates a piezoresistive strain transducer. The transducer converts the motion of the cantilever 190 into an electrical signal, in this case via the strain-induced change in resistance of a conducting path patterned from p+ doped Si epilayer disposed on the top surface of the cantilever 190. For the purposes of illustration the bioNEMS transducer or cantilever 190 shown in perspective view in the microphotograph FIG. 51 can be analogized as having the form of “a diving board with a cutout at its base”. The geometry of the device 190 causes dissipation to occur predominantly within a constriction region 192 comprised of one or more legs 194 of width b, which region 192 allows for enhanced or variably designed flexural stiffness of cantilever 190. It is also to be understood that cantilever 190 will have conventional electrodes (not shown) provided whereby a conventional external measurement circuit (not shown) providing a bias current may measure the change in piezoresistivity of legs 194 as they flex. In addition, an external driving force may or may not be applied in a conventional manner to cantilever 16 depending on the application and design choice. In the preferred embodiment there are two legs 194. We assume that a temperature rise of order 10 K is tolerable at the biofunctionalized tip 196 of the cantilever 190, which has a length, l, a width, w, and a thickness, t, resonant frequency in vacuum ω₀/2π and force constant K.

We characterize the transducer's performance by its responsivity, R, in units volts/m, R=I G, where I is the bias current, while

$$G = \frac{\partial {R}_{T}}{\partial x}$$

and R_{T} are the gauge factor ax and the two-terminal resistance of the transducer, respectively.

Near resonance, the force spectral density of thermomechanical displacement fluctuations is given by S_{V}^{y}=4k_{B}Tγ=4Kk_{B}T/Q. Three additional terms arising from electrical noise in the readout process must also be included. These must be referred back to the input, i.e. to the displacement domain using the factor 1/R². The first arises from the thermal voltage noise of the piezoresistive transducer, S_{VT}=4k_{B}TR_{T}, while the second arises from the readout amplifier's voltage and current noise, S_{VA}=S_{V}+S_{I}R_{T}²; where Sᵥ and S_{I} are the spectral density of the amplifier's voltage and current noise, respectively.

The sum of these fluctuations yields what we term the total coupled displacement noise, which is the actual displacement sensitivity of the entire system,

$${S}_{x}^{( C )} = {S}_{x}^{( γ )} + \frac{1}{{R}^{2}} \{ {S}_{VT} + {S}_{VA} \}$$

From this we can determine the coupled force sensitivity of the electromechanical system, which at resonance is given by
S_{F}^{(C)}=K²S_{X}^{(C)}/Q²
where K is the spring constant and Q is the quality factor of the cantilever beam.

The somewhat complex mechanical device shown in FIG. 51, compared to a simple cantilever geometry, provides a higher degree of compliance while providing low mass (if its overall size is kept small). Its spring constant is more complex than that of the simple cantilever, and can be written as ***EQN corrected***

$$K = \frac{{Et}^{3}}{\frac{4 {l}^{3}}{w} + ( 2 {l}_{1}^{3} - 6 {ll}_{1}^{2} + 6 {l}^{2} {l}_{1} ) ( \frac{1}{b} - \frac{2}{w} )} \qquad 7.1$$

The variables characterizing the device geometry are depicted in FIG. 51 and are summarized for the cantilevers discussed here in Table 3 which shows the physical parameters for three prototype Si nanocantilevers. The parameters tabulated are thickness, t; width, w; length, l, constriction width, b, and length l₁; frequency in vacuum ω₀/2π; force constant K; and resistance R_{T}.

TABLE 3

| cantilever | t | | w | | l | | l₁ | | b | | ω₀/2π | | K | | R_{T} | |
|---|---|---|---|---|---|---|---|---|---|---|---|---|---|---|---|---|
| 1 | 130 | nm | 2.5 | μm | 15 | μm | 4.0 | μm | 0.6 | μm | 0.51 | MHz | 34 | mN/m | 15.6 | kΩ |
| 2 | 110 | nm | 900 | nm | 6 | μm | 3 | μm | 300 | nm | 3.1 | MHz | 145 | mN/m | 22 | kΩ |
| 3 | 37 | nm | 300 | nm | 2 | μm | 1 | μm | 100 | nm | 9.2 | MHz | 48 | mN/m | 67 | kΩ |
| 4 | 30 | nm | 30 | nm | 0.3 | μm | 20 | nm | 10 | nm | 360 | MHz | 1.0 | N/m | 16 | kΩ |

In the illustrated device, cantilever 190 has thickness 130 nm, with the topmost 30 nm comprised of a heavily (p+) doped Si epilayer, while the remaining 100 nm is intrinsic Si layer underlying the Si epilayer. The piezoresistive transducer is patterned from the p+ boron doped Si (4×10¹⁹/cm³) with the current path in legs 194 oriented along the <110> direction. The gauge factor for this cantilever is given by

$$G = \frac{3 {βπ}_{L} K ( 2 l - {l}_{1} )}{2 {bt}^{2}} {R}_{T} \qquad 7.2$$

The parameter π_{L} is the piezoresistive coefficient of the p+ transducer material (4×10⁻¹⁰ m²/N for p-type <110> silicon). The parameter β, a coefficient between 0 and 1, is used to account for the finite thickness of the conducting layer. β approaches 1 monotonically as the carriers become confined to a surface of infinitesimal thickness. We expect β˜0.7 for our cantilevers. The factor β accounts for the decrease in G due to the finite thickness of the conducting layer; β approaches unity as the carriers become confined to a surface layer of infinitesimal thickness. We shall assume β=0.7 for our epilayer. For the cantilever pictured in FIG. 51 we observe, G=3.3×10⁷ Ω/m. For the transducer geometry pictured, a two-terminal (equilibrium) resistance of R_{T=}15.6 kΩ is obtained. Note that this implies G/R_{T}˜2.1 ppm/nm.

We now investigate what are the constraints upon the level of current bias applied in the circuit in legs 194. The force sensitivity attainable clearly hinges on the maximum level of bias current that is tolerable, given that the responsivity is proportional to bias current, [symbol] =I G. The largest practical level is determined by the maximum temperature rise deemed acceptable. The geometry of the prototype devices causes dissipation to occur predominantly within the constriction regions 192 of width b. We assume that a maximal temperature rise of order 10K is tolerable. We treat the problem as one dimensional, with the constricted region 192 of beam 190, of length l₁ and cross sectional area A, heat sunk at the supporting end 195. It is assumed that all no heat is exchanged through the vacuum. In the dissipative region x<l₁ we have

$$2 {κ}_{Si} {tl}_{1} b \frac{{ⅆ}^{2} T}{ⅆ {x}^{2}} = - {l}^{2} R ,$$

where Kₛᵢ=1.48×10² W/mK at 300K is the thermal conductivity of silicon. Assuming the dissipation in the region of cantilever 190 beyond the constriction region 192 to be negligible, we apply the boundary condition d/dx=0 at x=l₁. This simple thermal conductance calculation indicates that a maximum temperature rise of 10K is obtained with a steady-state bias current I=60 μA, leading to a power dissipation of roughly 60 μW. For this bias current, our prototype device yields a responsivity [symbol] =/G˜2 μV/nm.

With knowledge of these parameters we can now estimate the coupled force sensitivity of the prototype system. For cantilever 190, starting at room temperature and assuming that a 10K temperature rise, the transducer-induced thermal voltage noise, referred to the force domain is found to be K√S_{VT}/( [symbol] Q)=92 aN/√Hz at resonance for a Q of 2000. For a typical low noise readout amplifier with voltage and current noise levels (referred to input) of ˜4 nV/√Hz and, ˜5 fA/√Hz, respectively, these same parameters yield an amplifier term K√S_{VA}/Q=23 aN/√Hz. For this cantilever, the force spectral density of the thermomechanical displacement fluctuations is S_{F}^{γ}=300 aN/√Hz. The total transducer noise for improved quality factors are given in Table 4.

Clearly the noise from thermomechanical displacement fluctuations is dominant. This may be decreased by reducing the dimensions to increase the resonance frequency and decrease the spring constant.

To illustrate the benefits of further scaling downward in size for such devices, we consider two smaller cantilevers having geometry identical to that of FIG. 51, but with l=6 μm, t=110 nm, w=900 nm, b=300 nm, and l₁=3 μm. Assuming this device is constructed from the same epilayer thickness ratio as cantilever 190, this yields R_{T=}19 kΩ and G=2.9×10⁹ Ω/m (cantilever #2 in Table 4).

For cantilever #2 we again assume that a 10K rise at the tip is tolerable. For Q=2000, we find the transducer-induced force noise is K√S_{VT}/( [symbol] Q)=7.1 aN/√Hz, whereas the readout amplifier's contribution, referred to the force domain, is K√S_{VT}/( [symbol] Q)=1.5 aN/Hz. The force spectral density of the thermomechanical displacement fluctuations is S_{F}^{γ}=249 aN/√Hz. For Q=30000 the force spectral density of the thermomechanical displacement fluctuations is S_{F}^{γ}=64 aN/√Hz.

Another device considered, “cantilever #3” is identical to cantilever #2, but is uniformly reduced in all dimensions by a factor of −3. For this device R_{T=}67 kΩ, and G=3.0×10¹⁰ Ω/m. Once again using Q=2000, this yields transducer-induced Johnson force noise S_{F}^{γ}=1.5 aN/√Hz and an amplifier contribution, referred to the force domain, K√S_{VT}/Q=0.18 aN/√Hz. The force spectral density of the thermomechanical displacement fluctuations is S_{F}^{γ}=83 aN/√Hz. For Q=30000 the force spectral density of the thermomechanical displacement fluctuations is S_{F}^{γ}=21 aN/√Hz. Force sensitivity for other amounts of heating allowed is given in Table 4.

TABLE 4
Coupled force sensitivity at resonance for
room temperature piezoresistive detection

| Cantilever 1 | | Cantilever 2 | | Cantilever 3 | | Cantilever 4 | |
|---|---|---|---|---|---|---|---|
| | S_{F}^{C} | | S_{F}^{C} | | S_{F}^{C} | | S_{F}^{C} |
| Q | [aN/√Hz] | Q | [aN/√Hz] | Q | [aN/√Hz] | Q | [aN/√Hz] |
| 2000 | 329 | 2000 | 280 | 2000 | 86 | 2000 | 62 |
| 10000 | 136 | 10000 | 125 | 10000 | 38 | 10000 | 28 |
| 30000 | 77 | 30000 | 72 | 30000 | 22 | 30000 | 16 |
| 100000 | 42 | 100000 | 40 | 100000 | 12 | 100000 | 8.8 |

For a doping density of 4×10¹⁹/cm³ the depletion length is on the order of 2 nm therefore while cantilever #3 lies entirely within the domain of feasibility, it is not realistic to continue pushing the thickness any thinner than 30 nm. In order to achieve the 364 MHz of cantilever #4 the length was therefore decreased without significantly decreasing the thickness. Despite the limitation imposed by the increased spring constant, the force sensitivity remains excellent with a coupled force sensitivity of S_{F}^{γ}=62 aN/√Hz for a quality factor of 2000 at room temperature. The sensitivity of all four cantilevers for a variety of quality factors are summarized in table 4. Table 5 gives the analogous data for 4K.

TABLE 5
Coupled force sensitivity at resonance for piezoresistive detection at 4K

| Cantilever 1 | | Cantilever 2 | | Cantilever 3 | | Cantilever 4 | |
|---|---|---|---|---|---|---|---|
| | S_{F}^{C} | | S_{F}^{C} | | S_{F}^{C} | | S_{F}^{C} |
| Q | [aN/√Hz] | Q | [aN/√Hz] | Q | [aN/√Hz] | Q | [aN/√Hz] |
| 2000 | 74 | 2000 | 22 | 2000 | 5.7 | 2000 | 16 |
| 10000 | 20 | 10000 | 9.8 | 10000 | 2.5 | 10000 | 4.3 |
| 30000 | 9.9 | 30000 | 5.7 | 30000 | 1.5 | 30000 | 2.1 |
| 100000 | 5.0 | 100000 | 3.1 | 100000 | 0.81 | 100000 | 1.0 |

NEMS-Based Piezoresistive Force Sensing

Force sensitivity for a piezoresistive detector is discussed above at both room temperature and 9K. The pressure dependence of the room temperature force sensitivity is also discussed. A direct measurement of the gauge factor was obtained using an atomic force microscopy [AFM] to move the cantilever tip a known amount as shown in FIG. 51a. This yields a direct measurement of G=dR_{T}/dx=3×10⁷ Ω/m and we calculate G˜6×10⁸ Ω/m for β=0.7. The discrepancy is attributed to diffusion during processing. In particular, to mask these particular devices for which the membrane from which the cantilever was patterned was formed using a KOH etch during early processing steps, silicon nitride was grown by LPCVD at 850° C. at which temperature diffusion is a concern, decreasing β from the expected value; this high temperature masking step is not necessary if a DRIE etch is used as an alternative to the KOH etch for membrane formation.

Near resonance, the force spectral density of thermomechanical fluctuations is given by
S_{F}^{γ}=4k_{B}Tγ=4Kk_{B}T/(2πQf₀) 8.1
where γ is the damping coefficient in kg/s, f₀ is the resonance frequency and Q=mf₀/γ is the quality factor.

Near resonance, the voltage spectral density for the thermomechanical fluctuations is therefore given by

$${S}_{V}^{γ} = \frac{{S}_{F}^{γ} {G}^{2} {I}^{2}}{16 {π}^{2} {m}^{2} {f}_{0}^{2} [ 4 {( f - {f}_{0} )}^{2} + {f}_{0}^{2} / Q ]} \qquad 8.2$$

Measured at the amplifier this will give

$${S}_{V}^{measured} = \frac{{S}_{V}^{γ}}{{R}_{T}} {( {( \frac{1}{{R}_{T}} + \frac{1}{{R}_{bias}} + \frac{1}{{R}_{amp}} )}^{2} + 4 π {f}^{2} {C}^{2} )}^{- \frac{1}{2}} + {S}_{V}^{{J}_{measured}} + {S}_{V}^{A} \qquad 8.3$$

where R_{bias} is the impedance of the bias resistor, connected in parallel to the sample, Rₐₘₚ is the input impedance of an amplifier (not shown) to which cantilever 190 is electrically coupled, and C is the input capacitance of the amplifier, S_{V}^{J}^{_{measured}} is the Johnson noise as measured at the input to the amplifier and S_{V}^{A} is the voltage spectral density from the amplifier.

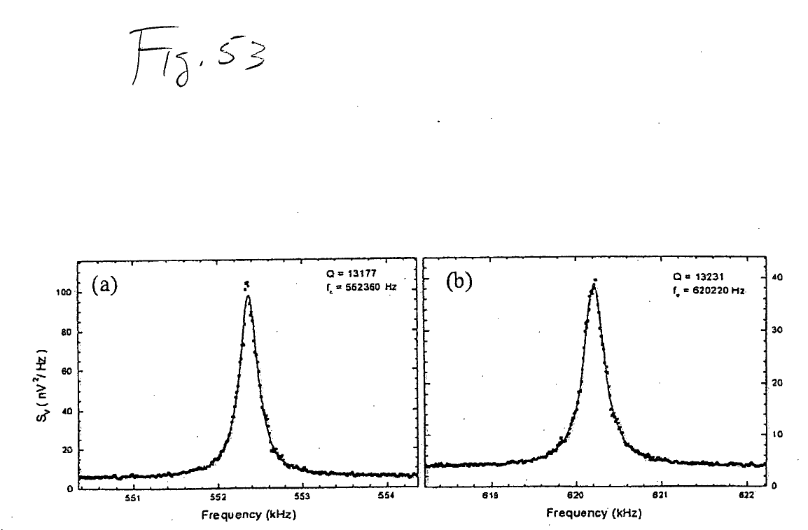

FIG. 52 shows the resonance peak for the thermomechanical noise in vacuum at room temperature, for a device of dimensions comparable to that used for the measurement of the gauge factor above. The sample resistance is 16.7 kΩ and is in parallel with a 10.5 kΩ resistor. The input capacitance of the amplifier is 33 pF and input resistance 100 kΩ. We therefore expect a background from Johnson noise of 5.7 nV/√Hz at 605.5 kHz. The preamplifier noise was measured to be 2.5 nV/√Hz at this frequency. Giving a combined expected background of 6.2 nV/√Hz. The measured background was 9.13 nV/√Hz. For this cantilever, the measured resonance frequency was 605.5 kHz. The measured quality factor in vacuum was 550. From Eqn. 8.1, the force spectral density from thermomechanical fluctuations is therefore 1.5 fN/√Hz. We may invert Eqns. 8.2 and 8.3 and use the Lorentzian fit to the experimental data to give a measurement of the gauge factor, giving G=1.0×10⁸ Ω/m.

The inset to FIG. 52 shows the pressure dependence of the quality factor for this device. The pressure clearly has a dampening effect above 200 mTorr.

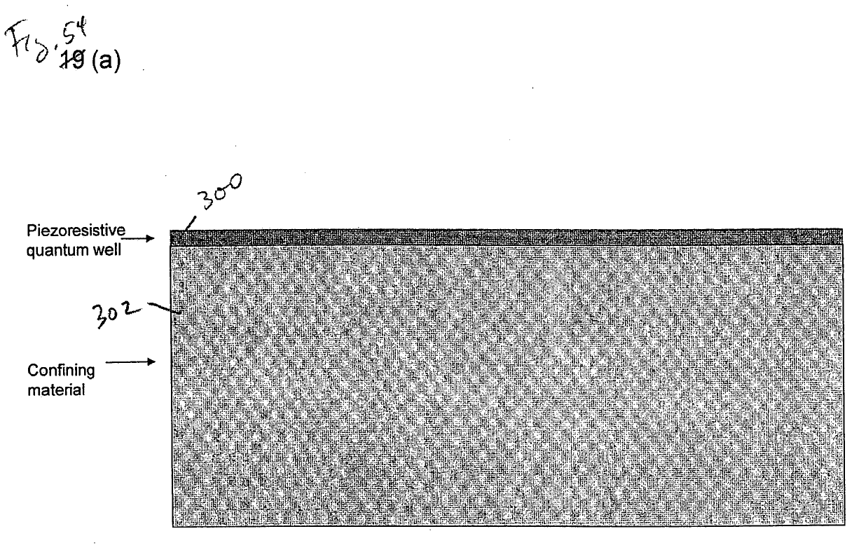

FIG. 53a shows the resonance peak for the same device placed in a liquid helium cryostat. A bias current of 48 μA was used, it is estimated that the maximal heating at this temperature (occurring at the device tip) should be given by I²R I₁/(4K_{Si}tb) ˜4K. So the temperature at the device tip is ˜9K. At this temperature the resonance frequency is 552 kHz and a quality factor of 2.1×10³ was obtained. The force sensitivity is given by equation 8.1. Using the measured quality factor and the estimated temperature of 9K this gives a force sensitivity of 113 aN/√Hz. From Eq. 8.2 it is possible to extrapolate the gauge factor. This gives a gauge factor of 1.6×10⁸ Ω/m or an increase by a factor of 1.6 from the room temperature value, arising from an increase in the piezoresistive coefficient increases with decreasing temperature.

FIG. 53b shows the same data for another device of the same dimensions fabricated simultaneously on the same chip. The resistance of this cantilever is 14.4 kΩ. The resonance frequency of this cantilever was 620 kHz and a quality factor of 2.11×10³ was measured. From Eq. 8.1 this gives a force sensitivity of 126 aN/√Hz.

Scaling of Piezoresistive Sensors

Piezoresistors are designed to have a thin heavily doped silicon layer on top of nominally intrinsic silicon. As the devices are scaled to smaller dimensions, the effect of the depletion layer in the thin silicon layer becomes increasingly significant. The carrier distribution is computed below by iterating between two procedures until convergence is attained. The first procedure adjusts the Fermi level until charge neutrality is attained. The second procedure calculates the bending of the valence band according to the equation

$$\frac{{ⅆ}^{2} {E}_{v}}{ⅆ {z}^{2}} = \frac{e ρ ( x )}{ɛ} \qquad 3.1$$

where Eᵥ is the energy of the valence band, e is the charge of the electron, ρ is volume density of carriers, and ∈ is the dielectric constant. ρ(x) is the charge density, given by Fermi statistics, ρ(x)=e(p(x)−n(x)) where p(x)=1.04×10²⁵ e^{-β(E}^{_{F}}^{-E}^{_{V}}⁾/m³ is the density of positive carriers. Subject to the boundary condition:

$$\frac{{ⅆ}^{2} {E}_{v}}{ⅆ {z}^{2}} {\vert}_{z = 0} = \frac{e σ}{ɛ} \qquad 3.2$$

where σ is the surface carrier density. The density of surface states a for equation 3.2 and 3.3 were estimated based on published values for interface state density at a silicon-silicon dioxide interface.

Setting the Fermi level to achieve charge neutrality assures that at the lower surface the boundary condition is attained,

$$\frac{{ⅆ}^{2} {E}_{v}}{ⅆ {z}^{2}} {\vert}_{z = t} = \frac{e σ}{ɛ} \qquad 3.3$$

where z=t is lower surface of the nominally intrinsic silicon, which is also normally the lower surface of the transducer or cantilever. (z is the out of plane direction)

The Fermi level, E_{F}, is set by the condition that charge neutrality be maintained;
∫₀^{l}(ρ(x)/e+N_{A}⁻(x))dx=0 3.6
where

$${N}_{A}^{-} ( x ) = \frac{\# dopants}{\frac{1}{2} {ⅇ}^{- β ( {E}_{A} - ( {E}_{F} - {E}_{V} ) )}} \qquad 3.7$$

is the density of ionized acceptor sites, E_{A} is the energy of the ionized acceptor sites.
p(x)=1.04×10²⁵e^{-β(E}^{_{F}}^{-E}^{_{V}}⁾/m³
n(x)=2.8×10²⁵e^{-β(E}^{_{C}}^{-E}^{_{F}}⁾/m³
where β is 1/kT and E_{C} is the energy of conduction band. Equations 3.1 and 3.6 were solved iteratively until convergence was attained.

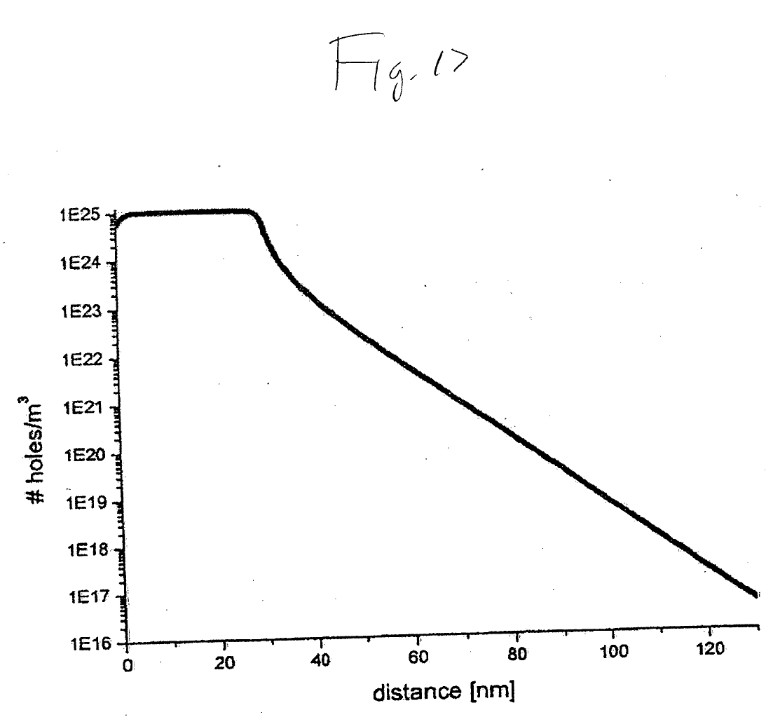

FIG. 17 shows the carrier distribution for a sample of 130 nm thickness in which the dopant layer is 30 nm thick and the dopant concentration is 4×10²⁵ m⁻³. The carrier distribution for a sample of 30 nm thickness for which the thickness of the doped layer is 7 nm is shown in FIG. 18. In both cases the carriers are well confined.

It is clear from FIG. 18 that we are now approaching the minimum thickness that may be achieved with a conventional 2 layer structure such as cantilever 190. Further direct reduction of the dimensions is not possible without sacrificing performance as the depletion layer thickness becomes significant relative to the dimension of the doped region. A new technique is therefore required.

Confining Carriers in Piezoresistive NEMS Sensors

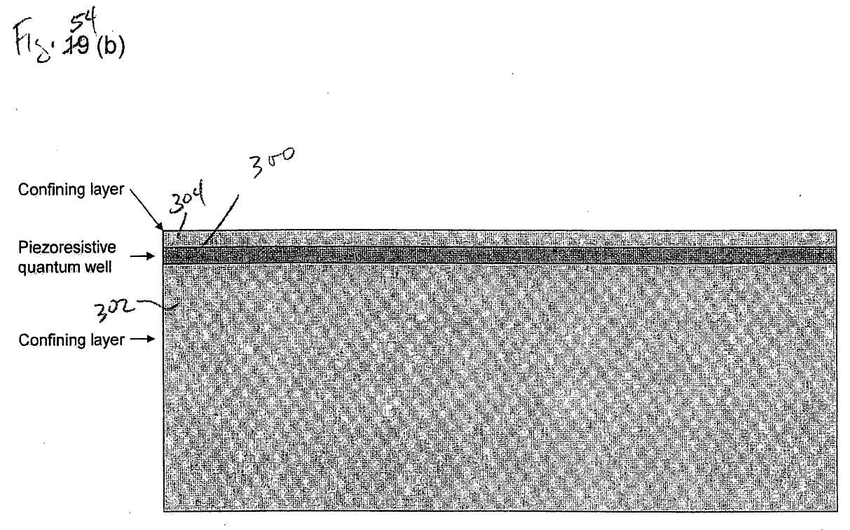

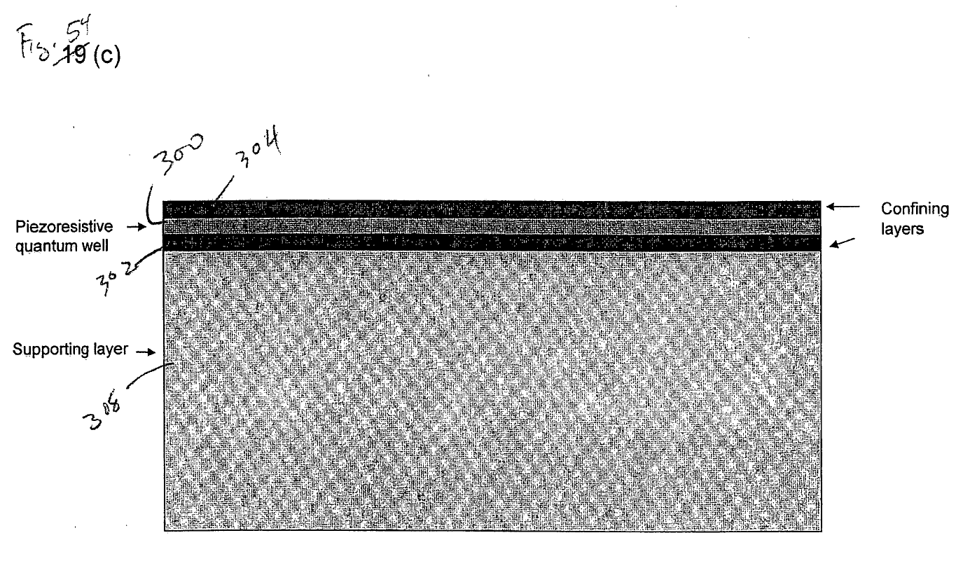

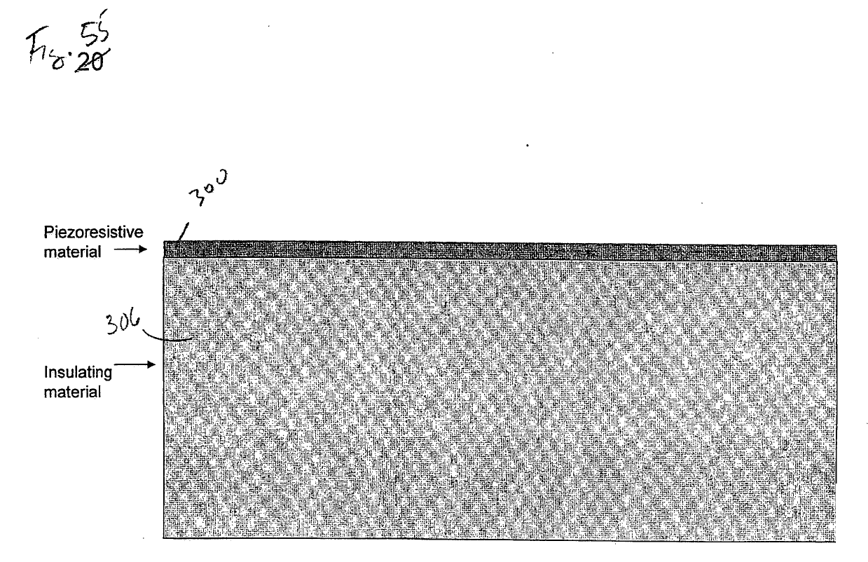

Carrier confinement can be substantially increased by confining the carriers in a quantum well structure as depicted in FIGS. 54a, 54b, and 54c. In these figures the conduction/piezoresistive sensing takes place in the quantum well (QW) layer 300 and the layer 302 referred to as the “confining layer” serves to confine the carriers to the QW layer 300. To accomplish this, the confining layer 302 must have a significantly lower valence band edge in the case of a p type sensor or a significantly higher conduction band edge in the case of an n type sensor. A difference in band edge energy on the order of 0.4 eV or greater is considered significant for the purposes of good carrier confinement.

In a concrete realization of the structure depicted in FIG. 54b, the top and bottom confining layers 302 and 304 might be intrinsic silicon grown in the (100) plane. While the quantum well layer 300 could be p doped germanium. (also grown in the (100) plane which may be epitaxially grown on the silicon layer; boron, indium and gallium are examples of p dopants in germanium). The piezoresistive sensor could then be patterned in the <110> direction. The piezoresistive coefficient for <110> oriented p-type germainium is 50% larger than that for silicon oriented in the same direction. The valence band edge in germanium is 0.46 eV above that for silicon, which is sufficient to confine the carriers for this application.

These materials might also be used for realization of the piezoresistive layer of FIG. 54c with germainium once again serving as the quantum well 300 and intrinsic silicon as the lower layer 302.

This specific example of materials that may be used is not intended to limit the invention in any way. The field of confining carriers to 2DEGs or quantum wells is well developed and all of the knowledge and technology of the field may be used in the production of sensors such as those described herein.

Structures such as that described above will also have limits on the minimum thickness that may be attained both due to carrier confinement (due to finite well depth) and practical fabrication issues (due to the multiple layers). Even greater reduction in sensor thickness may be attained through the use of an insulator as the supporting layer such as shown in FIG. 55. Examples of materials that may be used for the insulating layer 306 are silicon dioxide or silicon nitride but this invention includes any insulator and should not be limited to these two.

The benefits of increased sensitivity as the thickness of a piezoresistive sensor is decreased was demonstrated in the section Sensitivity of Piezoresistive NEMS Displacement Transducers in Vacuum. The inventions described herein allow for a decrease in thickness beyond that which may be achieved using a convenional 2 layer structures of heavily doped silicon on intrinsic silicon.

Balanced Electronic Displacement Detection for VHF NEMS

A broadband radio frequency (RF) balanced bridge technique for electronic detection of displacement in nanoelectromechanical systems (NEMS) uses a two-port actuation-detection configuration, which generates a background-nulled electromotive force (EMF) in a DC magnetic field that is proportional to the displacement of the NEMS transducer. The effectiveness of the technique is shown by detecting small impedance changes originating from NEMS electromechanical resonances that are accompanied by large static background impedances at very high frequencies (VHF). This technique allows the study of experimental systems such as doped semiconductor NEMS and provides benefits to other high frequency displacement transduction circuits.

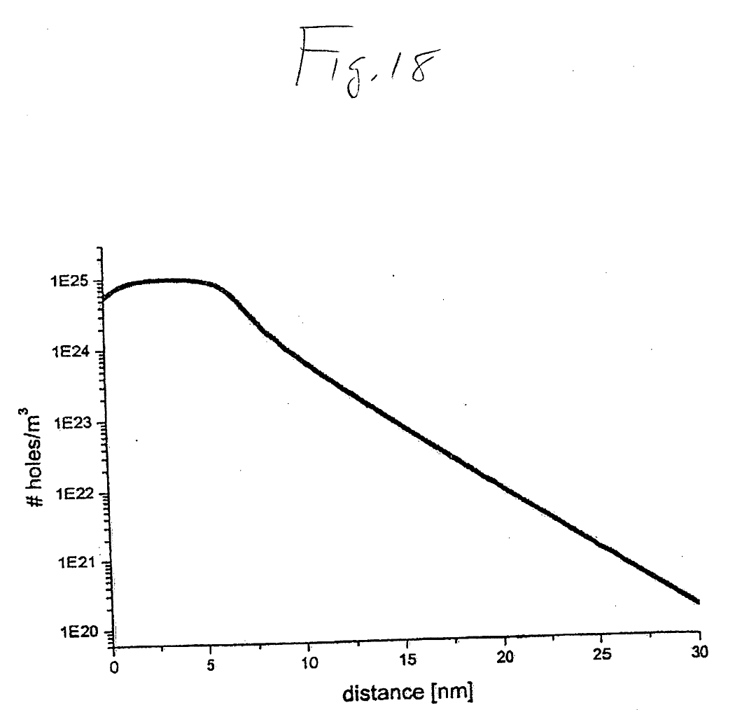

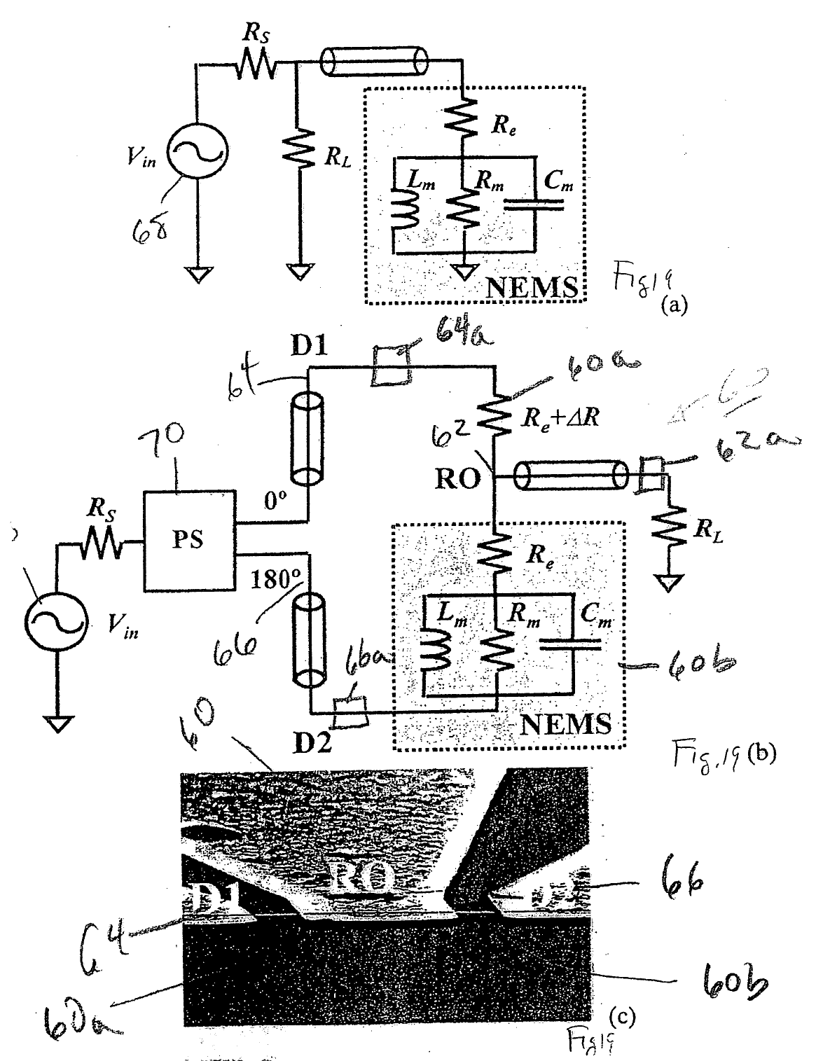

FIGS. 19a, 19b and 19c are directed to magnetomotive reflection and bridge measurements. While the illustrated embodiment is directed to magnetomotive NEMS devices, it is to be understood that the spirit of the invention includes all types of NEMS devices regardless of the means of inducing motion, such as electrostatic, thermal noise, acoustic and the like. FIG. 19a is a schematic diagram illustrating the magnetomotive reflection where there is only one NEMS device producing a signal, and FIG. 19b is a schematic diagram illustrating bridge measurements where there are two NEMS devices producing signals balanced against each other. In both measurements, a network analyzer 68 or other oscillator supplies a drive voltage, Vᵢₙ. In the bridge measurements in FIG. 19b, Vᵢₙ is split into two out-of-phase components by a power splitter 70 before it is applied to ports 64 and 66. R_{L} is the input impedance and Rₛ the source impedance of the network analyzer 68. In the illustrated embodiment both Rₛ=R_{L}=50 Ω.

The NEMS device 60b is modeled as a parallel RLC network in FIG. 19b, with a complex mechanical impedance, Zₘ(ω) and a DC coupling resistance, Rₑ. ΔR is the DC mismatch resistance between the NEMS devices 60a and 60b two arms of the bridge. The transmission lines, especially in bridge measurements at high frequencies, can disturb the overall phase balance if they have unequal electrical path lengths. FIG. 19c is a scanning electron microscope (SEM) micrograph of a representative bridge device of FIG. 19b, made out of an epitaxially grown wafer with 50 nm-thick n+ GaAs and 100-nm-thick intrinsic GaAs structural layers on top of a 1 μm thick AlGaAs sacrificial layer showing NEMS beams or devices 60a and 60b extending between detection port 62 and actuation ports 64 and 66. The Ohmic contact pads appear rough in the micrograph. The doubly clamped beams 60a, 60b have dimensions of 8 μm (L)×150 nm (w)×500 nm (t) and in-plane fundamental flexural mechanical resonance frequencies of about 35 MHz.

The balanced circuit shown in FIG. 19(b) with a NEMS transducer 60b on one side of the bridge and a matching effective resistor 60a of resistance, R≈Rₑ on the other side, is designed to improve the detection efficiency. The voltage, Vo(ω) at the read-out port 62 is nulled for ω≠ω₀ by applying two 180° out of phase voltages to the drive port 64 and drive port 66 in the circuit. We have found that the circuit can be balanced with exquisite sensitivity, by fabricating two identical doubly clamped beam transducers on either side of the balance point 62, instead of a transducer and a matching resistor.

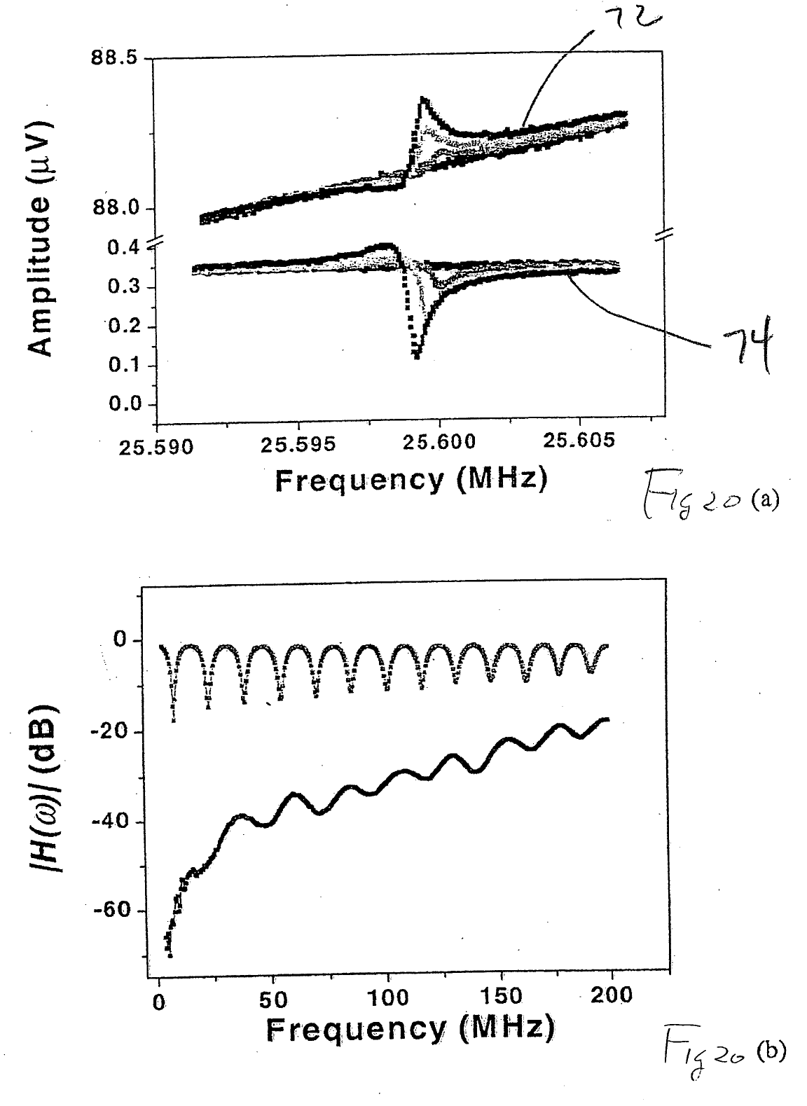

A representative device with the equivalent drive ports 64 and 66 and balance or detection point 62 is shown in the SEM microphotograph of FIG. 19(c). In such devices, we almost always obtained two well-separated mechanical resonances, one from each beam transducer 60a, 60b, with |ω₂−ω₁|>>ω₁/Q₁ where ω₁ and Q₁ are the resonance frequency and the quality factor of resonance of the transducers 60a, 60b, (i=1, 2 respectively) as graphically depicted in FIG. 21. The graph of FIG. 21 indicates that in the vicinity of the either mechanical resonance, the system is well described by the mechanical transducer-matching resistor model of the operational circuit of FIG. 19(b). We attribute this behavior to the high Q factors (Q≧10³) and the extreme sensitivity of the resonance frequencies to local variations of parameters during the fabrication process.

First, to clearly assess the improvements, we compare reflection and balanced bridge measurements of the fundamental flexural resonances of doubly clamped beams patterned from n+ (B-doped) Si as well as from n+ (Si-doped) GaAs. Electronic detection of mechanical resonances of these types of NEMS transducers 60a, 60b without metallization layers have proven to be challenging, since for these systems the two-terminal impedances can be quite high; Rₑ≧2 kΩ and Rₘ<<Rₑ. Magnetomotive beams normally require metallization in order to be driven, but in the case of bridge measurements the measurements are so sensitive that nonmetalized magnetomotive semiconductors beams can be used. Nonetheless, with the bridge technique described here, we have detected fundamental flexural resonances in the 10 MHz<f₀<85 MHz range for B-doped Si transducers and in the range from 7 MHz<f₀<35 MHz range for Si-doped GaAs beams. In all our measurements, the paradigm that Rₘ<<Rₑ remained true as Rₘ≦10 Ω and Rₑ remained in the range of 2 kΩ<Rₑ<20 kΩ.

Here, we focus on our results from n+ Si beams. These devices were fabricated from a B-doped Si on insulator wafer, with Si layer and buried oxide layer thicknesses of 350 nm and 400 nm, respectively. The doping was done at 950° C. and the average dopant concentration was estimated as Na≈6×10¹⁹ cm⁻³ from the average sheet resistance, R□≈60 Ω, of the sample. The fabrication of the actual devices was performed using conventional or standard methodologies employing optical lithography, electron beam lithography and lift off steps followed by anisotropic electron cyclotron resonance (ECR) plasma and selective HF wet-etches. After fabrication, samples were glued into a chip carrier and electrical connections were provided by Al wire bonds. The electromechanical response of the bridge at the point 62 was measured in a magnetic field generated by a superconducting solenoid.

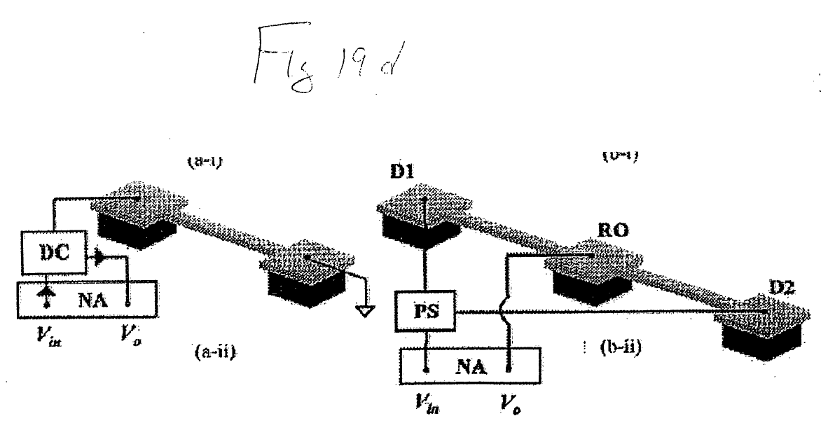

FIG. 20a is the graph of a doubly-clamped, B-doped Si beam resonating at 25.598 MHz with a Q about 3×10⁴ measured in reflection configuration in upper curves 72 and in bridge configuration for magnetic field strengths of B=0, 2, 4, 6 T in lower curve 74. The drive voltages are equal. The background is reduced by a factor of about 200 in the bridge measurements. The phase of the resonance in the bridge measurements are shifted 180° with respect to the drive signal as shown in FIG. 21. FIG. 20b is a graph of the amplitude of the broadband transfer functions for both configurations. The coupling between the actuation and detection ports in the bridge circuit is capacitive.

In particular, FIG. 20(a) shows the response of a device with dimensions 15 μm (L)×500 nm (w)×350 nm (t) and with Rₑ≈2.14 kΩ, measured in the reflection (upper curves) 72 and bridge configurations for several magnetic field strengths in curves 74. The device has an in-plane flexural mechanical resonance at 25.598 MHz with a Q≈3×10⁴ at T≈20 K. The DC mismatch resistance, ΔR was about 10 Ω. Note that a background reduction of a factor of about 200≈Rₑ/ΔR was obtained in the bridge measurements as shown in the analysis below.

FIG. 20(b) is a graph which shows a measurement of the wideband transfer functions for both configurations for comparable drives at zero magnetic field. Notice the dynamic background reduction by a factor of at least 100 in the relevant frequency range.

In metallized SiC beams 60a, 60b with Rₑ about 100 Ω and embedded within the bridge configuration, we were able to detect mechanical flexural resonances deep into the VHF band (Rₘ about 1 Ω). FIG. 21 is a graph which depicts a data trace of the in-plane flexural mechanical resonances of two 2 μm (L)×150 nm (w)×80 nm (t) doubly clamped SiC beams 60a, 60b. Two well-separated resonances are extremely prominent at 198.00 and 199.45 MHz, respectively, with Q factors about 10³ at T≈4.2 K. These beams were fabricated with Al and Ti top metallization layers of thicknesses of 20 nm and 3 nm, respectively, using a process described in below in regard to SiC beam fabrication.

NEMS devices 60a, 60b configured in a bridge can effectively be regarded as a two-port device with isolated actuation-detection ports 64-62, 66-62. Obviously, the coupling between the two ports 64, 66 is not solely of a mechanical nature, but the mechanical response dominates the electromechanical transfer function due to the dynamical nulling of the electronic coupling between the ports 64, 66.

We have recently demonstrated continuous frequency tracking by a phase locked loop (PLL) of the fundamental mechanical resonance a doubly clamped beam 60a or 60b configured in a bridge. Since the source impedance, Rₛ due to the power splitter is symmetric in both arms of the bridge, it is not explicitly incorporated into Z_{eq}′(ω), but can be regarded as part of Rₑ. In fact, replacing Rₑ with Rₑ+Rₛ would produce the more general form.

The voltage at point 62 in the circuit can be determined as

$$\begin{matrix}V ( ω ) = - \frac{{V}_{in} ( ω ) ( Δ R + Z ( ω ) )}{( {Z}_{m} ( ω ) + Δ R ) ( 1 + \frac{{R}_{e}}{{R}_{L}} ) + {R}_{e} ( 2 + \frac{{R}_{e}}{{R}_{L}} )} \\ = - \frac{{V}_{in} ( ω )}{{Z}_{eq}^{′} ( ω )} ( Δ R + {Z}_{m} ( ω ) )\end{matrix} \qquad 4.3$$

by analogy to equation 4.1. At ω=ω₀, we can define a detection efficiency similar to that of equation 4.2 for the signal S and background B:

$$\frac{S}{B} = \frac{{R}_{m}}{Δ R} \qquad 4.4$$

Given that ΔR is small, the detection efficiency becomes considerably higher than for the one port case. In the vicinity of the resonance, the background is suppressed by a factor of order Rₑ/ΔR, as confirmed by the measurements of FIG. 20(a). The inherent resistance mismatch ΔR, due to the fabrication, however, is not the ultimate limit to the background reduction.

Further balancing and hence background reductions can be obtained through insertion of a variable attenuator 64a and a phase shifter 66a in the opposite arms. The attenuator 64a will balance out the mismatch more precisely, while the phase shifter 66a will compensate for the phase imbalance created by the insertion of the attenuator 64a.

At higher frequencies, however, the circuit model of FIG. 19b, and hence the above expressions, become imprecise as is evident from the measurements of the transfer function. Capacitive coupling becomes dominant between the actuation ports 64 and 66 and the detection or balance port 62 at high frequencies as displayed in FIG. 20(b), and this acts to reduce the overall effectiveness of the technique. With careful design of the circuit layout and the bonding pads, such problems can be minimized.

Even further signal improvements can be obtained by addressing the significant impedance mismatch problem, Rₑ>>R_{L}, which exists between the output impedance, Rₑ and the amplifier input impedance, R_{L}. In the illustrated embodiment, e.g. in the measurements displayed in FIG. 20(a), this output impedance mismatch causes a signal attenuation estimated to be of order about 40 dB. Output impedance matching circuits 62a can be used to avoid the mismatch between the beams and the load resistance.

Energy Dissipation in NEMS Devices

Measurements on nanometer-scale doped beam transducers offer insight into energy dissipation mechanisms in NEMS devices, especially those arising from NEMS surfaces and surface adsorbates. In the frequency range investigated, 10 MHz<.f₀<85 MHz, the measured Q factors of 2.2×10⁴<Q<8×10⁴ in B-doped Si beams is a factor of 2 to 5 higher than those obtained from metallized beams. The comparison is strictly a qualitative one. We have compared Q factors of eight metallized and fourteen doped Si beams measured in different experimental runs, spanning the indicated frequency range. It has been suggested that both metallization layers and impurity dopants can make an appreciable contribution to the energy dissipation. Our measurements seem to confirm that at nanometer scales, metallization overlayers can significantly reduce Q factor. Second, the high Q factors attained and the surfaces that are free of metal films make these doped beams excellent tools for the investigation of small energy dissipation changes due to surface adsorbates and defects. In fact, efficient in situ resistive heating in doped beams through Rₑ has been shown to facilitate thermal annealing and desorption of surface adsorbates thereby yielding even higher Q factors. These devices are promising for studies of adsorbate-mediated dissipation processes.

In summary, we have developed a broadband, balanced radio frequency bridge technique for detection of small NEMS displacements. This technique may prove useful for other high frequency high impedance applications such as piezoresistive displacement detection. The technique, with its unique advantages, has enabled electronic measurements of mechanical resonances from systems that would otherwise be essentially unmeasurable.

Ultra High Frequency Silicon Carbide Nanomechanical Transducers

Nanomechanical transducers with fundamental mode resonance frequencies in the ultra-high frequency (UHF) band are fabricated from monocrystalline silicon carbide thin film material, and measured by magneto motive transduction, combined with balanced bridge read out circuit. The highest frequency among units which have been fabricated prior to the invention is a measured resonance of 632 MHz. The technique described here also holds clear promise in accessing the microwave L-band frequencies of mechanical motion, which carries great hope in studying the physics of mechanical motion at the mesoscopic scale, as well as in developing brand new technologies for the next generation of nanoelectromechanical systems (NEMS).

In the illustrated embodiment, we disclose the fabrication and measurement of ultra-high frequency silicon carbide nanomechanical transducers. Our measurement, which is based on the magnetomotive transduction has successfully detected resonance with frequencies above 600 MHz. Further, it is easy to see that our technique is not limited to the already achieved UHF frequency range. Microwave L-band (1 to 2 GHz) is also expected to be easily accessible by the same measurement setup with minor optimizations. The device fabrication process is similar to that described in Y. T. Yang et. al., Appl. Phys. Lett., 78, 162-164 (2001) with minor differences in terms of etch mask selection. The approach used here for nanometer-scale single crystal, 3C—SiC layers is not based upon wet chemical etching and/or wafer bonding. Especially noteworthy is that the final suspension step in the surface nanomachining process is performed by using a dry etch process. This avoids potential damage due to surface tension encountered in wet etch processes, and circumvents the need for critical point drying when defining large, mechanically compliant devices.

The starting material for device fabrication is a 259-nm thick single crystalline 3C—SiC film heteroepitaxially grown on a 100 mm diameter (100) Si wafer. 3C—SiC epitaxy is performed in an RF induction-heated reactor using a two-step, carbonization-based atmospheric pressure chemical vapor deposition (APCVD) process. Silane and propane are used as process gases and hydrogen is used as the carrier gas. Epitaxial growth is performed at a susceptor temperature of about 1330° C. 3C—SiC films grown using this process have a uniform (100) orientation across each wafer, as indicated by x-ray diffraction. Transmission electron microscopy and selective area diffraction analysis indicates that the films are single crystalline. The microstructure is typical of epitaxial 3C—SiC films grown on Si substrates, with the largest density of defects found near the SiC/Si interface, which decreases with increasing film thickness. A unique property of these films is that the 3C—SiC/Si interface is absent of voids, a characteristic not commonly reported for 3C—SiC films grown by APCVD.

Fabrication begins by defining large area contact pads by optical lithography. A 60-nm-thick layer of Cr is then evaporated and, subsequently, standard lift-off is carried out with acetone. Samples are then coated with a bilayer polymethylmethacrylate PMMA resist prior to patterning by electron beam lithography. After resist exposure and development, 30-60 nm of Cr is evaporated on the samples, followed by lift-off in acetone. The pattern in the Cr metal mask is then transferred to the 3C—SiC beneath it by anisotropic electron cyclotron resonance (ECR) plasma etching. We use a plasma of NF₃, O₂, and Ar at a pressure of 3 mTorr with respective flow rates of 10, 5, 10 sccm, and a microwave power of 300 W. The acceleration DC bias is 250 V. The etch rate under these conditions is about 65 nm/min.

The vertically etched structures are then released by controlled local etching of the Si substrate using a selective isotropic ECR etch for Si. We use a plasma of NF₃ and Ar at a pressure of 3 mTorr, both flowing at 25 sccm, with a microwave power 300 W, and a DC bias of 100 V. We find that NF₃ and Ar alone do not etch SiC at a noticeable rate under these conditions. The horizontal and vertical etch rates of Si are about 300 nm/min. These consistent etch rates enable us to achieve a significant level of control of the undercut in the clamp area of the structures. The distance between the suspended structure and the substrate can be controlled to within 100 nm.

After the structures are suspended, the Cr etch mask is removed either by ECR etching in an Ar plasma or by a wet Cr photomask etchant (perchloric acid and ceric ammonium nitrate). The chemical stability and the mechanical robustness of the structures allow us to perform subsequent lithographic fabrication steps for the requisite metallization step for magnetomotive transduction on the released structures. Suspended samples are again coated with bilayer PMMA and after an alignment step, patterned by electron beam lithography to define the desired electrodes. The electrode structures are completed by thermal evaporation of 5-nm thick Cr and 40-nm-thick Au films, followed by standard lift-off. Finally, another photolithography step, followed by evaporation of 5 nm Cr and 200 nm Au and conventional lift-off, is performed to define large contact pads for wire bonding.

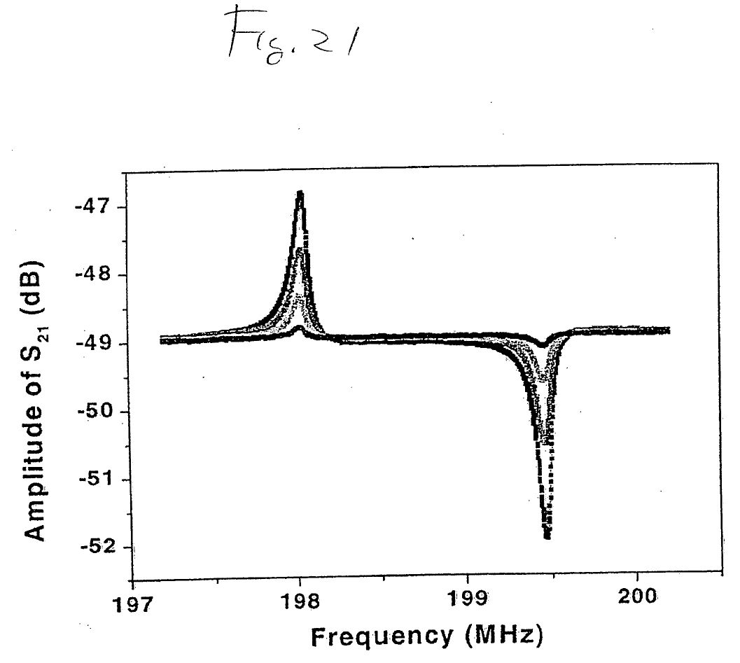

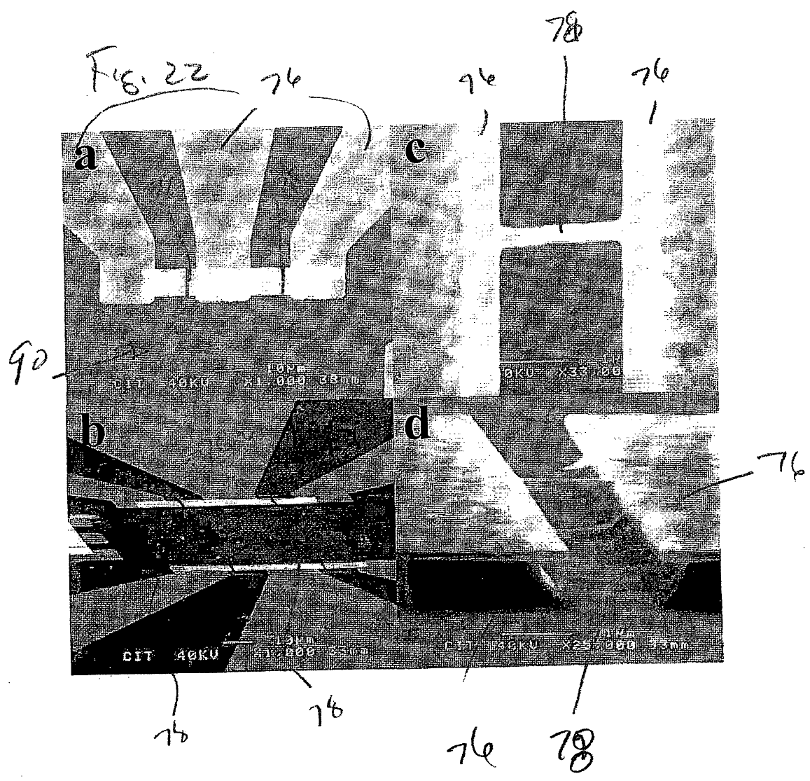

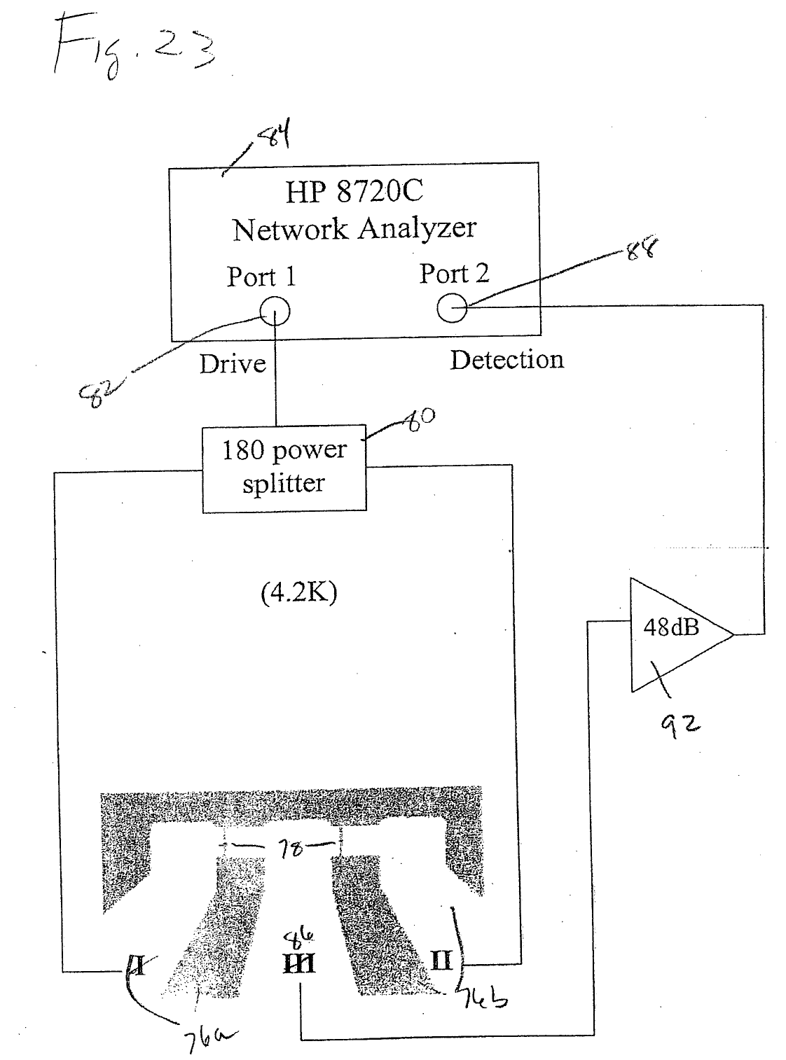

SEM micrographs of a completed device are shown in FIG. 22. The photos FIGS. 22a and 22b are the top view and sideview respectively, of the device region. The large area finger pads 76 are formed by thermally evaporated metal films of 6 nm of Cr for cohesion, followed by 80 nm of Au. The fine structures 78 of the device, defined by electron beam lithography, are covered by 36 nm of nickel film, deposited by electron beam evaporation. Such metal films, including Ni and Au, serve dual purposes, which are used as etch masks, and used for electrical conduction.

During the anisotropic electron cyclotron resonance (ECR) etch perpendicular to the wafer surface, the metal films comprising part of structure 78 serve to protect the mono crystalline 3C—SiC thin film underneath them. This first etching step exposes the substrate silicon material in areas not covered by metals. The following second ECR etching step, which slowly removes silicon material isotropically, will suspend the metallized silicon carbide beams 78 from the substrate. Each device 10 is comprised of two nominally identical doubly clamped beams 78. FIGS. 22c and 22d are zoom-in views of one of the two beams 78 in a device 10. Beam suspension can best be seen from the photo in FIG. 22d. Also from these photos, we can measure the geometry of the suspended beams to be roughly: a 1.25 μm length l, a 0.18 μm width w, and a 0.075 μm thickness, t. The thickness for the SiC film is obtained by subtracting 36 nm of the nickel thickness from a measurement of the beam overall thickness or height, since the nickel thickness reduction during the entire etching process is calibrated as negligible.

The metal masks which are used are retained as the conducting layer needed for magnetomotive transduction. A typical beam with nickel metallization has a measured resistance of about 90 Ohms, with the resistance mismatch in between the two beams 78 in the same device to be within 1-2%.

The sample is subsequently mounted on the sample holder (not shown), and wire bonded to 50 Ohm microstrip lines (not shown), which in turn are coupled to 50 Ohm coax cables (not shown). The cables and connections linked to the device finger pads 76a and 76b in the bridge circuit in FIG. 23 are made nearly identical, reaching up to the two output connectors of the 180° power splitter 80, which divides the driving power from port 82 of the HP8720C network analyzer 84 into two equal partitions, but with a phase difference of 180°. In a cryogenic measurement the device 10 sits in a dipper or instrument column, whose vacuum can or sample chamber is evacuated and immersed into liquid helium. An uniform static magnetic field is applied by a superconducting magnet (not shown), which has a field direction perpendicular to the doubly-clamped beams 78. When the RF current runs through the conducting layer of the beams 78, forces at the RF driving frequencies will be experienced by the beams 78. If the driving force frequency does not match the mechanical resonance frequency of beams 78, induced mechanical motion is minimal.

Terminal 86 will be the virtual ground in the ideal case, where the two beams 78 are exactly identical, as are the two branches of circuit components connected to them. Nonideality will introduce a residual background shift from the ideal virtual ground, as well as slightly different resonance frequencies of the two beams 78 in the device for the same mode. When the driving frequency matches the fundamental mode mechanical resonance frequency of one of the beams 78, resonant mechanical motion will occur for that beam 78. Such mechanical motion, which is perpendicular to the magnetic field, will induce an EMF voltage at the same frequency. This EMF voltage will act as an additional electrical generator, and affect the power transmitted out from terminal 86 of the device towards the detector port 88. Such power is then amplified and detected at port 88 of the network analyzer 84.

In the language of network analysis, we measure the frequency dependence of the forward transmission coefficient S₂₁ of the network. As known from definition, |S₂₁|² represents the power delivered to a matched load over the power incident on the input port. Information about the mechanical motion is revealed as resonance peaks in the spectra.

When the direction of applied magnetic field is in the plane of the wafer surface 90, which is the plane of FIG. 22a, and perpendicular to the beam 78, the direction of motion is perpendicular to the wafer surface 90 and is referred to as the out-of-plane resonance. A similar flexual mode, called in-plane resonance, will be excited when the magnetic field is perpendicular to the wafer surface 90. Such a mode involves resonant motion in the plane of the wafer surface 90.

For a device 10 that is nominally the same as the one shown in FIGS. 22a-22d, the out-of-plane resonance peaks are observed at 342 MHz and 346 MHz, which corresponds to the motion of the two beams 78 in the device 10, respectively. In-plane resonance measurement is also done after changing the orientation of the sample holder by 90°. The in-plane resonances are seen at 615 MHz and 632 MHz, respectively.

The expectation values of the resonance frequencies can be estimated using the equations below. The fundamental resonance frequency, f, of a doubly clamped beam of length, L, and thickness, t, varies linearly with the geometric factor t/L² according to the simple relation

$$f = 1.03 \sqrt{\frac{E}{ρ}} \frac{1}{{L}^{2}}$$

where E is the Young's modulus and r is the mass density. In our devices the resonant response is not so simple, as the added mass and stiffness of the metallic electrode modify the resonant frequency of the device. This effect becomes particularly significant as the beam size shrinks. To separate the primary dependence upon the structural material from secondary effects due to electrode loading and stiffness, we employ a simple model for the composite vibrating beam. In general, for a beam comprised of two layers of different materials the resonance equation is modified to become

$$f = \frac{η}{{L}^{2}} {( \frac{{E}_{1} {I}_{1} + {E}_{2} {I}_{2}}{{ρ}_{1} {A}_{1} + {ρ}_{2} {A}_{2}} )}^{\frac{1}{2}}$$

Here the indices 1 and 2 refer to the geometric and material properties of the structural and electrode layers, respectively. The constant η depends upon mode number and boundary conditions; for the fundamental mode of a doubly clamped beam η=3.57. Assuming the correction due to the electrode layer (layer 2) is small, we can define a correction factor K, to allow direct comparison with the expression for homogeneous beam

$$f = \frac{η}{{L}^{2}} {( \frac{{E}_{1} {I}_{10}}{{ρ}_{1} {A}_{10}} )}^{\frac{1}{2}} , \\ where$$

$$K = \frac{{E}_{1 } {I}_{1} + {E}_{2} {I}_{2}}{{E}_{1} {I}_{10}} \frac{1}{1 + \frac{{ρ}_{2} {A}_{2}}{{ρ}_{1} {A}_{1}}}$$

In this expression, I₁₀ is the moment calculated in the absence of the second layer. The correction factor K can then be used to obtain a value for the effective geometric factor, [t/L²]_{eff} for the measured frequency. Further nonlinear correction terms, of order higher than [t/L²]_{eff} are expected to appear if the beams are under significant tensile or compressive stress. The linear trend of our data, however, indicates that internal stress corrections to the frequency are small.

The measured resonance frequencies are about 30% lower than such estimates. The discrepancies are not surprising, comparing to what was encountered in our previous work at a lower frequency range. In particular, when the size of the device shrinks down, the role of surface, defects and non-ideal clamping etc. will become increasingly important. These factors are not considered in such predictions.

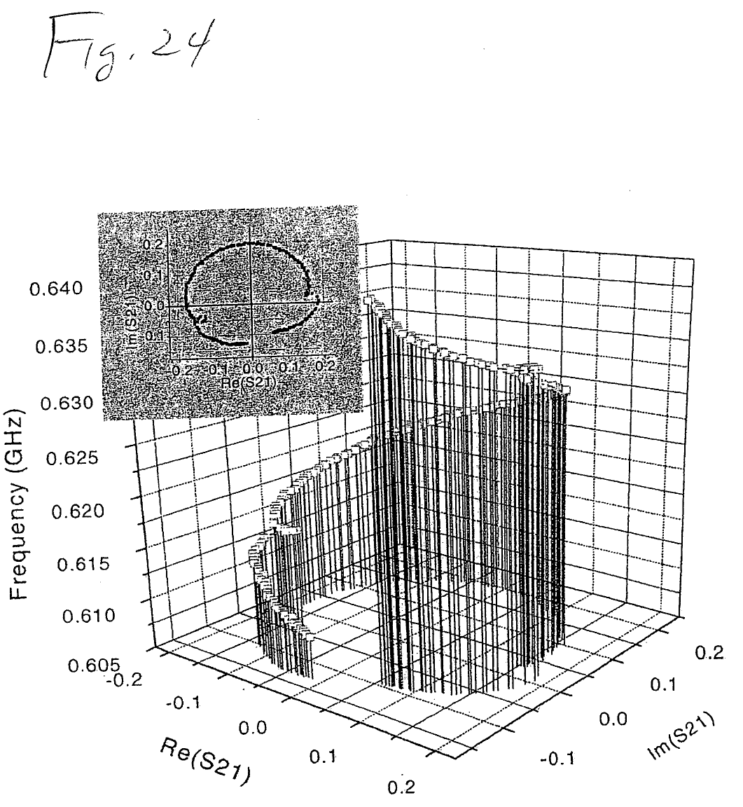

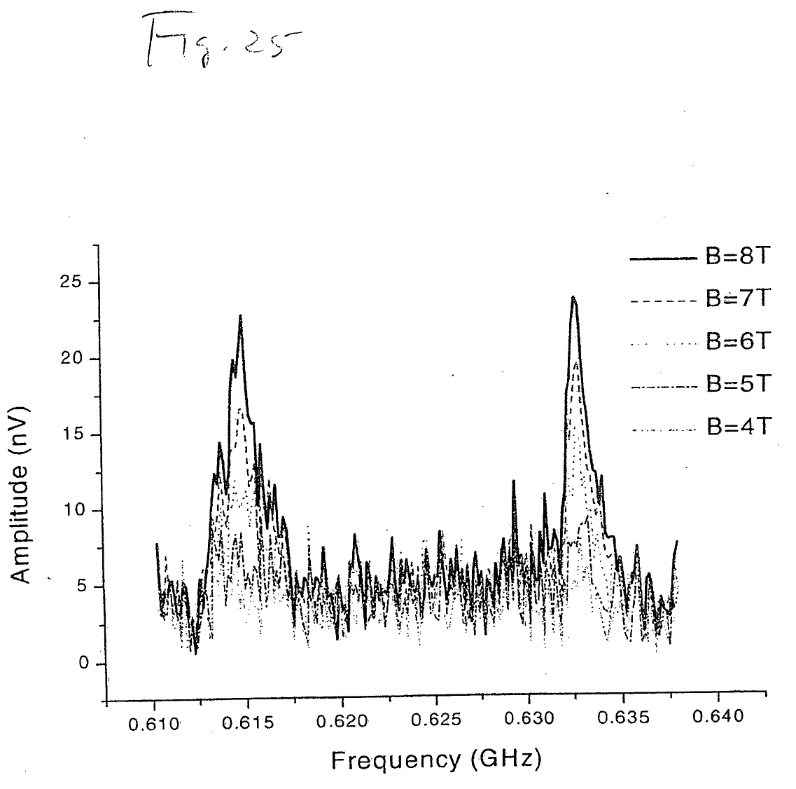

The in-plane resonance data is shown in FIG. 24, whereby magnetic field is 8 Tesla, driving power is −60 dBm, with a resolution bandwidth equal to 10 Hz. The frequency dependence of the forward transmission coefficient is plotted. The insert shows the projection of the complex function onto the S₂₁ plane. Two resonance peaks are observed at about 180° phase difference, as expected. In these data, information about both the mechanical transducer and the electrical connections is presented. To extract information about the mechanical resonant structure, we subtract the background, which is also a complex-valued function of frequency, fitted from data points taken away from the resonance peaks. After subtracting background, the amplitude of the resulting function is plotted in FIG. 25. Within experimental error the de-embedded amplitude peaks can be fitted to Lorentzian shape and the peak height is roughly proportional to B², as expected.

The amplitude axis of FIG. 25 is normalized, so that its value represents the signal voltage referred back to the input of the cryoamp 92. Such normalization can be easily done using the definition of network forward transmission coefficient, together with the knowledge of the gain (48 dB) of the amplifier 92. In such estimates, we ignore the loss from the coax cables. Also ignored is the effect from the impedance mismatch at the device output, which in our case should only contribute a factor in the order of unity. Under such simplification, the signal voltage referred to the input of the cryoamp 92 represented in FIG. 25, can be considered approximately the EMF voltage generated by the magnetomotive transduction, which can be expressed by
V_{emf}˜BL2πf₀A 5.1
where L is the length of the beam, f₀ is the resonance frequency, B is the magnitude of the magnetic field, and A is the displacement amplitude of the mechanical motion. We thus obtain the maximum amplitude of the motion is about 7×10⁻³ Å under 8 Tesla magnetic field.

Using the same expression, we can also estimate the displacement sensitivity, if the noise voltage per √Hz is known. In general, the detection sensitivity is limited by the Johnson noise from beam resistance, and the noise from the pre-amplifier 92. These two noise sources are comparable to each other, since the experiment is done at liquid helium temperature. Beam resistance is typically a few teens of Ohms, and the noise temperature of the MITEQ cryogenic amplifier 92 is in the order of a few Kelvin in the frequency range of interest. The combined noise is effectively a noise temperature of about 10 K referred to the input, which corresponds to a noise voltage per √Hz of 150 pV/√Hz. This in turn gives a displacement sensitivity of about 5×10⁻⁵ Å/√Hz. In reality, the noise estimated from FIG. 25 is higher than the above values by a factor of a ______. This additional noise reflects the receiver sensitivity of the network analyzer 84.

For the purpose of this particular illustration, we did not attempt to optimize the noise performance of the system. However, it is essentially trivial to do so, by adding a reasonably low-noise second stage amplifier (not shown) with −40 dB gain after the cryoamp 92, so as to utilize the full capabilities of the ultra low noise feature of the cryoamp 92.

As a first order approximation, we know that the resonance frequency for in-plane case

$${f}_{0} = \sqrt{\frac{E}{ρ}} \frac{W}{{L}^{2}} \qquad 5.2$$

Where W, L is the width and length of the beam, respectively. E is the Young's modulus, ρ is the mass density. Combining Eqn. 5.1 and 5.2 we have

$${V}_{emf} ∝ BA \sqrt{\frac{E}{ρ}} \frac{W}{L} \qquad 5.3$$

From Eqn. 5.2, we know that shrinking the size of the beam in all three dimensions by the same ratio, using the device described above as the starting point, can easily get the resonance frequency into the microwave L-band. Such scaling down is readily achievable by current technology of e-beam lithography. On the other hand, Eqn. 5.3 tells us that the signal amplitude will not be significantly reduced, as long as we keep the same B field, the same material, and similar amplitude of mechanical motion.

In conclusion, we have demonstrated the measurement of silicon carbide nanomechanical transducers with fundamental resonance frequencies in the UHF range, and the microwave L-band frequencies as well by the same technique. This gives access to frequency bands of mechanical motion, which were never inaccessible before.

Frequency Tuning of MEMSINEMS Transducers by the Lorentz Force

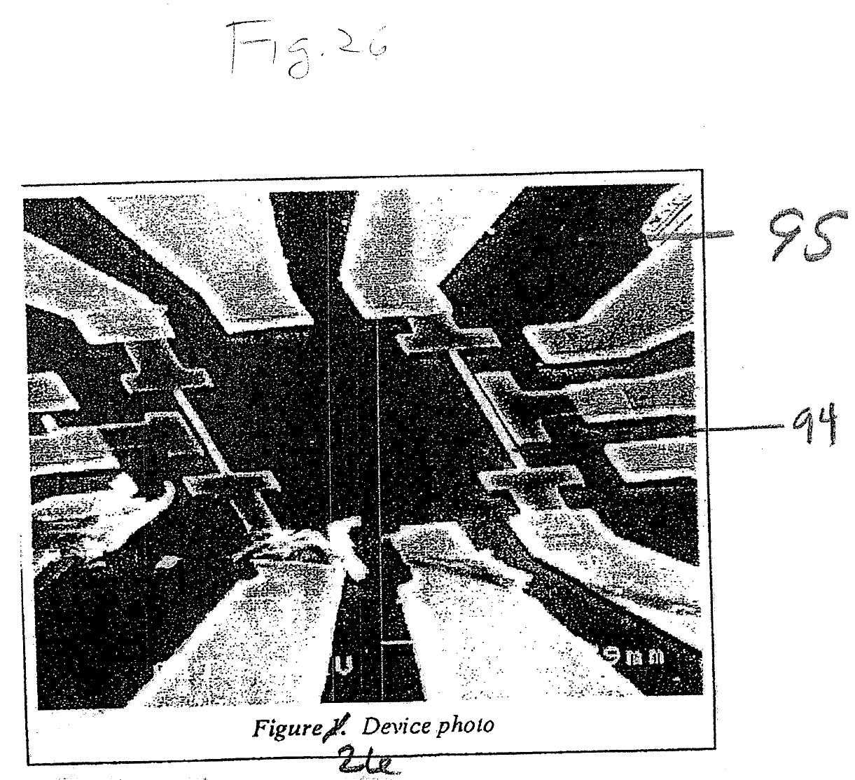

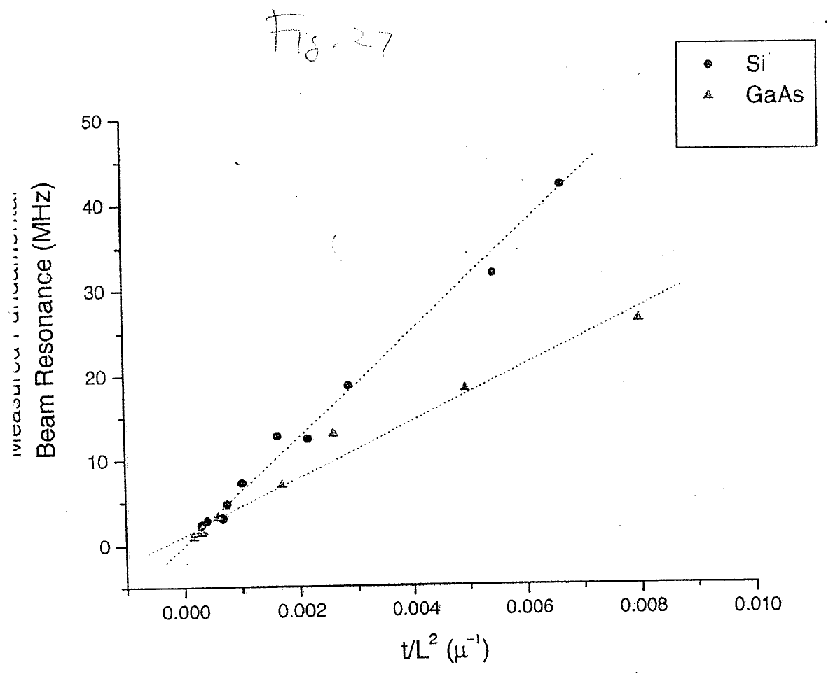

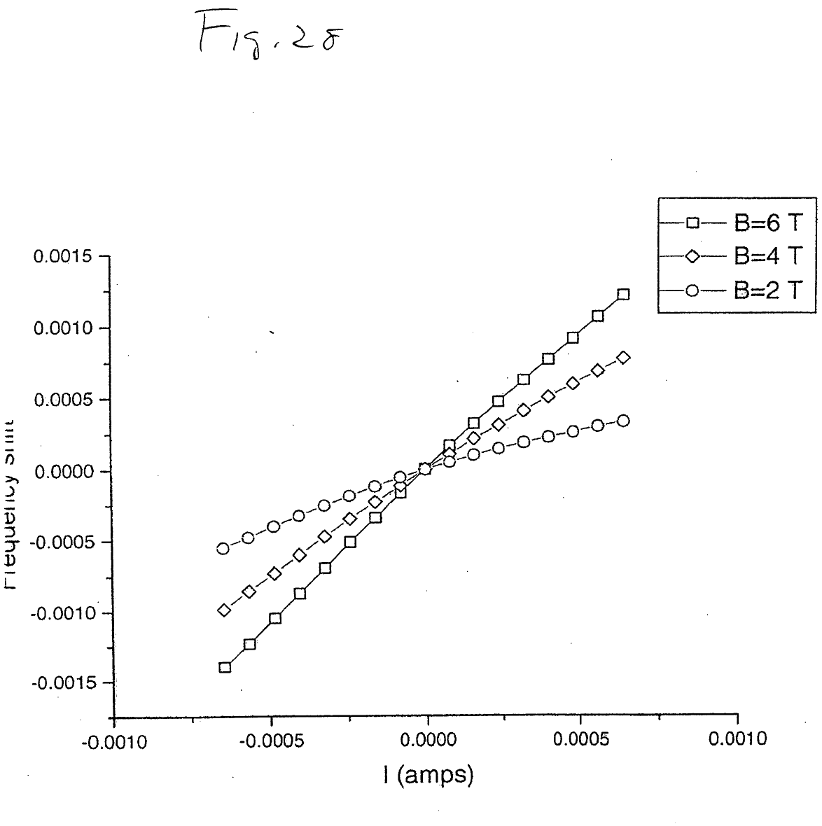

The resonance frequency of a magnetomotive NEMS transducer can be fine tuned by varying the static stress applied to the resonating beam by means of a Lorentz force device from a DC current passed through the beam. We have performed all of our measurements on doubly clamped beams 94 such as those displayed in the SEM photograph of FIG. 26. These beams were microfabricated out of GaAs and Si. In order to electrically couple to these mechanical structures, we patterned thin Au or Al electrode layers of d≈50 nm on top of the beams 94. Several beams 94 with different lengths of 50 μm<L<70 μm and with fixed w=1.5 μm and t=0.8 μm were used for the force tuning experiments, covering a frequency range of 1 MHz<ω₀/2π:<3.5 MHz. For investigations of the temperature variations of the frequency, several beams with differing aspect ratios (4 MHz<f<40 MHz) were fabricated on the same chip, and the resonance frequency was recorded as the temperature was varied.

A magnetomotive excitation and detection scheme was used for the measurements. Briefly, a network analyzer 96 was used to drive an alternating current (AC) along an electrode (not shown) on top of the beam 94, which was placed in the bore of a superconducting magnet (not shown) at 4.2 K. The Lorentz force due to this AC current excited the beams 94 and the electromotive force generated by the motion was detected by the network analyzer 94. The frequency shift data were obtained from the resonance curves by inspection.

The tuning force was introduced by running a direct current (DC) as well as the AC drive current through the electrode. The DC current in a constant magnetic field subjects the beam to a constant Lorentz force per unit length, T=IB, where I is the current and B the magnetic field. Two different geometries were investigated in these experiments. In the first case, the beams 94 were excited perpendicular to the plane of the chip (defined as the z-direction) and were subjected to a constant force in the same direction via the DC current flow. In the second case, the beam was rotated through a 90° angle with respect to the magnetic field and the excitation and the tensile forces were in plane (x-y plane).

The motion of the doubly clamped beams 94 can be modeled by the beam equation:

$$\frac{{\partial }^{4} u ( x , t )}{\partial {x}^{4}} - \frac{σA}{EI} \frac{{\partial }^{2} u ( x , t )}{\partial {x}^{2}} = - \frac{ρA}{EI} \frac{{\partial }^{2} u ( x , t )}{\partial {t}^{2}}$$

where σ is the tensile or the compressive stress in the beam, A and I are the cross-sectional area and moment of the area, respectively. E is the Young's modulus and ρ is the mass density of the material as usual, t is time, x is the distance along the beam and u is the displacement of the beam in the direction of excitation.

To present a more general discussion, we have included an internal stress term in the beam equation. However, our analysis below shows that internal stresses do not modify significantly the observed beam resonances. The frequency of the fundamental resonance can be derived from the above equation as

$${ω}_{0} = 1.03 \frac{t}{{L}^{2}} \sqrt{\frac{E}{12 ρ} ( 1 + \frac{12 {L}^{2} σ}{4 {π}^{2} {Et}^{2}} )}$$

where t and L are the beam thickness and length respectively and E is the Young's modulus.

We have measured the resonance frequencies of up to 30 Si and GaAs beams. FIG. 27 shows the measured fundamental frequency of the beams 94 as a function of the aspect ratio, t/L². The fact that we obtain linear dependence of the resonance frequency, f on t/L² suggests that the corrections to f, due to various internal stresses in the beam 94 are very small. The measured E/ρ values from the slopes in FIG. 27 are only within 75% of the calculated values. This, however, can be explained by the frequency lowering effects of unintended undercuts in the semiconductor sacrificial layer that might change the effective length by up to 10% and mass loading effects due to the electrode layers disposed on the beam for the magnetomotive current (not shown).

i) Lorentz Force Tuning:

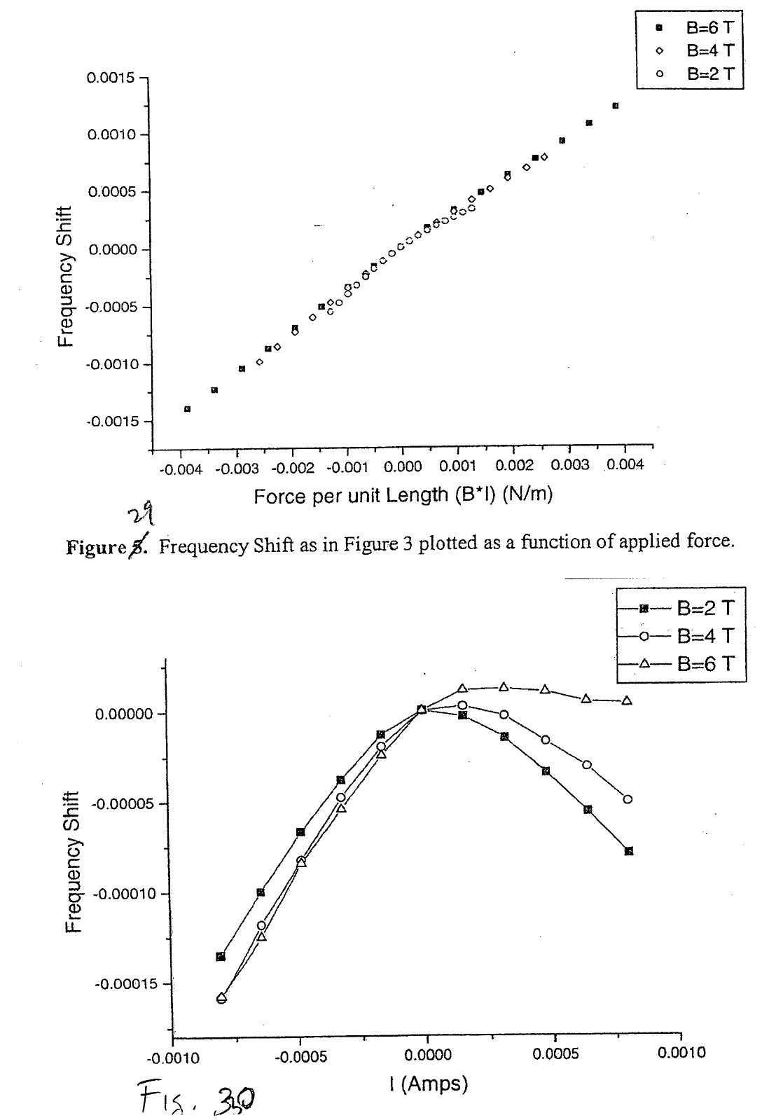

In FIG. 28, we present the Lorentz force tuning curves of the out-of-plane resonance of a 1.177 MHz beam 94. The frequency shift, δf_{z}/f_{z}, where δf_{z} is the change in frequency for a z-direction or out-of-plane excitation and f_{z} is frequency for a z-direction or out-of-plane excitation frequency, as a function of the applied DC current is plotted at three different magnetic fields. The fact that the plots collapse onto the same curves shown in FIG. 30 reassures that this effect is indeed a force tuning effect. The apparent curvature at the lowest fields is due to the heating effect of the DC current, as will be discussed below. We note that qualitatively similar curves were obtained for four different GaAs samples with 1<f<3 MHz.

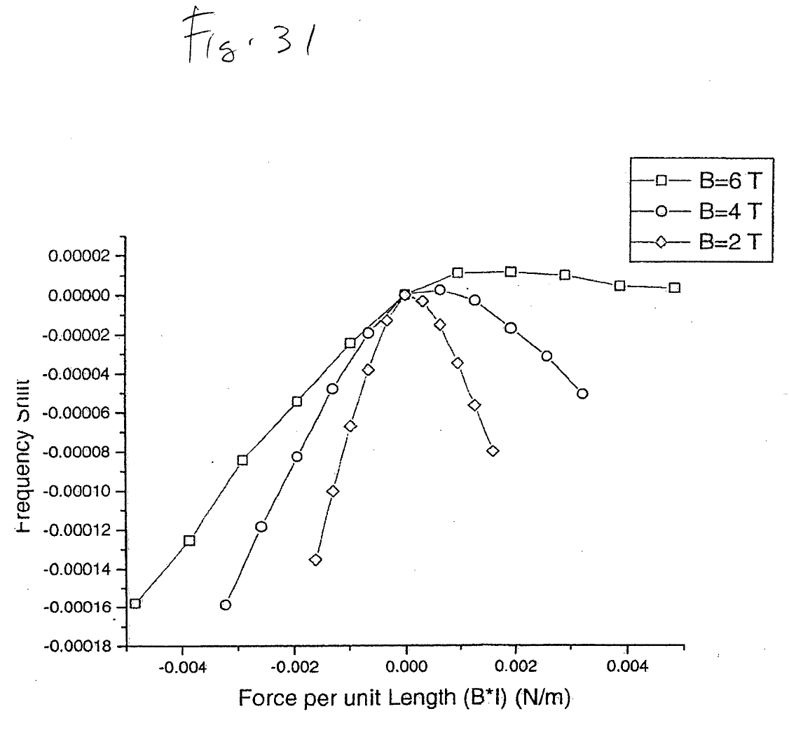

FIG. 29 shows the normalized in plane frequency shift, δf_{xy}/f_{xy}, of the same beam 94 for in-plane excitation as a function of the current for different magnetic field strengths. The lack of symmetry in the data becomes more evident as the magnetic field strength is increased. The tuning plotted as a function of the applied force per unit length in FIG. 31 implies that the force tuning effects in this plane are very weak and are probably obscured by the frequency lowering effects of heating.

Ii) Thermal Tuning:

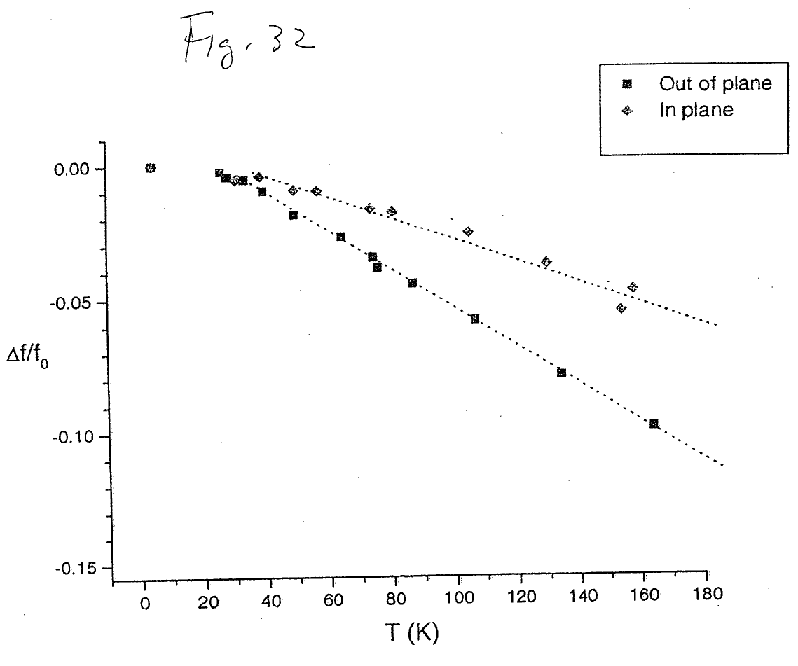

The temperature variations of the normalized out-of-plane and in-plane frequencies of a GaAs beam covered with a thin Au layer are shown in FIG. 32. It is important to note that the two modes exhibit different temperature coefficients with the stiffer mode showing the least change. In this case the beam dimensions w×t×L were 1.5×0.8×70 microns. The out-of-plane and in-plane resonances were at f_{z}=1.177 MHz and f_{xy}=1.838 MHz respectively. A similar effect was observed in a Si beam with slightly higher frequencies (f_{z}=2.830, f_{xy}=2.328 MHz).

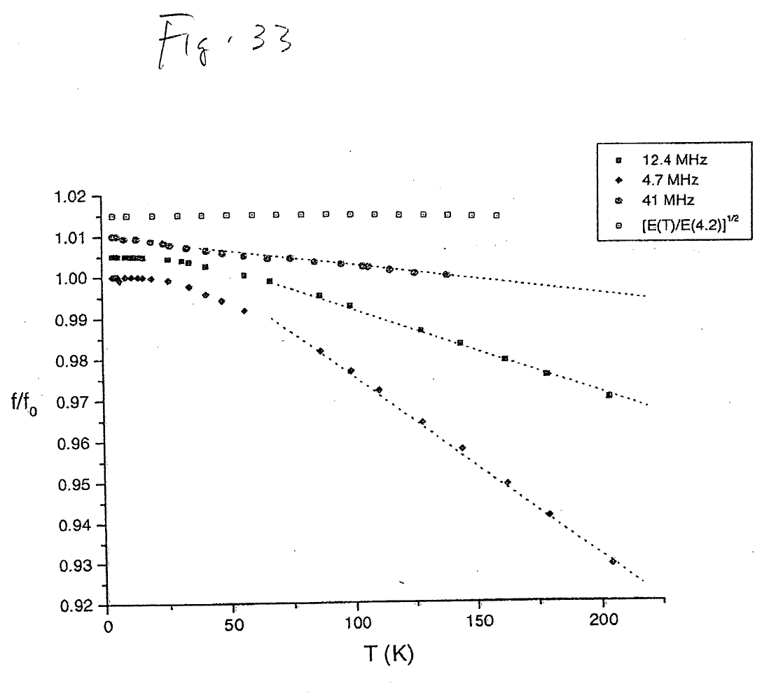

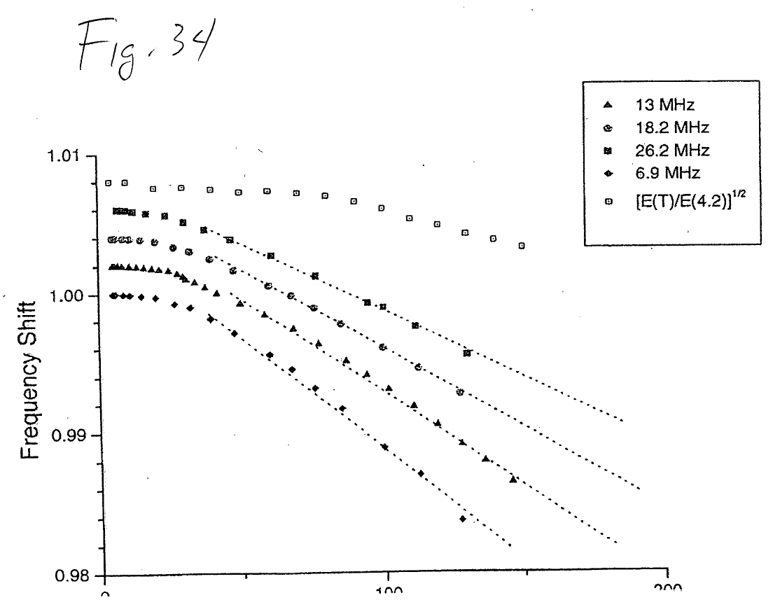

The data of FIG. 32 is suggestive that thermal tuning will be weak in very stiff structures. This expectation is verified by measuring temperature dependence of the resonance frequencies of a number of beams 94 with a range of frequencies. The data for Si and GaAs are displayed in FIGS. 33 and 34 respectively. Also plotted on the data for both materials is the variation of the sound velocity given that the density charge is negligible over the temperature range. Any conventional source of heating and cooling can be employed to vary the temperature.

i) Lorentz Force

We have argued above that the intrinsic stresses in the beams do not contribute appreciably to the observed resonance frequencies of our structures (see FIG. 27). We will analyze the tuning problem by assuming a neutral beam and by adding a stress term due to the constant Lorentz force. We therefore start by reviewing the response of a clamped beam to constant stresses axial with the beam, which we later relate to the Lorentz Force. The equation of motion for small amplitudes around the equilibrium point, is

$$\frac{{\partial }^{4} u ( x , t )}{\partial {x}^{4}} - \frac{σA}{EI} \frac{{\partial }^{2} u ( x , t )}{\partial {x}^{2}} = - \frac{ρA}{EI} \frac{{\partial }^{2} u ( x , t )}{\partial {t}^{2}} \qquad 6.1$$

where σ is the tensile or the compressive stress in the beam, A and I are the cross-sectional area and moment of the area, respectively. E is the Young's modulus and ρ is the mass density of the material as usual. The frequency of oscillation for the stressed case, (ω₀′) for clamped boundary conditions, can be obtained by solving the above equation:

$${ω}_{0}^{′} = 1.03 \frac{1}{{L}^{2}} \sqrt{\frac{EI}{ρ A} ( 1 + \frac{{AL}^{2} σ}{4 {π}^{2} EI} )} = {ω}_{0} \sqrt{1 + \frac{3 {L}^{2} σ}{{π}^{2} {Et}^{2}}} \qquad 6.2$$

In this equation, L and t are the length and thickness of the beam 94, respectively. The resonance frequency can increase or decrease depending on the nature of the stress, i.e. compressive or tensile.

A small constant transverse force per unit length modifies the equilibrium shape of the beam 94. A beam 94 under the effect of such a pull assumes elastically a shape described by

$$u ( x ) = \frac{τ}{24 EI} {{x}^{2} ( x - L )}^{2} \qquad 6.3$$

where T is the constant force per unit length on the beam. This force causes the beam to elongate and hence results in a tensile stress. The tensile stress due to T is given by

$$σ = E \frac{Δ L}{L} = \frac{1}{60480} \frac{{L}^{6}}{{Et}^{2}} {τ}^{2} = \frac{1}{420} \frac{{L}^{6}}{{Ew}^{2} {t}^{6}} {τ}^{2} \qquad 6.4$$

Therefore the new resonant frequency using eqn. 6.2 is

$${ω}_{0}^{′} = {ω}_{0} \sqrt{1 + \frac{1}{140 {π}^{2}} {( \frac{L}{t} )}^{8} \frac{{τ}^{2}}{{E}^{2} {w}^{2}}} . \qquad 6.6$$

Note that the frequency shift is positive for all transverse forces.

The expression for frequency shift for the constant force per unit length, T=IB, takes the form

$${ω}_{0}^{′} = {ω}_{0} \sqrt{1 + \frac{1}{140 {π}^{2}} {( \frac{L}{t} )}^{8} \frac{{I}^{2} {B}^{2}}{{E}^{2} {w}^{2}}} \qquad 6.7$$

The prefactor for our GaAs beams with L/t≈50 and w=1 μm is of order 10⁰ in metric units. The maximum force per unit length applied is 4×10⁻³ N/m. Therefore we can safely expand the frequency shift as

$$Δ ω \approx {ω}_{0} ( \frac{1}{280 {π}^{2}} {( \frac{L}{t} )}^{8} \frac{{I}^{2} {B}^{2}}{{E}^{2} {w}^{2}} ) \qquad 6.8$$

This expression estimates a normalized frequency shift of order 10⁻⁵-10⁻⁶ for our beams 94. Our measurements, however, deviate from the above expressions in several significant ways. First, the measured frequency shift is asymmetric for the resonance in the z direction, and we encounter with negative frequency shift for forces pulling the beam towards the substrate 95. The effect we are observing is significantly larger and is linear in both variables B and I.

The method to apply the constant force per unit length, however, causes complications in the case of Lorentz force tuning. The constant current I produces a local temperature increase estimated to be about 5 to 10 K. Therefore the measured frequency shift is a more detailed function of the applied current and hence force:
Δf=Δf_{tuning}(I,B)+Δf_{heating}(I)

This effect becomes more apparent as the magnetic field strength B goes to zero. In the case of B=0, we would expect a completely symmetric curve in I. As seen in FIG. 29 the frequency shift curve becomes more symmetric as the tuning force becomes smaller. In FIG. 35 we plot the data in FIG. 29 after subtracting the even component, which we assume is due to heating. Note the similarity of FIG. 35 to FIG. 28. However, the effect in FIG. 35 is an order of magnitude smaller.

We do not understand the origin of the asymmetric tuning observed in both cases. Asymmetric tuning of this kind could be observed in buckled structures, however observed beam resonance frequencies in our experiments indicate that our beams are far away from the buckling transition. The interesting temperature dependencies of the resonance frequencies in FIGS. 32 and 33 suggest that resonant frequency shift with temperature is not responsible for the observed behavior. The observed effects might be due the stresses formed in the semiconductor-contact metal bilayer. Single component beams made out of polycrystalline metals and single crystalline highly doped semiconductors eliminate the above mentioned stresses.

Ultimate Limits of Displacement Detection with Flexural and Torsional Transducers Using Magnetomotive Transduction

In the illustrated embodiment we quantify the performance of the magnetomotive detection technique in the context of micromechanical transducers. We outline the factors which limit its displacement sensitivity at frequencies from 1 MHz to 1 GHz. We evaluate the sensitivity for realistic systems and instruments, and show that it is possible to attain the thermomechanical noise limit of sensitivity at 1 GHz.

i) Magnetomotive Transduction

In the presence of a magnetic field, mechanical motion perpendicular to the field induces an electromotive force (EMF) perpendicular to both. An electrode on the moving object transmits the induced voltage signal or EMF to a detector. Let us evaluate the magnetomotive transduction of a mechanical transducer's motion. At frequencies close to a normal mode of the transducer, and at low amplitudes, its motion is well-described by a damped simple harmonic oscillator, with an effective mass m and effective spring constant k:

$$m \frac{{ⅆ}^{2} y ( t )}{ⅆ {t}^{2}} + γ m \frac{ⅆ y ( t )}{ⅆ t} + ky ( t ) = F ( t )$$

γ denotes the damping coefficient arising due to the coupling of motion to internal and external degrees of freedom which cause dissipation. The value of m depends on the mode shape, and the value of k depends on how the force F is applied and the location at which the displacement z is measured. For a straight doubly-clamped beam of length L, thickness t, and width w, vibrating in its fundamental flexural mode in the t direction, the spring constant measured at the center of the beam for a uniform force is:
k=32E(t/L)³w
where E is the elastic constant of the material.

The EMF per unit length induced in the detection electrode at the coordinate x along the electrode is

$${V}_{0} ( x , t ) = B \frac{ⅆ y ( c , t )}{ⅆ t} sin θ ( x )$$

where y is measured perpendicular to the field and θ is the angle between the electrode and the field, B. By integrating along the length Lₑ of the detection electrode, the total voltage can be expressed in terms of a geometric factor ζ as:

$${\overline{V}}_{0} ( t ) = ξ {L}_{e} B \frac{ⅆ y ( t )}{ⅆ t}$$

For the fundamental flexural mode of a straight doubly-clamped beam, ζ=0.53 if displacement is measured at the center. At the resonance frequency ω₀, then, the efficiency of magnetomotive transduction is given by:
V₀≅2πξLBf₀y₀
We thus define the responsivity R of the device as follows:

$$R = \frac{{V}_{0}}{{y}_{0}} = 2 πξ {LBf}_{0}$$

(ii) Magnetomotive Circuit Model

For a high Q transducer driven by the Lorentz force F=Bl_{d}L_{d} on a drive electrode of length L_{d}, magnetomotive transduction yields a Lorentzian line shape centered at the resonance frequency ω₀=√(k/m):

$${V}_{0} ( ω ) = \frac{ⅈ {ωω}_{0}^{2} ξ {L}_{e} {LB}^{2} / k}{{ω}_{0}^{2} - {ω}^{2} + ⅈγω} {I}_{d} ( ω )$$

For a straight doubly-clamped beam, the fundamental frequency for vibration in the thickness direction is:

$${f}_{0} = 1.03 \frac{t}{{L}_{2}} \sqrt{\frac{E}{ρ}}$$

where ρ is the mass density of the material.

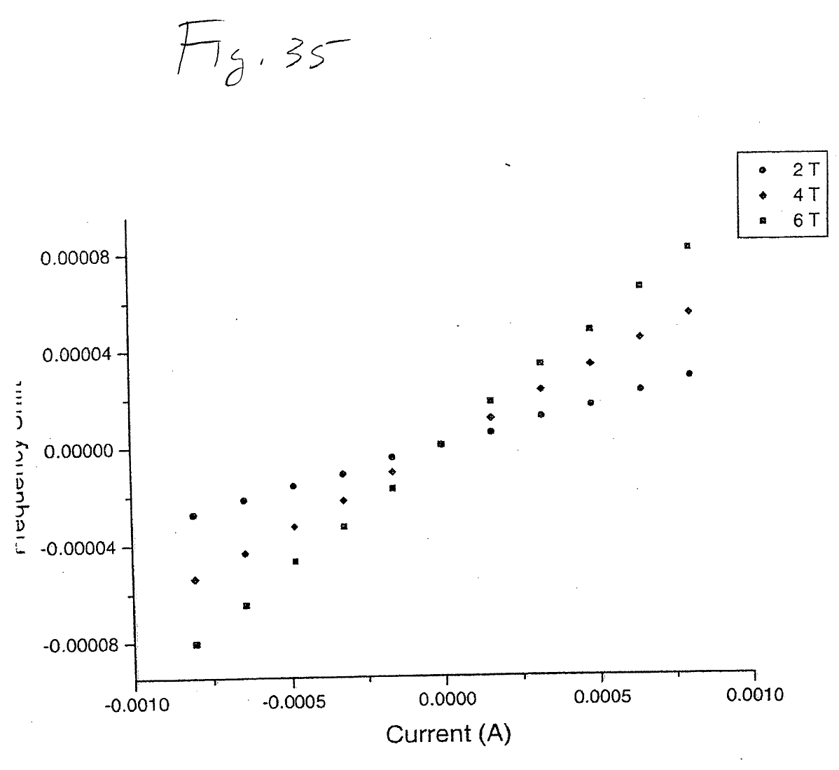

The equation of motion has the same form as that of the voltage generated in a parallel LCR circuit schematically shown in FIG. 36, so analogous electrical parameters for the mechanical system can thus be defined as follows.

$$\begin{matrix}{R}_{m} = \frac{ξ {L}^{2} {B}^{2} {ω}_{0}}{k} Q \\ {C}_{m} = \frac{k}{ξ {L}^{2} {B}^{2} {ω}_{0}}\end{matrix}$$

$${L}_{m} = \frac{ξ {L}^{2} {B}^{2}}{k}$$

The quality factor Q describes the dissipation of the energy of motion, and is related to the damping coefficient: γ=ω₀/Q. Mechanical dissipation is thus represented by a mechanical resistance. For the fundamental resonance ω₀ of a doubly-clamped silicon beam,

$${R}_{m} = .004444 \frac{{B}^{2} Q}{{wt}^{\frac{1}{2}} {f}^{\frac{3}{2}}}$$

The amplitude of motion is proportional to the electrical amplitude across the LCR transducer by the responsivity.

In principle, the technique used to generate the transducer's motion is not directly relevant to its detection. However, in practice, due to space constraints on submicron transducers it is often convenient to use a single electrode on the surface of the beam for both drive and detection. In the magnetomotive scheme, by passing an alternating current through the electrode perpendicular to the field, an oscillating Lorentz force can be applied to the device. Our analysis will be divided into two qualitatively different cases: the one-port case, in which a single electrode serves as both magnetomotive drive and detection, and the two-port case, in which the detection electrode is separate. The two-port case is relevant to the measurement of the transducer's response to an external stimulus in the absence of magnetomotive drive.

One-Port Case:

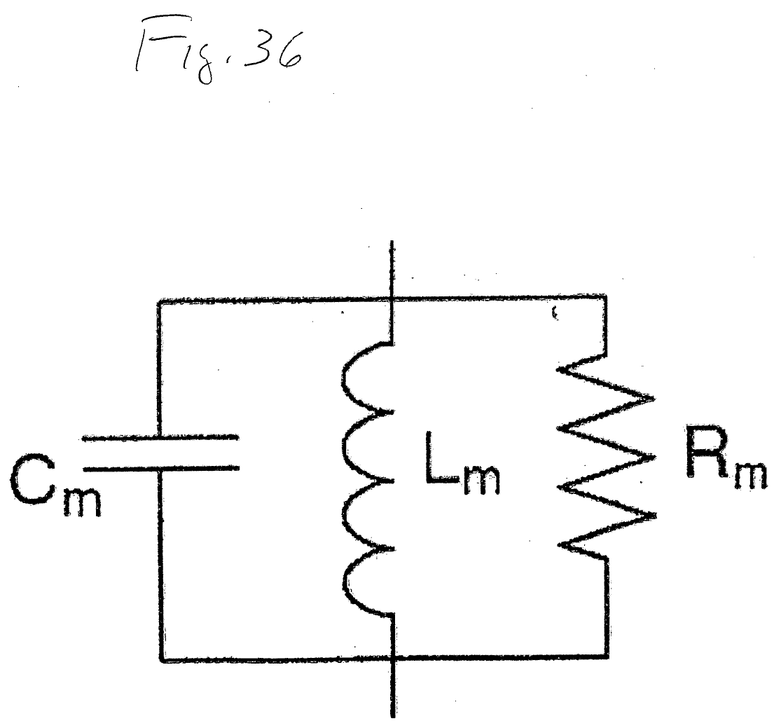

The one-port circuit model is shown in the schematic of FIG. 37. The resistance 96, Rₑ, denotes the DC resistance of the electrode and the resistance 98, R_{L}, the detector's input impedance. The resistance 100, R_{0,} provides a large embedding impedance to make the drive a current source 102. The device is connected to the drive 102 by a 50 Ω transmission line 104. The RLC circuit of FIG. 36 is coupled between resistance 96, Rₑ, and ground.

Two-Port Case:

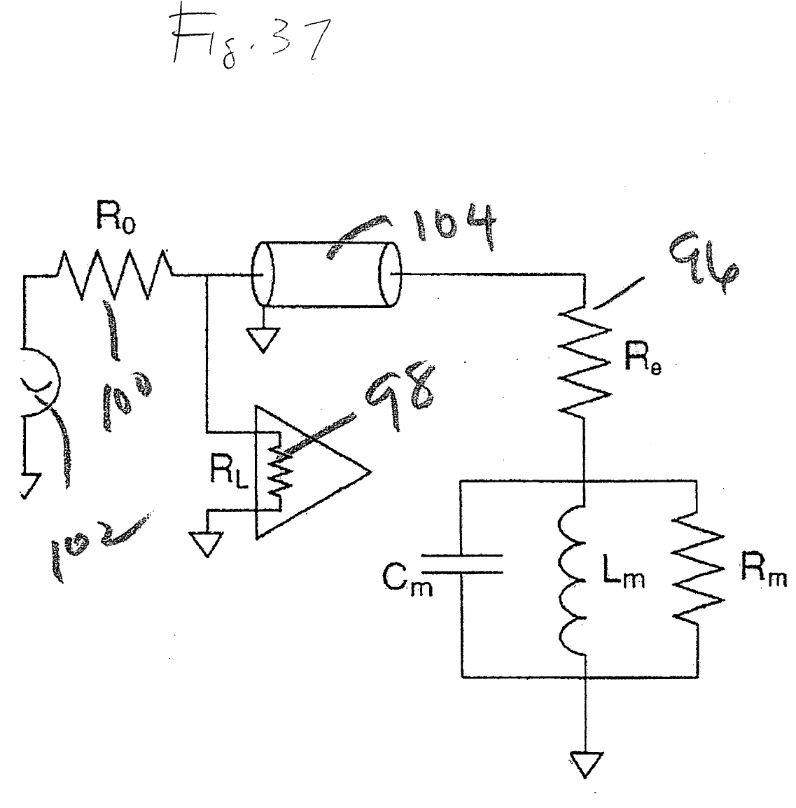

In the two port case with magnetomotive drive, the drive circuit is identical to the one port circuit of FIG. 37. The detection circuit as shown in FIG. 39 is completely separate, except for a small reactive coupling. The detect electrode can be modeled as an ideal AC voltage source in series with the electrode resistance. The AC source voltage V′ is proportional to the voltage across the RLC parallel circuit, or the motion of the transducer. The flow of current Iₘ in the measurement circuit affects the drive circuit by adding to the damping force in the equation of motion:
γ→γ′=γ+κBLₑIₘ/m
where Lₑ is the length of the detect electrode, and κ is a geometric factor to account for the two electrodes being at different locations on the structure. In the case of a straight beam with two identical parallel electrodes, L′=L and κ=1. The circuit for the mechanical resonance is modified by the addition of a parallel resistance:

$${R}_{d} = \frac{ξ {BL}^{2}}{κ L ' {I}_{m}}$$

This approximation is valid near the resonance peak.
Coupling to the Measurement Circuit

The most significant obstacle to magnetomotive detection at high frequencies is the efficient coupling of the transduced signal to the detector. As the device frequency is increased and its overall size is reduced, the dimensions of the detection electrode must be reduced proportionally, in order that the mechanical properties of the device are not ultimately dominated by electrode itself. Since the electrode's resistance scales as L/wt, it must be taken into account. For typical nanomechanical devices operating at 100 MHz and above, this source impedance Rs is much higher than the load impedance R_{L} of the detection circuit. If no attention is paid to the coupling circuit, the voltage measured by the detector can be substantially reduced.

One Port Case:

In the one-port case, the most straightforward coupling option is to connect a detector to the device either directly or through a transmission line. If a standard RF amplifier with R_{L}=50 Ω is used, then a transmission line of length λ/2 acts as a 1-1 transformer, and we can substitute the equivalent circuit shown in FIG. 38. In this circuit configuration, the electrical response is not directly proportional to the motion of the transducer. For this reason it is appropriate to define the coupling efficiency as the ratio between the difference Vₘ in voltage at the detector on and off resonance, and the voltage V₀ induced by the motion. On resonance, the mechanical part of the response is given by Rₘ, while off-resonance, it is essentially zero. Thus the coupling efficiency ε₁ is given by:

$$\begin{matrix}{ɛ}_{1} = \frac{{V}_{m}}{{V}_{0}} \\ = \frac{{V}^{on resonance} - {V}^{off resonance}}{{V}_{0}} \\ = \frac{( {R}_{e} + {R}_{m} ) {R}_{L}^{2}}{( {R}_{e} + {R}_{L} ) {( {R}_{e} + {R}_{m} + {R}_{L} )}^{2}}\end{matrix}$$

Note that the coupling efficiency is reduced when the electrode resistance is large, and also when the mechanical resistance, or the transducer's responsivity, is large. The coupling can be improved by using a high-impedance detector such as a metal semiconductor field effect transistor (MESFET) (not shown), but the improvement is only substantial if it is connected directly across the device.

Two Port Case:

In the two-port case, the most practical coupling strategy is to transform the source impedance down to the 50 Ω input impedance of a standard low-noise RF amplifier. Here we consider the simplest impedance transformation, a two-element L-section, as shown in FIG. 39.

The optimum choice for the reactive elements is:

$$\begin{matrix}L = \frac{{R}_{S}}{ω} \sqrt{\frac{{R}_{L}}{{R}_{S} - {R}_{L}}} \\ C = \frac{1}{ω {R}_{S}} \sqrt{\frac{{R}_{S} - {R}_{L}}{{R}_{L}}}\end{matrix}$$

where Rₛ refers to the resistance of the detect electrode.

The measured voltage is then reduced by the factor:

$${ɛ}_{2} = \frac{{V}_{m}}{{V}_{0}} = {( \frac{{R}_{L}}{{R}_{S}} )}^{\frac{1}{2}} {( \frac{{R}_{S} - {R}_{L}}{4 {R}_{S} - 3 {R}_{L}} )}^{\frac{1}{2}}$$

For example, a signal from a 1 kΩ electrode transformed to 50 Ω is coupled with an efficiency of 0.11, compared to 0.0023 in the one-port case. It is clear that the two-port configuration is preferable as long as there is sufficient space on the device for two electrodes, and especially when the intent is to measure the response of the device to an external stimulus.

Parasitic Reactance:

At frequencies above 100 MHz, effect of parasitic reactance on the coupling circuitry must be considered. For a straight doubly clamped silicon beam transducer of length 3 μm, width 200 nm and thickness 100 nm, vibrating at 100 MHz, the self-inductance for a 70 nm-wide electrode is negligible, at ˜2 mΩ. The mutual impedance between two electrodes of width 70 nm, separated by 60 nm on the same transducer is ˜1 mΩ, Their capacitance is also negligible, at ˜1 fF. To a first approximation, the capacitance and inductance from these elements, to a first approximation, scale as L log(L/w), they are not expected to be important for standard geometries, well into the GHz frequency range. The most significant parasitic element is the capacitance between the ground plane on which the substrate rests, and the leads connecting the device to the transmission line. For typical leads of width 100 μm and length 500 μm, on a silicon substrate of thickness 500 μm, the shunt capacitance is ˜150 fF, or 1 kΩ at 1 GHz. Since this capacitance shunts a detection electrode of similar impedance, it will reduce the coupling efficiency and ultimately the sensitivity of the measurement. In order to ensure efficient coupling at frequencies above 1 GHz, care must be taken to either minimize the lead length, or to provide a proper transmission line to the device by fabricating a coplanar waveguide on the substrate.

Sensitivity Analysis

System Constraints:

The sensitivity limit of the magnetomotive detection technique is a function of each of the three components of the measurement: transduction, coupling, and amplification. As shown above, the transduction efficiency or responsivity, depends in a straightforward way on the physical dimensions of the device and the frequency of operation. The coupling efficiency of the readout circuit has the most potential for optimization, as it depends on many parameters, including the finite resistance of the detection electrode, stray reactance, and the coupling circuit elements themselves. The input noise of the readout amplifier is taken to be fixed. In principle there are three ultimate noise sources for the measurement: the amplifier noise S^{a}_{v,} the Johnson noise S^{J}ᵥ in the detection electrode, and the intrinsic thermomechanical vibration of the transducer. The spectral density S^{m}_{X} of noise introduced by the measurement can be converted to the motion of the device as follows:

$${S}_{X ( 1 , 2 )}^{M} = \frac{1}{{R}^{2}} ( {S}_{V}^{J} + \frac{1}{{ɛ}_{( 1 , 2 )}^{2}} {S}_{V}^{a} )$$

Our calculation demonstrates that the device and readout can be designed to reduce the contribution of the amplifier noise below the expected thermomechanical noise, at frequencies up to 1 GHz.

To constrain the scope of the problem, we apply the general relationships developed in the analysis to the simple case of a straight doubly-clamped beam with one or two gold electrodes on its surface, vibrating in its fundamental normal mode. We further require that the device thickness be no less than 50 nm, and the drive and detection electrodes be significantly thinner. Many applications have the additional requirement that the measurement circuit have negligible influence on the motion to be measured. In magnetomotive detection, the back-action or the perturbative effect of measurement is proportional to the current drawn by the measurement circuit.

Transduction Geometry:

The geometry of a nanomechanical device is typically constrained by the thickness of the structural layer from which it is fabricated, or by the aspect ratio appropriate to the fabrication process or the application. For the simple flexural and torsional transducers shown below, there are only two independent parameters among (L, t, f₀). Since we are particularly interested in high-frequency applications, we will calculate the geometry-related parameters of magnetomotive transduction in terms of (t, f₀) and (L/t, f₀).

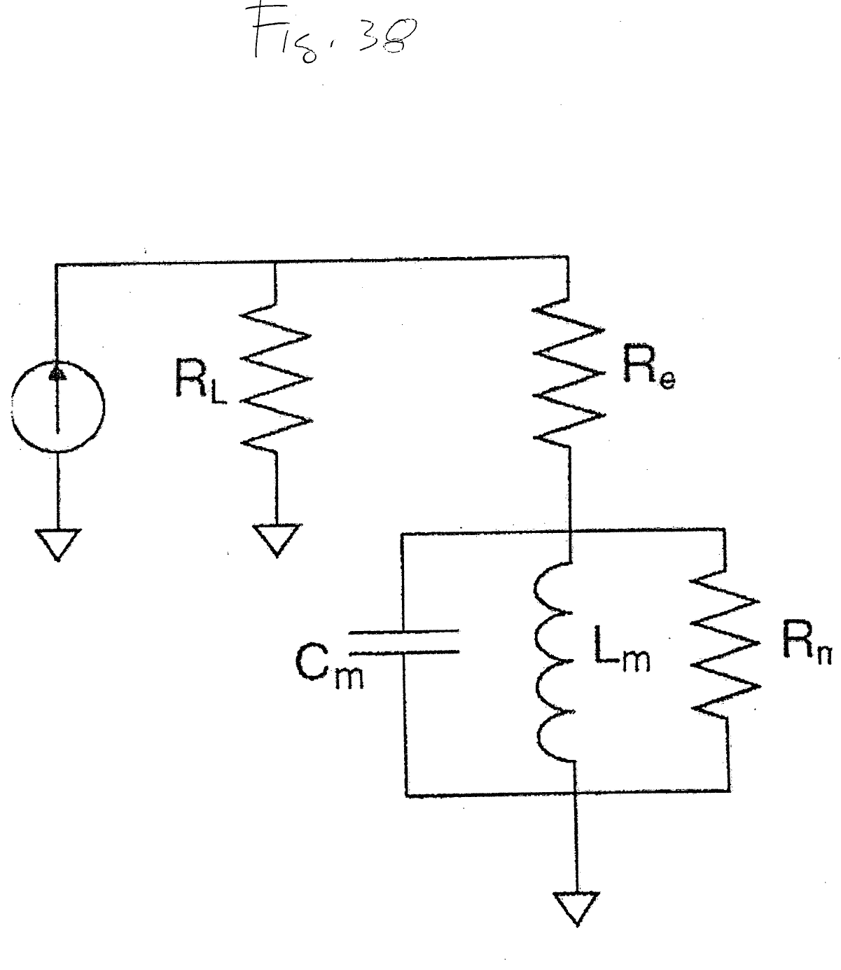

Tables 1 and 2 show the frequency and responsivity in silicon for these two simple geometries. Table 1 lists the geometry-related parameters for flexural and torsional transducers. The force constant is measured at the beam's center 202 in the flexural case and at the edge of the paddle 200 in the torsional case as diagrammatically shown in FIG. 40. All numerical quantities have SI units. Table 2 lists the geometry-related parameters for typical flexural and torsional transducers.

TABLE 1

| | fundamental flexure | torsion |
|---|---|---|
| frequency | ${f}_{0} = 8800 \frac{t}{{L}^{2}}$ | ${f}_{0} = 1900 \frac{{t}^{3 / 2}}{{L}^{5 / 2}}$ |
| force constant | $\begin{matrix}k = ( 6.60 \times {10}^{6} ) {wt}^{3 / 2} {f}_{0}^{3 / 2} \\ or \\ k = ( 4.78 \times {10}^{16} ) {( \frac{t}{L} )}^{5} {f}_{0}^{- 1}\end{matrix}$ | $\begin{matrix}k = ( 2.58 \times {10}^{7} ) {t}^{11 / 5} {f}_{0}^{6 / 5} \\ or \\ k = ( 4.22 \times {10}^{14} ) {( \frac{t}{L} )}^{11 / 2} {f}_{0}^{- 1}\end{matrix}$ |
| length scale | L = 95 (t/f₀)^{1/2} | L = 20.5t^{3/5}f₀^{-2/5} |
| responsivity | $\begin{matrix}R ( V / m ) = 312 {( {f}_{0} t )}^{1 / 2} B \\ or \\ R ( V / m ) = 29300 ( t / L ) B\end{matrix}$ | $\begin{matrix}R ( V / m ) = 129 {f}_{0}^{3 / 5} {t}^{3 / 5} B \\ or \\ R ( V / m ) = 12000 {( \frac{t}{L} )}^{3 / 2} B\end{matrix}$ |

TABLE 2

| | flexure | | torsion | | flexure | | torsion | |
|---|---|---|---|---|---|---|---|---|
| frequency | 100 MHz | | | | 1 GHz | | | |
| thickness | 100 nm | | | | 50 nm | | | |
| length scale | 3 | μm | 800 | nm | 670 | nm | 215 | nm |
| force | 21 | N/m | 41 | N/m | 115 | N/m | 140 | N/m |
| constant | | | | | | | | |
| responsivity, | 790 | nV/ [symbol] | 510 | nV/ [symbol] | 1.12 | μV/ [symbol] | 1.08 | μV/ [symbol] |
| 8T | | | | | | | | |

Doubly clamped beams 202 and torsional transducers 200 offer comparable magnetomotive responsivity in the RF frequency range. While their force constants and responsivities are similar, straight beams offer a distinct advantage over torsion paddle transducers. To achieve frequencies approaching 1 GHz with thickness no less than 50 nm, the torsional transducer must have torsion rods 204 with very low aspect ratio. For example, for the 1 GHz transducer described in the table, this aspect ratio is 4. Not only is the structure difficult to fabricate, but the nonlinear coefficient in the restoring torque is strong for torsion rods with such a small aspect ratio. This severely limits the linear dynamic range of any device application.

Coupling:

The coupling efficiency is governed by two contradictory requirements. The source impedance should be small, while at the same time the detect electrode should be small, in order to minimize mass-loading and possible damping effects. To simplify the analysis, we set an upper limit A on the ratio of electrode thickness to device thickness, which in principle would depend on the specific application. In the calculation we assume the electrode is optimal, having as large a cross-section as possible. For a straight beam, the resistance of the electrode is then given by:

$${R}_{S} = \frac{L}{λσ {tw}_{e}}$$

where σ is the conductivity of the electrode, λ is the wavelength of the driving signal, t is the beam thickness, L is the beam length and wₑ is its width.
In the one-port case, the insertion loss or the ratio, power out/power in, of the coupling circuit is:

$$\begin{matrix}{ɛ}_{1} = \frac{{α}^{2}}{( 1 + α ) ( 1 + α + \frac{{R}_{m} λσ tw}{L} )} \\ where α = \frac{λσ {R}_{L} tw}{L} .\end{matrix}$$

For typical devices with large aspect ratio L/t, α<<1, so the coupling efficiency can be approximated as α².

In the two-port case, the insertion loss of the coupling circuit is:

$${ɛ}_{2} = \frac{1}{2} {{α}^{\frac{1}{2}} ( \frac{1 - α}{1 - .75 α} )}^{\frac{1}{2}}$$

For typical devices with large aspect ratio L/t, α<<1, so the term in parentheses can be neglected. Since parasitic reactances are small, this result is qualitatively valid whether or not magnetomotive drive is used. If magnetomotive drive is used, however, the presence of two electrodes on the beam requires x to be reduced by a factor of approximately √3.

The coupling efficiency can be expressed in terms of the thickness or aspect ratio of a straight beam:

$$\begin{matrix}{ɛ}_{2} = 0.496 {( σλ )}^{\frac{1}{2}} {( \frac{ρ}{E} )}^{\frac{1}{8}} {f}_{0}^{\frac{1}{4}} {t}^{\frac{1}{4}} {{w}^{\frac{1}{2}} ( \frac{1 - α}{1 - 0.75 α} )}^{\frac{1}{2}} \\ where α = 0.99 {R}_{L} {σλ ( \frac{ρ}{E} )}^{\frac{1}{4}} {f}_{0}^{\frac{1}{2}} {t}^{\frac{1}{2}} w \\ {ɛ}_{2} = 0.507 {( σλ )}^{\frac{1}{2}} {( \frac{E}{ρ} )}^{\frac{1}{4}} {( \frac{t}{L} )}^{\frac{3}{2}} {{f}_{0}^{- \frac{1}{2}} ( \frac{1 - α}{1 - 0.75 α} )}^{\frac{1}{2}} for w = t \\ where α = 1.03 {R}_{L} {σλ ( \frac{E}{ρ} )}^{\frac{1}{2}} {( \frac{t}{L} )}^{3} {f}_{0}^{- 1} for w = t\end{matrix}$$

Measurement Sensitivity:

The sensitivity of magnetomotive detection is limited by two sources of electrical noise: Johnson noise in the detection electrode itself, and noise at the amplifier input. The spectral density for the detection electrode is:

$$\sqrt{{S}_{V}^{J}} = \sqrt{\frac{4 {k}_{B} {TL}_{e}}{λσ {tw}_{e}}}$$

This expression can be written in terms of the thickness or the aspect ratio of a straight beam:

$$\sqrt{{S}_{V}^{J}} = 2.01 {( \frac{{k}_{B} T}{σλ} )}^{\frac{1}{2}} {( \frac{E}{ρ } )}^{\frac{1}{8}} {f}_{0}^{- \frac{1}{4}} {t}^{- \frac{1}{4}} {w}^{- \frac{1}{2}}$$

$$\sqrt{{S}_{V}^{J}} = 1.97 {( \frac{{k}_{B} T}{σλ} )}^{\frac{1}{2}} {( \frac{ρ}{E } )}^{\frac{1}{4}} {( \frac{L}{t} )}^{\frac{3}{2}} {f}_{0}^{\frac{1}{2}} for w = t$$

Combining the responsivity, the coupling efficiency, and the electrical noise sources, we obtain the spectral displacement sensitivity of the 2-port measurement on a straight doubly-clamped beam:

$$\sqrt{{S}_{X ( 2 )}^{m}} = \frac{1.68}{{σ}^{\frac{1}{2}} {λ}^{\frac{1}{2}} B} {( \frac{ρ}{E } )}^{\frac{1}{8}} {f}_{0}^{- \frac{3}{4}} {t}^{- \frac{3}{4}} {{w}^{- \frac{1}{2 }} [ {k}_{B} T + \frac{{S}_{V}^{a}}{{R}_{L}} ( \frac{1 - 0.75 α}{1 - α} ) ]}^{\frac{1}{2}}$$

$$\sqrt{{S}_{X ( 2 )}^{m}} = \frac{1.71}{{σ}^{\frac{1}{2}} {λ}^{\frac{1}{2}} B} {( \frac{ρ}{E } )}^{\frac{1}{2}} {( \frac{L}{t} )}^{\frac{3}{2}} {{w}^{- \frac{1}{2}} [ {k}_{B} T + \frac{{S}_{V}^{a}}{{R}_{L}} ( \frac{1 - 0.75 α}{1 - α} ) ]}^{\frac{1}{2}} for w = t$$

Note that the sensitivity is independent of frequency for beams of constant aspect ratio. In the preceding calculation we replaced the width w of the device for the width of the electrode. This presumes that there is only a single electrode, and that the device is driven by another means, or is used in a passive measurement. If magnetomotive drive and detect are used simultaneously, the calculation is identical in all respects except that w must be replaced by w/3, the approximate width of an individual electrode.
Comparison to Thermal Noise

The ultimate noise floor for a measurement of a mechanical transducer is its intrinsic thermal fluctuations. The spectral density of displacement noise corresponding to thermal fluctuations of a mechanical transducer has a Lorentzian line shape, with a value on resonance given by:

$$\sqrt{{S}_{X}^{′}} = \sqrt{\frac{4 {k}_{B} TQ}{ξ k {ω}_{0}}}$$

In the particular case of a straight doubly-clamped beam,

$$\begin{matrix}\sqrt{{S}_{X}^{′}} = 0.200 \frac{{( {k}_{B} TQ )}^{\frac{1}{2}}}{{E}^{\frac{1}{8}} {ρ}^{\frac{3}{8}} {t}^{\frac{3}{4}} {f}_{0}^{\frac{5}{4}} {w}^{\frac{1}{2}}} \\ \sqrt{{S}_{X}^{′}} = 0.194 {{E}^{\frac{1}{2}} ( \frac{L}{t} )}^{\frac{3}{2}} {w}^{\frac{1}{2}} {f}^{\frac{1}{2}} for w = t\end{matrix}$$

For the two port measurement technique, then,

$$\sqrt{\frac{{S}_{X ( 2 )}^{M}}{{S}_{X}^{′}}} = \frac{3.15 {ρ}^{\frac{1}{2}}}{{( σλ Q )}^{\frac{1}{2}} B} {{f}_{0}^{\frac{1}{2}} [ 1 + \frac{{S}_{V}^{a}}{{k}_{B } {TR}_{L}} ( \frac{1 - 0.75 α}{1 - α} ) ]}^{\frac{1}{2}}$$

From the above expression, the level of amplifier noise required to detect thermomechanical fluctuations decreases roughly as I/f₀, and in the limit of small a is independent of other geometric factors. Neglecting the α term, we can solve for the amplifier input noise necessary to achieve the thermomechanical limit:

$${S}_{V}^{a} = 0.1 \frac{{k}_{B} {TR}_{L} σλ {QB}^{2}}{ρ {f}_{0}}$$

Although its overall sensitivity scales well to high frequencies, the frequency range of magnetomotive detection is fundamentally limited by the necessary measurement circuit. In the following section we will determine where this frequency limit lies for practical systems.

### NUMERICAL EXAMPLE

Typical low-noise RF amplifiers with input impedance R_{L}=50 Ω have noise figures ranging from 0.3 dB to 1.0 dB for a source impedance of 50 Ω. In the two-port detection circuit described in this report, the amplifier sees 50 Ω through the impedance transformation, so the noise figure (NF.) can be converted to a power spectral density by the following equation:
S_{V}^{α}=(4k_{B}TR_{L})10^{NF/10dB}

This gives an effective noise voltage S_{V}^{α} across 50 Ω, which includes both the voltage and current noise at the amplifier's input. For the quoted noise figures, the amplifier noise voltage ranges from 0.93 nV/√Hz to 1.0 nV/√Hz, assuming the amplifier is at room temperature. For a cryogenic amplifier at 4K, the noise level drops to 0.12 nV/√Hz.

Consider a silicon beam of square cross-section with the following electrical parameters: λ=0.1, R_{L}=50 Ω, σ=1.6×10⁷/Ω-m, in a magnetic field B=8T. The two-port detection sensitivity is:

$$\sqrt{{S}_{X ( 2 )}^{m}} = 1.72 \times {10}^{- 6} {f}_{0}^{- \frac{3}{4}} {t}^{- \frac{3}{4}} {{w}^{- \frac{1}{2 }} [ {k}_{B} T + \frac{{S}_{V}^{a}}{{R}_{L}} ( \frac{1 - 0.75 α}{1 - α} ) ]}^{\frac{1}{2}}$$

$$\sqrt{{S}_{X ( 2 )}^{m}} = 7.2 \times {10}^{- 11} {{{f}_{0}^{\frac{1}{2}} ( \frac{L}{t} )}^{\frac{5}{2}} [ {k}_{B} T + \frac{{S}_{V}^{a}}{{R}_{L}} ( \frac{1 - 0.75 α}{1 - α} ) ]}^{\frac{1}{2}}$$

$$where$$

$$α = 850000 {f}_{0}^{\frac{1}{2}} {t}^{\frac{3}{2}}$$

$$and$$

$$α = 7.0 \times {10}^{11} {( \frac{t}{L} )}^{3} {f}_{0}^{- 1}$$

The thermomechanical noise is:

$$\begin{matrix}\sqrt{{S}_{X}^{th}} = 4.27 \times {10}^{- 4} {( {k}_{B} TQ )}^{\frac{1}{2}} {f}_{0}^{- \frac{5}{4}} {t}^{- \frac{5}{4}} \\ \sqrt{{S}_{X}^{th}} = 5.01 \times {10}^{- 9} {( {k}_{B} TQ )}^{\frac{1}{2}} {( \frac{L}{t} )}^{\frac{5}{2}}\end{matrix}$$

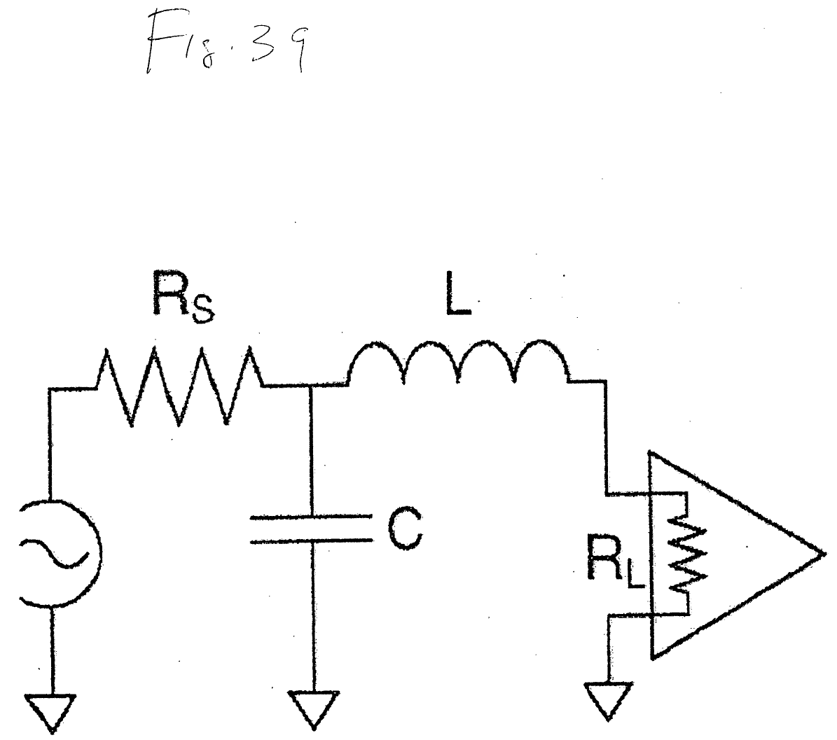

FIG. 41 summarizes the sensitivity calculations in a graph of the sensitivity of the two-port magnetomotive detection technique as a function of frequency, compared to thermomechanical noise, for straight doubly-clamped silicon beams of Q=10000 and different thicknesses, measured in a magnetic field of 8 T. Note that the frequency at which thermomechanica 1 noise can be measured is dependent only on parameters of the electrical circuit.

FIG. 42 is a graph of the input noise level required of a 50 Ω amplifier for magnetomotive sensitivity limited by thermomechanical noise, as a function of the conductivity of the electrode. The device is a straight doubly-clamped silicon beam with Q=10000 in a magnetic field of 8 T, and its electrode is 1/10 as thick as the structure. Based on the expression derived earlier for the amplifier input noise, the best way to extend the magnetomotive technique into the GHz frequency range would be to increase the conductivity of the detection electrode. The plot in FIG. 42 shows the effectiveness of this approach.

The magnetomotive technique is a very powerful tool for the detection of nanomechanical transducers in motion. It attains high sensitivity at frequencies up to and over 1 GHz, and has a large linear dynamic range. The physical principles underlying its effectiveness are very basic, enabling straightforward analysis of measured signals. With a simple readout circuit and a standard RF amplifier, magnetomotive detection can attain the sensitivity limit of thermomechanical fluctuations for a nanomechanical transducer operating at 1 GHz.

NEMS Fabrication Using Si and GaAs Membranes

Si and GaAs membranes can be fabricated using bulk micromachining techniques. In both cases, backside-processing using anisotropic selective etchants produces a suspended membrane of various widths and dimensions which can be further micromachined into a wide array of devices. While the basic method for each process is the same, the different crystallographic natures of the two materials require two distinct procedures.

Si Membrane Fabrication

Stiction in microelectromechanical systems (MEMS) has been a major failure mode ever since the advent of surface micromachining in the 80s of the last century due to large surface-area-to-volume ratio. When the devices are scaled down to nanoelectromechanical systems (NEMS), the stiction poses an even more challenging issue during in the fabrication process. By patterning the NEMS devices in predefined membrane, suspended nano-structures are no longer in close proximity to the substrate. Release related stiction is effectively prevented during drying. Higher yield of NEMS devices are therefore achieved.

The membrane substrates are also beneficial for high resolution lithography since backscattering in the substrate during the exposure of the pattern is much reduced. We have proved that nanometer scale pattern can be easily defined through electron beam lithography.

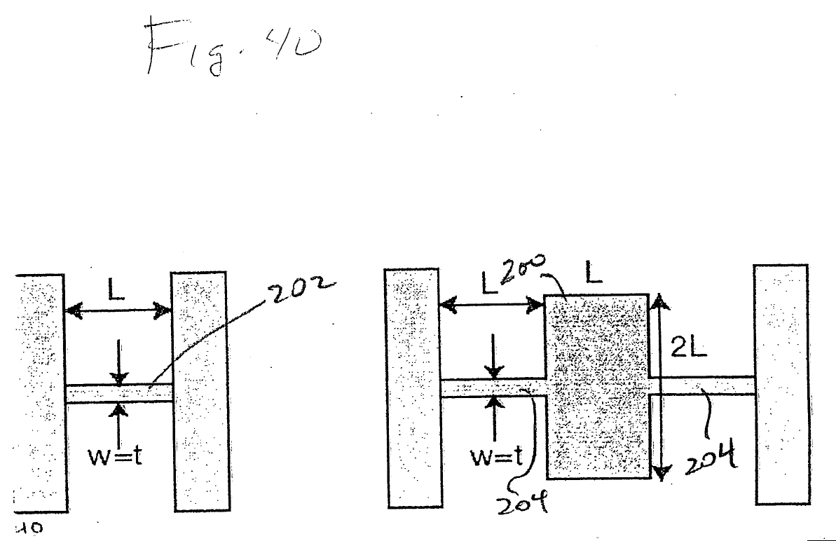

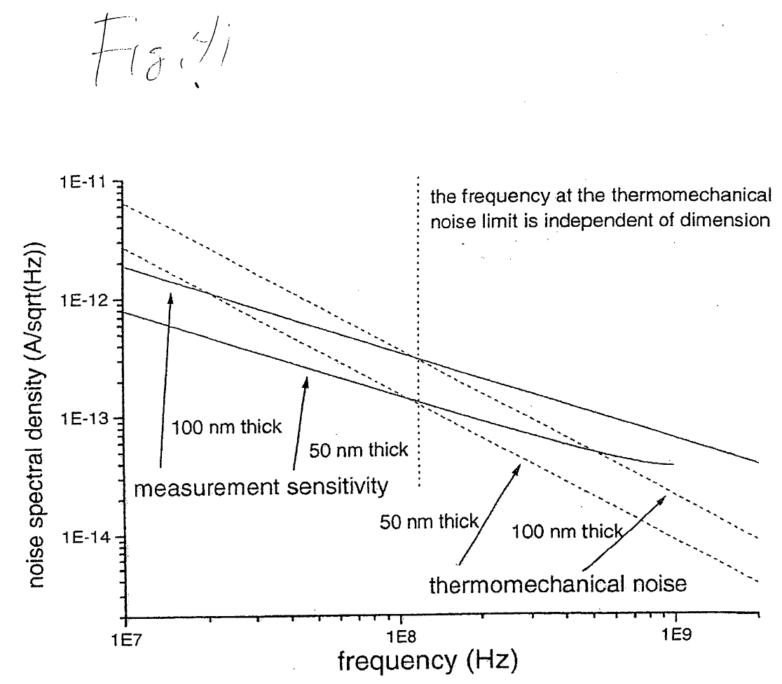

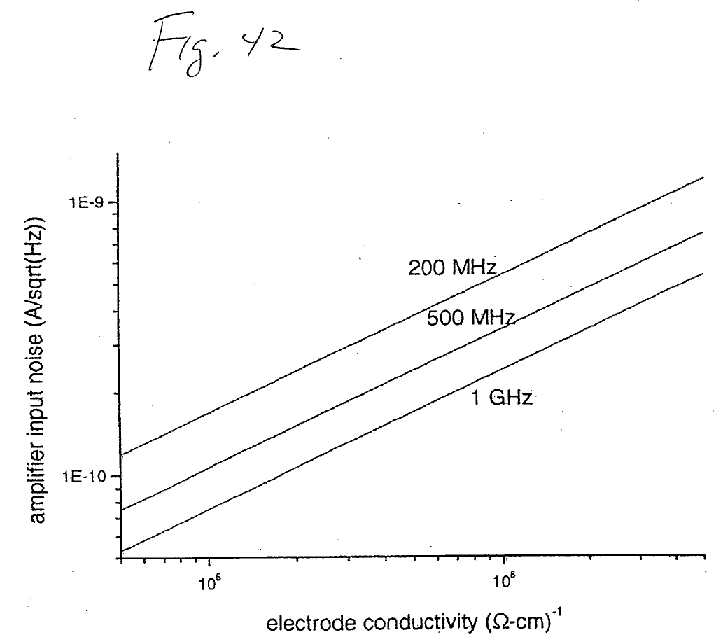

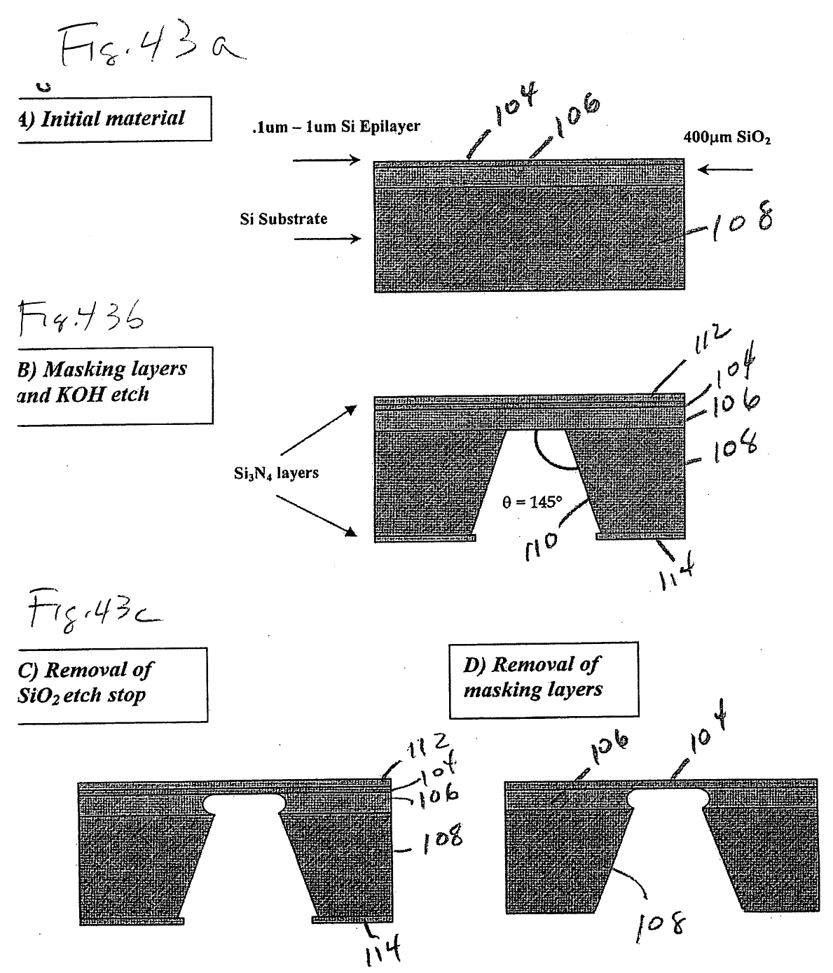

The procedure for processing Si membranes is outlined in FIG. 43a-43d. Membrane fabrication begins with a material comprised of a silicon epilayer 104 and a 0.4 μm thick implanted SiO₂ layer 106, bonded to a Si substrate 108 as depicted in FIG. 43a. A highly anisotropic KOH wet etch is used to remove a region 110 of the bulk Si substrate 108 from the backside of a sample. The selective etch characteristics of KOH allow the SiO₂ to serve as an etch stop layer, which ensures a smooth backside and a well-defined and uniform membrane thickness.

Etch Anisotropy of Silicon

KOH etches Si precisely along its crystal planes, forming a pyramidal etch window 110 which forms a sidewall angle of 125° as depicted in FIG. 43b. Undercutting of the mask is negligible for our purposes. This precise anisotropy allows membranes of any size to be constructed fairly easily. The mask is comprised of a series of squares of the appropriate sizes, separated by lines along the cleave planes to facilitate multiple sample processing and easy cleaving into individual dies once the process is finished.

Membrane Fabrication

Due to the aggressive nature of the KOH etch, low stress (Si-rich) Si₃N₄ is used as a mask. Both sides of the wafer are coated with 600 Å of Si₃N₄ via low pressure chemical vapor deposition (LPCVD), creating a pinhole free protection layer 112 for the Si epilayer 104, as well as a masking layer 114 for the backside. The mask 112 is defined in the nitride by photolithography and subsequent etching in an electron cyclotron resonance (ECR) system, using a mixture of 10 standard cubic centimeters per minute (sccm) of Ar and 20 sccm NF₃ for 2 minutes. A layer of photoresist layer (not shown) should be spun on the epilayer side for protection before etching to ensure that the silicon nitride coating 112 is not damaged.

The bulk Si etch is performed in a 30% KOH solution, held at 80° C. and mixed just prior to etching. This volume ratio yields a maximum etch rate of approximately 1.4 μm/min, requiring an etch time of just over 6 hours before the SiO₂ layer 106 is reached. KOH etches SiO₂ at ˜8 Å/min, leaving ample time to stop the etch before doing any damage to the Si epilayer 104.

The SiO₂ sacrificial layer 106 is removed in a 10% HF solution, with an etch rate of ˜340 Å/min as depicted in FIG. 43c. Undercutting of the SiO₂ layer 106 widens the membrane size no more than 4 μm in both directions. Dilute HF etches Si₃N₄ at a rate of ˜3 Å/min, removing only ˜38 Å of the mask 112 during the etch time of 12 min.

The remainder of the Si₃N₄ layer 112 is then removed in an 85% H₃PO₄ bath kept at 160° C., for 6 minutes as depicted in FIG. 43d. The etch rate of SiO₂ and Si in H₃PO₄ is negligible for our purposes, although some damage was observed on the Si layer 104 with etch times greater than 30 minutes.

It is possible that a small percentage of metal impurities in the solution can deposit on the underlying bare Si surface 104 through an electrochemical displacement plating reaction during the etch process. This is avoided by adding 5% HCl by weight to the solution to act as a chelating agent, leaving the etch characteristics unaffected. It should also be noted that as the solution evaporates, the etch rate slows considerably. For this reason the process should be carried out as soon as possible after the proper temperature is reached to ensure consistent results.

GaAs Membrane Fabrication

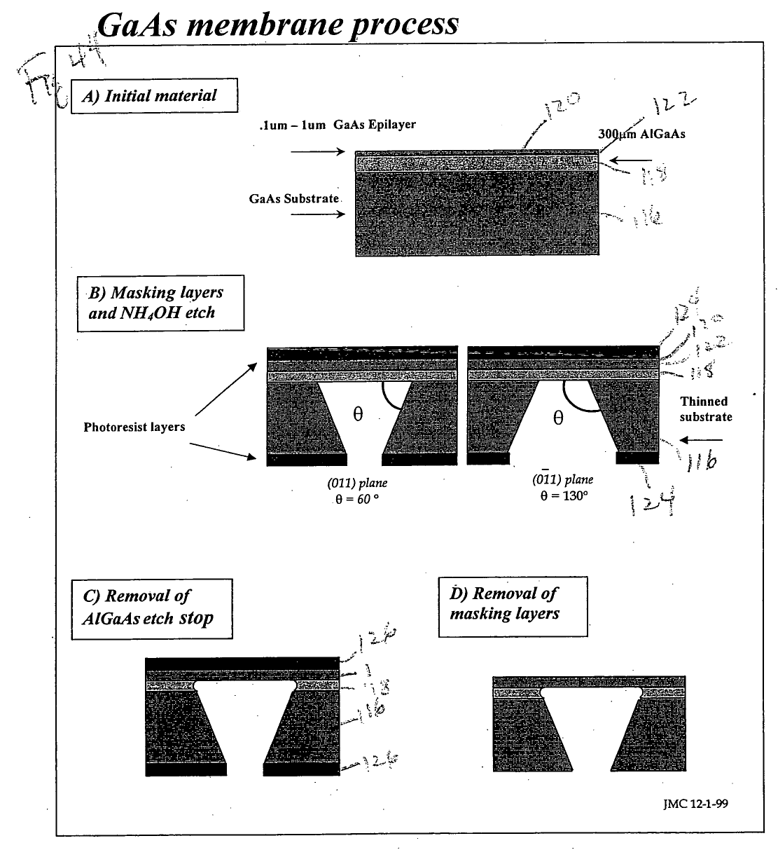

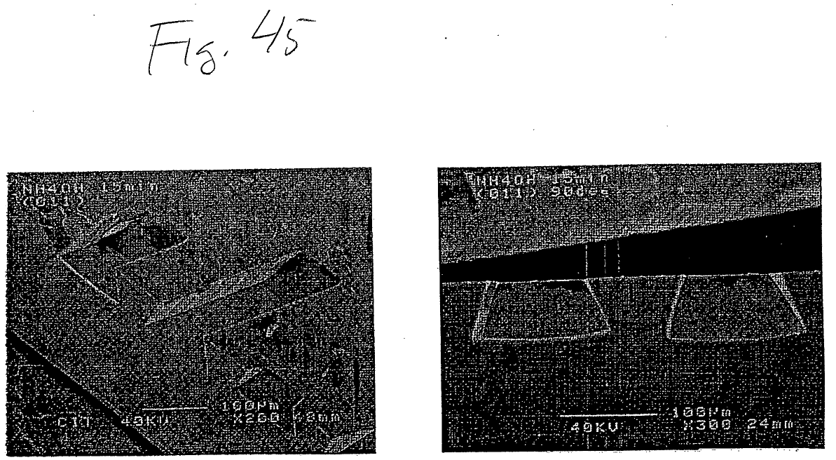

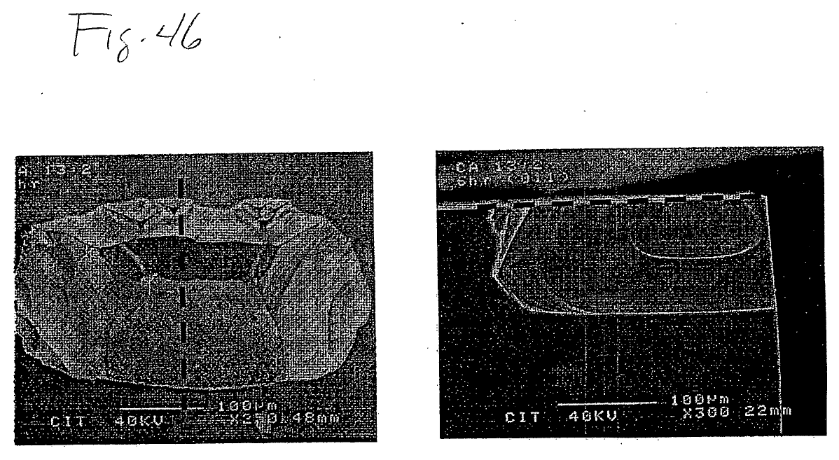

The procedure developed to create GaAs membranes is depicted in the side cross-sectional views of FIGS. 44a-44d. Processing begins with a material consisting of a bulk GaAs substrate 116, topped with a three electron beam epitaxial (MBE) grown layers: a 600 nm GaAs buffer layer 118, a 1 μm Al_{0.8}Ga_{0.2}As etch stop layer 120, and the appropriate GaAs epilayer 122 required for the desired final membrane thickness as depicted in FIG. 44a. Two anisotropic selective etches were investigated: a NH₄OH:H₂O₂ solution, and a citric acid:H₂O₂ solution. Each etchant has it's own characteristic etch profile and the advantages of each vary accordingly.

Etch Anisotropy

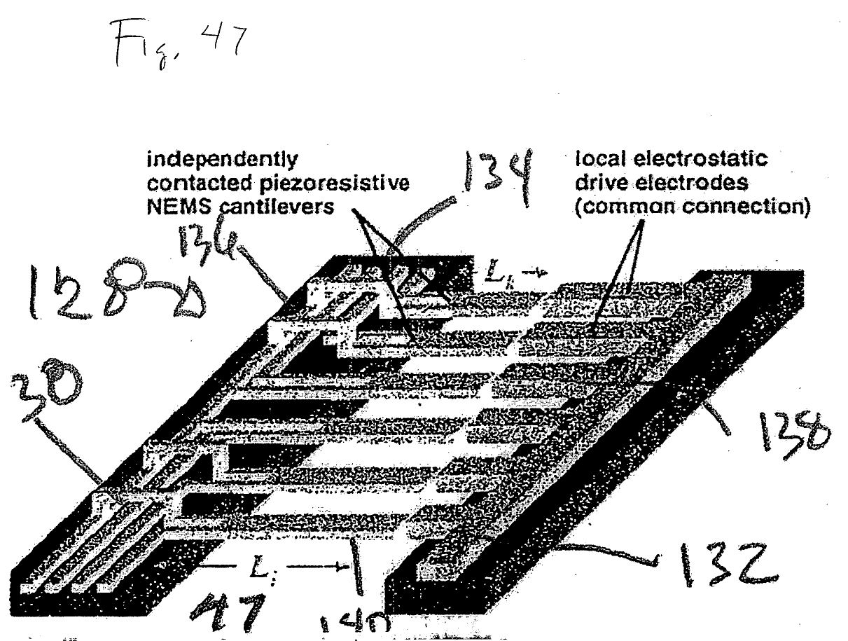

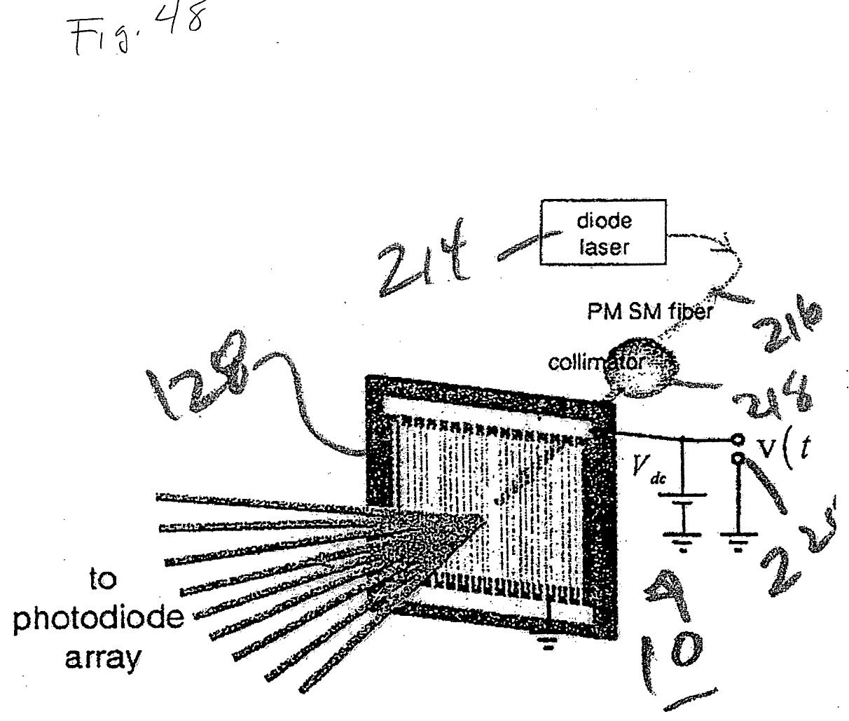

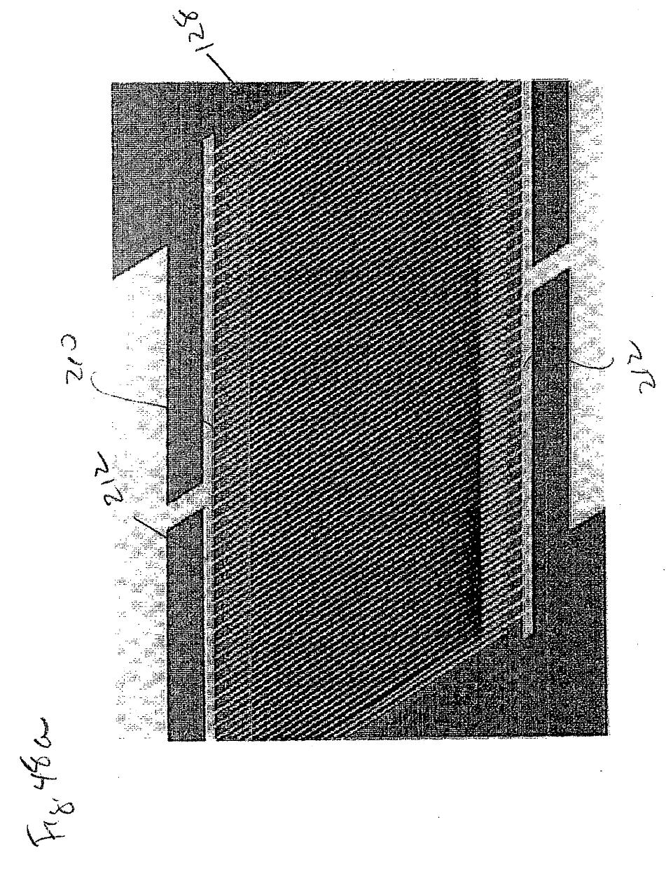

Anisotropic etching of GaAs presents some complications as compared to the previously described process in silicon with etch profiles differing along the two major crystal planes as well as with the etchant used. The NH₄OH solution produces well-defined and smooth surfaces along the etched walls and floor as shown in the microphotograph of FIG. 45a, while the citric acid etches less uniformly on all surfaces as shown in the microphotograph of FIG. 46a. The undercut ratios for both etchants limit how small the final membrane dimensions can be, requiring a thinner substrate than that commercially provided in order to produce a membrane of reasonable size. The undercut ratio is defined as the ratio of the lateral etch rate to the vertical etch rate. The substrate 116 can be thinned down to 100 μm, below which makes the sample very fragile and prone to breaking or chipping and less likely to survive later processing steps. Because the front side of the membrane is protected as described in processing steps below, it is possible to avoid the fragility problems due to substrate thickness by fabricating the desired device on the front surface before thinning the substrate and processing the membrane. This requires an infrared mask aligner to align the device with the membrane pattern before etching.

The etch rate of the NH₄OH:H₂O₂ solution varies along different crystal planes depending on the volume ratios of etch products. The 1:30 solution, chosen for maximum selectivity, produces an obtuse sidewall angle of ˜130° in the (0\overline{1}0) plane and an acute sidewall angle of ˜60° in the (011) plane as depicted in FIG. 44b. In addition, significant undercutting also occurs, with an undercut ratio averaging ˜0.5 for both crystal planes. This serves to widen the mask window dimensions by ˜1 square micron for every micron of etched depth. The combination of the above characteristics constrains the dimension along the (011) plane to a minimum of −200 μm for an initial substrate thickness of 100 μm.

The anisotropic etch characteristics of citric acid on GaAs differ somewhat from that of NH₄OH. For a volume ratio of 3:1 it also produces a sidewall angle of ˜130° in the [1\overline{1}0] direction, but an effective angle of 90° in the [011] direction as shown in the microphotograph of FIG. 46b. The undercut ratios for the [0\overline{1}0] and [011] planes are 1.2 μm and 1.5 μm respectively. The combination of these two characteristics reduces the dimension constraint in the [011] direction to about 150 μm for an initial substrate thickness of 100 μm.

In cases where later device constraints require smaller membrane dimensions, the citric acid solution could be preferable to the NH₄OH solution. However, at the present conditions the etch rate approaches zero past a depth of about 100 μm. This requires the substrate to be thinned as much as possible creating a fragile sample which can be difficult to handle. Because the NH₄OH etch ant can etch uniformly through thicknesses of greater than 600 μm with well-defined and reproducible membrane dimensions, at the present time this solution is preferred when larger membrane sizes can be tolerated. Further experimentation with citric acid volume ratios and temperature conditions may prove the solution more useful at a later time.

Membrane Fabrication

Substrate Thinning

The sample preparation process for both etch methods is identical. Membrane fabrication begins with thinning the GaAs substrate 116 to a thickness between 300 and 100 μm using a fast isotropic H₂SO₄:H₂O₂:H₂O wet etch in the volume ratio 1:8:1. This etches at approximately 5 μm/min and produces a reasonably smooth and sufficiently homogenous backside surface for our purpose. A piece of the material a few millimeters on a side is prepared, which will later be cleaved into smaller samples for individual membrane processing.

A layer of photoresist 124 is spun on the front side to protect the epilayer 120 before waxing the material face down to a glass coverslip. AZ 4330 photoresist is used, and care should be taken not to heat the sample and wax above 130° C. as it makes the photoresist extremely difficult to remove later in the process. Once the wax has hardened, a small cotton swab with acetone can be used to gently remove the photoresist residue from the backside of substrate 116.

It should be noted that the etch rate is extremely sensitive to temperature. As some heating occurs when the etchant components are mixed, the solution is left for an hour to return to room temperature before immersing the sample. Also due to this temperature sensitivity, normal room temperature fluctuations can result in a somewhat unstable etch rate, varying by as much as 20%. Because removing the sample from the solution periodically to determine thickness can produce markedly different etch times subsequent etch rates, a vertical micrometer is helpful in achieving the exact desired material thickness. Once this thickness is reached, the sample is rinsed thoroughly in DI water and left in acetone to dissolve the wax.

Etch Methods

Once the wax is removed, photoresist 126 is again spun on the front for protection. The backside is then flood exposed in a mask aligner and developed to remove residual resist. AZ 4330 photoresist 126 is spun on the backside of the sample at 2750 rpm and baked for 1 min at 95° C., producing a resist layer about 5 μm thick. The etch mask corresponding to the final membrane dimensions is then defined relative to the proper crystal planes. After the pattern is developed it is post-baked at 115° C. for 2 min, while waxing the sample epilayer side down to a glass microscope slide.

The NH₄OH solution used is comprised of NH₄OH and H₂O₂ in the volume ratio of 1:30 for greatest selectivity (˜100), and is freshly mixed prior to etching. The reaction is diffusion-rate limited and spraying it onto the sample serves to circulate and mix the solution, as well as mechanically remove etch products. It should be noted that the use of a Teflon sample holder is important to ensure the greatest selectivity. When the AlGaAs sacrificial layer is reached, the etched window becomes transparent through the top two layers and orange in color. The etch is allowed to continue for ˜30 seconds to assure complete removal of the underlying GaAs layer, and the sample is rinsed thoroughly in DI water to ensure removal of all etch products.

The citric acid solution previously mentioned can also be used to remove the bulk substrate. This is reaction-rate limited, and therefore used as a simple bath. Citric acid monohydrate is mixed 1:1 with DI water by weight one day in advance to ensure complete dissolution. This solution is then mixed in a 3:1 volume ratio with H₂O₂, and allowed to rest for approximately 20 minutes to return to room temperature. The sample is immersed in the bath until the transparent window is seen (just over 6 hours for an initial substrate thinned to 100/μm), and rinsed thoroughly.

At this point the AlGaAs layer is removed by immersing the sample, still attached to the glass slide, in 20% HF for 1 min 15 s, with a selectivity of AlGaAs to GaAs of greater than 107 as depicted in FIG. 44c. When the AlGaAs layer has been completely removed, a faint ring can be optically seen around the membrane, indicating undercutting of the sacrificial layer. To complete the process, the sample is left in acetone overnight to dissolve the wax, transferred to isopropyl alcohol, and gently blown dry resulting in the structure of FIG. 44d.

A process has been developed to produce membrane structures out of silicon and gallium arsenide using bulk micromachining methods. Both processes utilize selective etching anisotropic etching systems. For the Si system, a well-defined KOH etchant was characterized, which is selective to Si over SiO₂. For the GaAs system, NH₄OH and citric acid solutions were characterized, both of which are selective to GaAs over AlGaAs. It was found that the preferred etchant for both reproducibility and durability is NH₄OH, unless future device constraints require membrane dimensions less than 150 μm.

NEMS Array Scalar Analyzers/Correlators

FIG. 47 illustrates basic concepts behind a NEMS array spectrum analyzer 128. In this conceptualization the analog of “resonant reeds” are piezoresistive NEMS cantilevers, as pictured in FIG. 47. The elements 130 forming the array 128 have lengths that are staggered (here denoted as Lᵢ, . . . , Lₖ), thus yielding overall resonant response that covers some desired, preprogrammed spectral range. Here each element 130 is pictured as being separately driven and sensed, however all share a common ground electrode 132. It is noteworthy that even simpler readouts are possible. The signal is pictured here as being delivered from a common transmission line 134 with local stubs 136 to provide electrostatic actuation at each element 130. Note that a difference in thickness difference between the drive electrode 138 and the cantilever tips 140 in FIG. 47 provides requisite the out-of-plane electric fields for inducing mechanical motion in this direction.

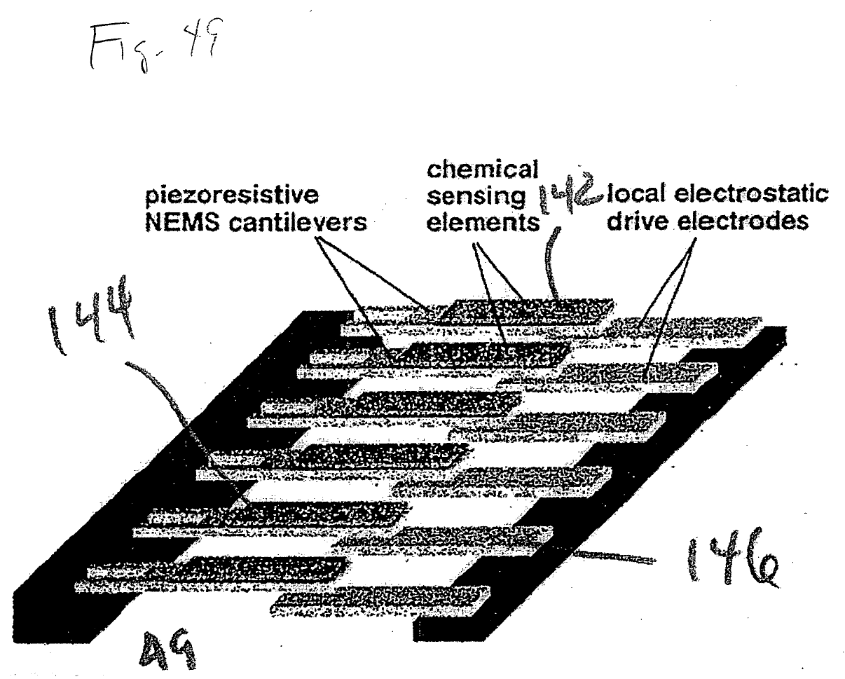

FIG. 47 represents a realization where individual, uncoupled elements provide the functionality. It is also possible to have collective mechanical modes in a coupled array of mechanical elements. This provides for a broad class of optoelectromechanical array spectrum analyzers. One simple realization from this family is conceptually depicted in FIG. 48 where a plurality of interdigitated or otherwise arrayed and interacting beams or cantilevers 210 as shown in FIG. 48a are disposed between two opposing T-frames 212. Here the Fourier components present in the electrical signal waveform, denoted as v(t), parametrically drive the collective modes of the array. This motion, in turn, modulates the strength of the diffracted orders of light from a laser 214 coupled to device 10 by means of an optic fiber 216 collimated by collimator 218 and transmitted through the array 128 which is, in essence, a time-varying optical diffraction grating. These orders can be read out continuously and therefore can provide real-time spectral analysis of the electrical waveform, v(t) at input 220.

NEMS Array Chemical/Biological Sensors

Two groups have pioneered MEMS based electromechanical “nose” devices. The efforts have primarily been directed toward the sensing of gaseous analytes and fluidic analytes. There are two modes of operation that stems from two distinct physical mechanisms of interaction. The first mode, which is the basis for the recent work from both groups, is based upon the induction of differential strain in the cantilevers from an overlayer that swells or shrinks upon exposure to the analytes. If this overlayer coats only one face of the cantilever, the swelling or shrinkage of the overlayer results in bending, which is then detected optically.

The second mode of sensing is based upon mass loading, and the resultant change in the total inertial mass of the sensor, which can be detected as a resonant frequency shift.

There are significant and compelling reasons for scaling these ideas down into the realm of NEMS arrays. Most significant is that the sensitivity of a “electromechanical nose” can be greatly enhanced due to the smaller mass of NEMS elements, and also by the further improvements that can be derived from the enhanced strain sensitivity, mass sensitivity, compliance, and operating frequency of nanoscale mechanical elements. A concrete example of this is given by our recent work on ultrasensitive NEMS mass sensing.

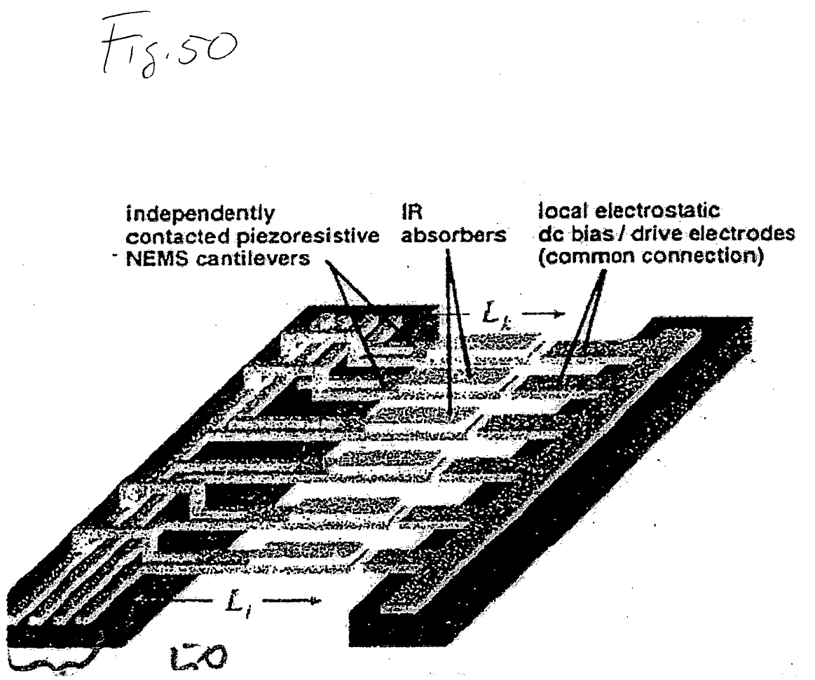

FIG. 49 illustrates a conceptualization of a NEMS array electronic nose. Each element 142 within an array of separately transduced piezoresistive cantilevers 144 is surface loaded with a film providing sensitivity to a particular target analyte. In this conceptualization, adjacent electrostatic drive electrodes 146 allow separate excitation of the chemically functionalized elements. This would require individual connections to each drive electrode.

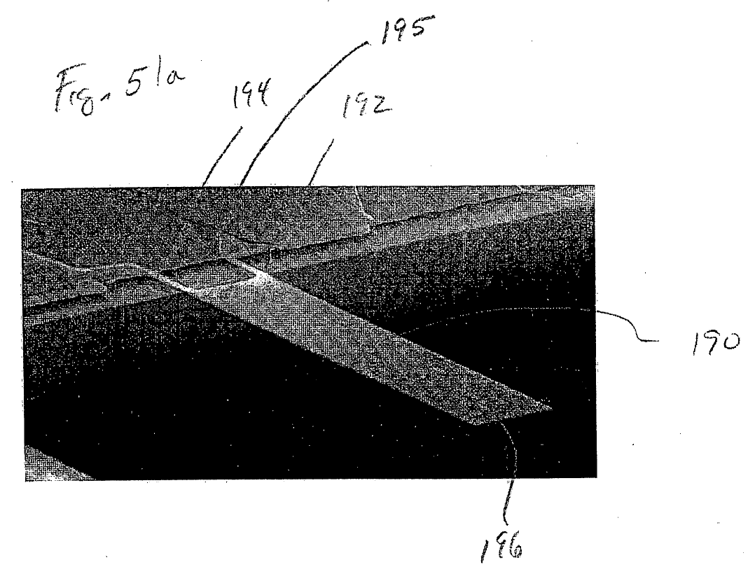

Another means for addressing each element 142 is shown in FIG. 50; this employs a single transmission line 130 and a swept signal yielding addressability in the frequency domain if the cantilevers 144 are designed with staggered lengths as depicted in FIG. 50.

NEMS Array Infrared Detectors/Imagers

In the illustrated embodiment IR imagers are based upon NEMS arrays 128. The significant reductions in size will provide immense pay-offs in terms of sensitivity and response time. One possible device layout is shown in FIG. 50. Here the resonant frequencies of the individual elements are staggered by means of lithographically patterned variations in the lengths of the IR absorber (?). AC readout of the strain-induced bending arising from IR absorption in the “absorbers” is detected as a frequency shift. This shift is the direct consequence of a resonant frequency for each element that is dependent upon its average position. This position dependence arises from a static DC voltage applied to each element's drive electrode in addition to the RF drive signal itself. This DC voltage bias translates into an electrostatic term in each cantilever's potential energy, resulting in a position dependent resonant frequency. In this particular conceptionalization, we also envisage fast interrogation of the large number of array elements by stepped frequency excitation of the individual resonant elements. This allows individual addressability via a single transmission line. It is quite reasonable to envisage frequency-multiplexing the readouts in similar manner, by AC coupling the piezoresistors to a common readout transmission line.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

1. A monolithically fabricated apparatus comprising:
a doubly clamped, suspended beam with a submicron width having an asymmetrically positioned, mechanical-to-electrical transducing layer fabricated within or on the beam;
at least one side drive gate proximate to the beam within a submicron distance.

2. The apparatus of claim 1 where the asymmetrically positioned, mechanical-to-electrical transducing layer comprises an asymmetrically positioned piezoelectric layer within the beam.

3. The apparatus of claim 1 where the beam is fabricated from a 2 DEG heterostructure.

4. The apparatus of claim 1 wherein the beam is provided with electrical contacts and forms a two-terminal circuit with an output terminal, and further comprising an inductor in parallel circuit with the beam and a blocking capacitor coupled to the output terminal of the beam.

5. The apparatus of claim 4 further comprising a low noise cryogenic amplifier coupled to the blocking capacitor.

6. The apparatus of claim 1 where the gate is provided with a gate dipole charge separation and where the beam is provided with a beam dipole charge separation, the beam and gate interacting through the dipole-to-dipole interaction.

7. The apparatus of claim 1 further comprising cryogenic means for maintaining the beam at cryogenic temperatures.

8. The apparatus of claim 1 wherein the side gate includes a 2 DEG layer.

9. The apparatus of claim 1 wherein the beam and side gate comprise a chip and further comprise a substrate on which the chip is disposed, the substrate having an electrode formed thereon, where the gate being provided with a gate dipole charge separation between the electrode of the substrate and the gate, and where the beam is provided with a beam dipole charge separation, the beam and gate interacting through the dipole-to-dipole interaction.

10. The apparatus of claim 1 where the beam and gate are fabricated from an asymmetric heterostructure stack comprising a 2 DEG GaAs piezoelectric layer, two sandwiching AlGaAs spacer layers on each side of the GaAs layer, a first and second AlGaAs:Si donor layer above and below the AlGaAs spacer layers respectively, two GaAs cap layers above and below the AlGaAs:Si donor layers respectively.

11. The apparatus of claim 10 where each of the layers below the 2 DEG GaAs piezoelectric layer is thicker than the corresponding layer above the 2 DEG GaAs piezoelectric layer.

12. The apparatus of claim 10 further comprising an AlₓGa₁₋ₓAs sacrificial layer disposed under the stack and a substrate disposed under the AlₓGa₁₋ₓAs sacrificial layer, where 0<x<1.

13. The apparatus of claim 1 where the gate is provided with a gate dipole charge separation, and where the beam is provided with a beam dipole charge separation, the beam and gate interacting through the dipole-to-dipole interaction.

14. The apparatus of claim 13 further comprising two gates, each disposed within a submicron distance of the beam and each provided with a gate dipole charge separation.

15. The apparatus of claim 13 further comprising a source of sensing current supplied to the beam and an amplifier in circuit with the beam to generate an output signal.

16. The apparatus of claim 15 where the amplifier is cryogenic.

17. The apparatus of claim 15 where the source of sensing current supplies DC and AC sensing current to the beam.

18. The apparatus of claim 1 where the transducing layer of the beam is piezoelectric which is used to induce oscillation of the beam, and is also piezoresistive which is used to sense oscillation of the beam.

19. An improvement in a method of forming a suspended NEMS beam including a two-dimensional-electron-gas layer comprising:
providing a heterostructure stack including a 2 DEG layer disposed on a sacrificial layer;
selectively disposing a mask on the stack to define a pattern for the NEMS beam;
dry etching away exposed portions stack the using a Cl₂/He plasma etch to define the NEMS beam without substantially altering the electrical characteristics of the 2 DEG layer; and
etching the sacrificial layer away to release the NEMS beam.

20. The method of claim 19 where dry etching away exposed portions stack the using a Cl₂/He plasma etch comprises supplying Cl₂ and He gas at a flow rate ratio of 1:9 respectively into an ECR plasma chamber.

21. The method of claim 20 where supplying Cl₂ and He gas into the ECR plasma chamber further comprises maintaining the stack at or less than 150V self-bias with 20 W constant RF power and ionizing the Cl₂ and He gas with approximately 300 W microwave power or more.

22. A NEMS parametric amplifier comprising:
a suspended oscillating submicron signal beam defined in a plane and having a flexural spring constant for in-plane motion and being driven at w at or near the frequency of mechanical resonance of the signal beam;
a pair of pump beams coupled to the signal beam and being driven at or near 2ω;
a source of magnetic field applying a field with at least a component perpendicular to the signal beam and pair of pump beams; and
a source of alternating current coupled in circuit with the pump beams to apply a current through the pump beams in the presence of the magnetic field to generate a modulated Lorentz force on the pump beams to apply in turn a force oscillating of compression and tension to the signal beam to perturb the flexural spring constant for in-plane motion of the signal beam.

23. The apparatus of claim 22 further comprising an amplifier coupled to the beam.

24. The apparatus of claim 22 where the pump beams and signal beam collectively form an H-shaped structure in the plane, the signal beam forming the middle portion of the H-shaped structure.

25. The apparatus of claim 22 where the pump beams are tuned to resonate at 2ω.

26. A method of operating a NEMS parametric amplifier comprising:
applying a magnetic field with at least a component perpendicular to a pair of pump beams;
supplying alternating current at a frequency of or near 2ω to the pump beams in the presence of the magnetic field to generate a modulated Lorentz force of compression and tension to the signal beam coupled to the pump beams to perturb the flexural spring constant for in-plane motion of the signal beam;
oscillating the signal beam in response to the driven pump beams at a frequency of ω which is at or near the mechanical resonant frequency of the signal beam; and
sensing signal beam oscillations.

27. The method of claim 26 further comprising providing the pump beams tuned to the frequency 2ω.

28. The method of claim 26 where the pump beams are driven in an opposing quadrature of phase relative to the oscillation of the signal beam.

29. A submicron cantilever characterized by a submicron displacement comprising:
a NEMS cantilever having a restriction portion;
a piezoresistive strain transducer epilayer coupled to the cantilever;
where G is the gauge factor of the apparatus given by
$$G = \frac{3 {βπ}_{L} K ( 2 I - {I}_{1} )}{2 {bt}^{2}} {R}_{T}$$
where the parameter π_{L} is the piezoresistive coefficient of the piezoresistive transducer material, the factor β accounts for the decrease in G due to the finite thickness of the conducting layer, K is the spring constant of the cantilever, l the overlength of the cantilever, l₁ the length of the restriction portion, b the thickness of the restriction portion, t the thickness of the thickness of the restriction portion, and R_{T} is two-terminal resistance of the transducer.

30. The cantilever of claim 29 where near resonance, force spectral density of thermomechanical fluctuations is given by
S_{F}^{γ}=4k_{B}Tγ=4Kk_{B}T/(2πQf₀)
where k_{B} is the Boltzman constant, T is the temperature, γ is the damping coefficient, f₀ is the resonance frequency and Q=mf₀/γ is the quality factor, m is the mass of the cantilever.

31. The cantilever of claim 30 where near resonance, voltage spectral density for the thermomechanical fluctuations is given by
$${S}_{V}^{γ} = \frac{{S}_{F}^{γ} {G}^{2} {I}^{2}}{16 {π}^{2} {m}^{2} {f}_{0}^{2} [ 4 {( f - {f}_{0} )}^{2} + {f}_{0}^{2} / Q ]}$$
where f is the frequency of oscillation of the cantilever.

32. A method for scaling and determining carrier distribution in NEMS devices having a doped layer with different doping concentration and different thicknesses disposed on an instrinsic layer comprising:
providing the doped layer with a predetermined thickness;
providing a doping concentration in the doped layer;
adjusting the Fermi level until charge neutrality is obtained by satisfying the condition
∫₀^{l}(ρ(x)/e+N_{A}⁻(x))dx=0
where
$${N}_{A}^{-} ( x ) = \frac{\# dopants}{\frac{1}{2} {ⅇ}^{- β ( {E}_{A} - ( {E}_{F} - {ɛ}_{V} ) )}}$$
is the density of ionized acceptor sites, where ρ is volume density of carriers given by Fermi statistics, ρ(x)=e(p(x)−n(x)) and positive and negative carrier densities are
p(x)=1.04×10²⁵e^{-β(E}^{_{F}}^{-E}^{_{V}}⁾/m³
n(x)=2.8×10²⁵e^{-β(E}^{_{C}}^{-E}^{_{F}}⁾/m³
where β is 1/kT, E_{F} is the Fermi energy, E_{V} is the energy of the valence band energy, and E_{C} is the energy of conduction band;
determining the bending of the valence band according to the equation
$$\frac{{ⅆ}^{2} {E}_{v}}{ⅆ {z}^{2}} = \frac{ⅇρ ( x )}{ɛ}$$
where E_{V} is the energy of the valence band, ∈ is the dielectric constant, e is the charge of the electron, subject to the boundary condition:
$$\frac{{ⅆ}^{2} {E}_{v}}{ⅆ {z}^{2}} {\vert}_{z = 0} = \frac{ⅇσ}{ɛ}$$
where σ is the empirical surface carrier density; and
iteratively repeating the foregoing steps of adjusting and determining until convergence is attained for a carrier density, ρ.

33. A bridge circuit comprising;
a source of excitation signal;
a power splitter coupled to the source to generate two out-of-phase components of the excitation signal;
a first actuation port coupled to the power splitter;
a second actuation port coupled to the power splitter;
a first circuit arm coupled to the first actuation port including a first NEMS resonating beam having an transduced electrical output;
a second circuit arm coupled to the second actuation port including a second NEMS resonating beam having an transduced electrical output, the first and second beams being matched to each other; and
a detection port coupled to the DC coupling resistance, Rₑ and to the NEMS resonating beam.

34. The bridge of claim 33 further comprising a variable attenuator and a phase shifter coupled in circuit in opposing ones of the first and second circuit arms, the attenuator to balance out impedance mismatch between the first and second circuit arms more precisely than without the inclusion of the attenuator, while the phase shifter compensates for the phase imbalance created by the circuit inclusion of the attenuator.

35. The bridge of claim 33 where the NEMS resonating beam includes a surface adapted to adsorb a test material, performance of the NEMS resonating beam being affected by the test material and being measured by the bridge.

36. The bridge of claim 33 further comprising an amplifier and an output impedance mismatch circuit coupling the detection port to the amplifier.

37. The bridge of claim 33 where the first and second NEMS resonating beams are magnetomotive NEMS resonating beams and have no metallization.

38. A method of balancing the output of two NEMS devices in a bridge circuit comprising:
providing an excitation driving signal;
splitting the excitation driving signal into two out-of-phase components;
providing one of the out-of-phase components to a first NEMS resonating beam having a first transduced electrical output;
providing the other one of the out-of-phase components to a second NEMS resonating beam having a second transduced electrical output, the first and second beams being matched to each other; and
summing the first and second transduced electrical outputs together to generated a balanced detected output signal.

39. The method of claim 38 further comprising variable attenuating the driving excitation signal to one of the first and second NEMS resonating beams and providing a compensating phase shift in the driving excitation signal to the other one of the first and second NEMS resonating beams to balance out impedance mismatch between the first and second NEMS resonating beams more precisely than without attenuation or phase shift compensation for the phase imbalance created by the attenuation.

40. The bridge of claim 38 further comprising adsorbing a test material on the surface of the NEMS resonating beam to alter performance of the NEMS resonating beam and measuring the alteration of performance in the balanced detected output signal.

41. The method of claim 38 further comprising amplifying the balanced detected output signal in an amplifier, and impedance matching the output of a detection port on which the balanced detected output signal is provided with the amplifier.

42. The method of claim 38 further comprising providing a magnetic field in which the first and second NEMS resonating beams are exposed; driving the first and second NEMS resonating beams with a magnetomotive force without metallization on the first and second NEMS resonating beams.

43. The apparatus of claim 38 further comprising an adsorbing surface disposed on one of the NEMS resonating beams, wherein adsorption of an adsorbate on the adsorbing surface is indicated in the balanced detected output signal.

44. An apparatus comprising:
a driving source;
a power splitter coupled to the source for generating drive signals of opposing phases;
a first magnetomotive NEMS resonating beam coupled to one phase of the drive signal generated by the power splitter;
a second magnetomotive NEMS resonating beam coupled to the other opposing phase of the drive signal generated by the power splitter;
a terminal electrical coupled to the two magnetomotive NEMS resonating beams;
an amplifier coupled to the terminal; and
means coupled to the amplifier, the means for measuring the frequency dependence of the forward transmission coefficient S₂₁ of the apparatus.

45. The apparatus of claim 44 where the first and second magnetomotive NEMS resonating beams are comprised of SiC.

46. The apparatus of claim 44 where the first and second magnetomotive NEMS resonating beams vibrate in an in-plane resonance.

47. The apparatus of claim 44 where the first and second magnetomotive NEMS resonating beams vibrate in an out-of-plane resonance.

48. The apparatus of claim 44 further comprising an adsorbing surface disposed on one of the NEMS resonating beams, wherein adsorption of an adsorbate on the adsorbing surface is measured by the means for measuring.

49. A method comprising:
providing an excitation driving signal;
splitting the excitation driving signal into two out-of-phase components;
providing one of the out-of-phase components to a first NEMS resonating beam having a first transduced electrical output;
providing the other one of the out-of-phase components to a second NEMS resonating beam having a second transduced electrical output, the first and second beams being matched to each other;
vibrating the first and second NEMS resonating beams;
summing the first and second transduced electrical outputs together to generated a balanced detected output signal;
amplifying the balanced detected output signal in an amplifier; and
measuring the frequency dependence of the forward transmission coefficient S₂₁.

50. The method of claim 49 where vibrating the first and second magnetomotive NEMS resonating beams comprises vibrating the beams at an in-plane resonance.

51. The apparatus of claim 49 where vibrating the first and second magnetomotive NEMS resonating beams comprises vibrating the beams at an out-of-plane resonance.

52. An improvement in a magnetomagnetically driven submicron NEMS resonating beam comprising:
a submicron SiC NEMS beam having a surface and an axial length L, width W, Young's modulus E, mass density ρ, and displacement amplitude A;
a source of a magnetic field, B;
an electrode means disposed on the surface of the beam for conducting current along at least a portion of the axial length of the beam;
a source of alternating current coupled to a first end of the electrode means to magnetomotively drive the SiC NEMS beam to a resonant frequency
$${f}_{0} = \sqrt{\frac{E}{ρ}} \frac{W}{{L}^{2}} ;$$
and
a detector coupled to a second end of the electrode means to detect a generated Vemf from the SiC NEMS beam of
$${V}_{emf} ∝ B A \sqrt{\frac{E}{ρ}} \frac{W}{L} .$$

53. The improvement of claim 52 where the electrode means comprises a single electrode coupled to the source of alternating current for driving the beam in the magnetic field and coupled to the detector for sensing the EMF generated in the electrode by motion of the beam.

54. The improvement of claim 52 where the electrode means comprises a first electrode coupled to the source of alternating current for driving the beam in the magnetic field and a second electrode coupled to the detector for sensing the EMF generated in the electrode by motion of the beam.

55. The improvement of claim 52 where the SiC NEMS beam has dimensions and parameters providing a fundamental resonance frequencies in the UHF range and higher.

56. The improvement of claim 52 where the SiC NEMS beam has dimensions and parameters providing a fundamental resonance frequencies in the microwave L band.

57. A method of tuning a submicron NEMS device having an out-of-plane resonance comprising:
providing a magnetic field in which the NEMS device is positioned;
supplying an AC current to the NEMS device to oscillate the NEMS device in the magnetic field at a resonant frequency;
supplying a DC current to the NEMS device to tune the out-of-plane resonant frequency of the NEMS device with a constant Lorentz force.

58. The method of claim 57 where the NEMS device has an axial length and is provided with a metallization along its axial length, where supplying a DC current to the NEMS device comprises supplying a DC current to the metallization.

59. The method of claim 57 where the NEMS device also has an in-plane resonance and further comprising varying the temperature of the NEMS device to tune both the out-of-plane and in-plane resonance of the NEMS device.

60. A tunable submicron NEMS device having an out-of-plane resonance comprising:
a source of a magnetic field in which the NEMS device is positioned;
an AC current source coupled to the NEMS device to oscillate the NEMS device in the magnetic field at a resonant frequency;
a DC current source coupled to the NEMS device to tune the out-of-plane resonant frequency of the NEMS device with a constant Lorentz force.

61. The NEMS device of claim 60 where the NEMS device has an axial length and is provided with a metallization along its axial length, where the DC current source coupled to the NEMS device supplies a DC current to the metallization.

62. The NEMS device of claim 60 where the NEMS device also has an in-plane resonance and further comprising means for varying the temperature of the NEMS device to tune both the out-of-plane and in-plane resonance of the NEMS device.

63. The NEMS device of claim 62 where the NEMS device comprises a semiconductor-metal bilayer formed of a single crystalline highly doped semiconductor and the metallization disposed thereon is a polycrystalline metal to reduce stresses in the semiconductor-metal bilayer.

64. An improvement in a resonating submicron one-port NEMS device comprising a resonating beam having a width w, a thickness t, a length L, a detector load resistance R_{L}, an equivalent mechanical impedance Rₘ, operating a frequency corresponding to the wavelength λ with an electrode on the beam with a conductivity of σ such that the insertion loss ε defined as:
$${ɛ}_{1} = \frac{{α}^{2}}{( 1 + α ) ( 1 + α + \frac{{R}_{m} λσ t w}{L} )} where α = \frac{λσ {R}_{L} t w}{L}$$
is minimized or near unity.

65. An improvement in a resonating submicron two-port NEMS device comprising a resonating beam having a width w, a thickness t, a length L, a detector load resistance R_{L}, an equivalent mechanical impedance Rₘ, operating a frequency corresponding to the wavelength λ with an electrode on the beam with a conductivity of σ such that the insertion loss ε defined as:
$${ɛ}_{2} = \frac{1}{2} {{α}^{\frac{1}{2}} ( \frac{1 - α}{1 - .75 α} )}^{\frac{1}{2}} where α = \frac{λσ {R}_{L} t w}{L}$$
is minimized or near unity.

66. An improvement in a two-port, straight, doubly clamped NEMS magnetomotive beam coupled to an amplifier with a load resistance R_{L}, the NEMS beam having a length L, a thickness t, a width w, Young's modulus E, mass density ρ, in a magnetic field B, with a conductivity a of its metallization, a temperature T, a driving signal wavelength of λ, a resonant frequency of f₀, an amplifier spectral power density S^{a}_{V}, chosen so that the spectral displacement sensitivity S^{m}_{X(2)} is equal to or greater than the spectral displacement density corresponding to thermal fluctuations of the NEMS beam, which spectral displacement sensitivity S^{m}_{X(2)} is defined as
$$\sqrt{{S}_{X ( 2 )}^{m}} = \frac{1.68}{{σ}^{\frac{1}{2}} {λ}^{\frac{1}{2}} B} {( \frac{ρ}{E} )}^{\frac{1}{8}} {{f}_{0}}^{- \frac{3}{4}} {t}^{- \frac{3}{4}} {{w}^{- \frac{1}{2}} [ {k}_{B} T + \frac{{S}_{V}^{a}}{{R}_{L}} ( \frac{1 - 0.75 α}{1 - α} ) ]}^{\frac{1}{2}}$$
where k_{B} is the Boltzman constant and
$$α = 0.99 {R}_{L} {σλ ( \frac{ρ}{E} )}^{\frac{1}{4}} {f}_{0}^{\frac{1}{2}} {t}^{\frac{1}{2}} w .$$

67. A method for fabrication of a NEMS beam from a Si membrane comprising:
providing a Si substrate;
disposing a SiO₂ layer on the Si substrate;
disposing a Si epilayer on the SiO₂ layer;
selectively anisotropically etching away a portion of the Si substrate down to the SiO₂ layer used as a stop layer;
selectively etching away a portion of the SiO₂ layer to expose a suspended Si epilayer membrane; and
forming the NEMS beam in the suspended Si epilayer membrane
whereby capillary distortion is avoided and electron beam resolution is achieved without proximate scattering from a substrate.

68. A method for fabrication of a NEMS beam from a GaAs membrane comprising:
providing a GaAs substrate;
disposing an AlGaAs layer on the GaAs substrate;
disposing a GaAs epilayer on the AlGaAs layer;
selectively anisotropically etching away a portion of the GaAs substrate down to the AlGaAs layer used as a stop layer;
selectively etching away a portion of the AlGaAs layer to expose a suspended GaAs epilayer membrane; and
forming the NEMS beam in the suspended GaAs epilayer membrane.

69. The method of claim 68 where selectively anisotropically etching away a portion of the GaAs substrate down to the AlGaAs layer used as a stop layer comprises etching with a NH₄OH or citric acid solution.

70. The method of claim 69 where etching with a NH₄OH solution comprises etching with a solution comprised of NH₄OH and H₂O₂ in the volume ratio of approximately 1:30, freshly mixed prior to etching.

71. The method of claim 69 where etching with a citric acid solution comprises etching with a room temperature bath comprised of citric acid monohydrate mixed and completely dissolved in a 1:1 mixture with deionized water by weight, then mixing this 1:1 mixture in a 3:1 volume ratio with H₂O₂ to provide the bath.

72. A NEMS array analyzer comprising:
two opposing parallel substrates;
a plurality of piezoresistive NEMS cantilevers extending from one of the substrates, each of the NEMS cantilevers having a different resonant frequency so that the corresponding plurality of resonant frequencies covers a selected spectral range; and
a plurality of drive/sense elements extending from the other one of the substrates, each of the drive/sense elements primarily coupled with one of the plurality of piezoresistive NEMS cantilevers.

73. A NEMS array analyzer comprising:
a frame;
a plurality of NEMS structures forming an interacting array to form an optical diffraction grating;
means for driving the plurality of NEMS structures in response to an input signal; and
light source for illuminating the plurality of NEMS structures; and
detector means for detecting diffracted light from the plurality of NEMS structures acting collectively as a time-varying diffraction grating.

74. A NEMS electronic chemical sensing array comprising:
a plurality of strain-sensing NEMS cantilevers, each having an overlayer disposed thereon which is responsive to a corresponding analyte, the response of the overlayer imposing a strain on the corresponding cantilever; and
means for detecting the strain of each of the plurality of strain-sensing NEMS cantilevers.

75. The NEMS electronic chemical sensing array of claim 74 where the response of the overlay comprises expansive or contractile volume changes of the overlay causing a strain to be imposed on the corresponding cantilever to cause it to bend, and where the means for detecting comprises an optical detector array for determining the amount of bending of each cantilever.

76. The NEMS electronic chemical sensing array of claim 74 where the response of the overlay comprises a mass loading resulting in a change in total inertial mass of each corresponding cantilever and where the means for detecting comprises means for detecting changes in resonant frequency shifts for each cantilever.

77. A NEMS infrared sensing array comprising:
two opposing parallel substrates;
a plurality of identically sized piezoresistive NEMS cantilevers extending from one of the substrates, each of the cantilevers being provided with a corresponding IR absorber responsive to a different IR frequency and inducing a corresponding differential thermal expansion of each cantilever depending on the amount of IR absorbed by each IR absorber; and
a plurality of drive/sense elements extending from the other one of the substrates, each of the drive/sense elements primarily coupled with one of the plurality of piezoresistive NEMS cantilevers.

78. A piezoresistive NEMS device with a confined carrier region comprising:
a doped semiconductor layer; and
an intrinsic semiconductor underlying the doped semiconductor wherein the thickness of the doped and instrinsic layers are as thin as approximately 7 nm and approximately 23 nm respectively while retaining a well confined conducting layer.

79. A piezoresistive NEMS device with a confined carrier region comprising:
a doped semiconductor layer in which a quantum well is defined; and
an intrinsic semiconductor underlying the doped semiconductor, the thickness of the doped semiconductor layer and underlying intrinsic layer being reduced, until a predetermined magnitude of thickness for a depletion layer at the interface between the doped and intrinsic layers, and at the top surface of the doped layer is just allowed with a difference in band edge energy on the order of 0.4 eV or greater being established at the interface.

80. The piezoresistive NEMS device of claim 79 further comprising a confining layer having a difference in band edge energy on the order of 0.4 eV or greater with respect to the doped semiconductor layer disposed adjacent to the doped semiconductor layer.

81. The piezoresistive NEMS device of claim 80 further comprising a confining layer adjacent and underlying the doped semiconductor layer, and a confining layer adjacent and overlying the doped semiconductor layer, each confining layer having a difference in band edge energy on the order of 0.4 eV or greater with respect to the doped semiconductor layer.

82. A piezoresistive NEMS device with a confined carrier region comprising:
a doped semiconductor layer in which a quantum well is defined; and
an insulating underlying the doped semiconductor, the thickness of the doped semiconductor layer and underlying insulating layer being reduced, until a predetermined magnitude of thickness for a depletion layer at the interface between the doped and insulating layers, and at the top surface of the doped layer is just allowed with a difference in band edge energy on the order of 0.4 eV or greater being established at the interface.

83. A method of providing a piezoresistive transducer of minimal thickness while still retaining a piezoresistive characteristic comprising reducing the thickness of a doped semiconductor layer and reducing an underlying intrinsic layer, until a predetermined magnitude of thickness for a depletion layer at the interface between the doped and intrinsic layers, and at the top surface of the doped layer is just allowed.
